(19) United States
(12) Patent Application Publication
(10) Pub. No.: US 2026/0234309 A1
(43) Pub. Date: Aug. 13, 2026

(54) PATTERNED ALKALINE EXCHANGE MEMBRANES

(71) Applicant: ECOLECTRO, INC., Ithaca, NY (US)

(72) Inventor: Christopher Simoneau, Ithaca, NY (US)

(21) Appl. No.: 19/152,587

(22) PCT Filed: Jan. 31, 2024
(86) PCT No.: PCT/US24/13776

§ 371 Date: Jul. 31, 2025

Related U.S. Application Data
(60) Provisional application No. 63/442,617, filed on Feb. 1, 2023.

(51) Int. Cl. C08F 232/04; B01J 41/05; B01J 41/14; B01J 47/12; C08J 3/28; C08J 5/22; C25B 9/23; C25B 11/048; G03F 7/00; G03F 7/038; G03F 7/20; H01M 4/90; H01M 8/10; H01M 8/1004; H01M 8/1025; H01M 8/103; H01M 8/1034

(52) U.S. Cl. CPC C08F 232/04; B01J 41/05; B01J 41/14; B01J 47/12; C08J 3/28; C08J 5/2287; C25B 9/23; C25B 11/048; G03F 7/038; G03F 7/2002; G03F 7/70008; H01M 4/9008; H01M 8/1004; H01M 8/1025; H01M 8/103; H01M 8/1034; C08F 2800/10; C08F 2810/20; C08F 2810/50; H01M 2008/1095; H01M 2300/0082

(57) ABSTRACT

The present disclosure relates to patterned anion exchange membranes comprising cross-linked segments and non-crosslinked segments. The present disclosure further relates to methods of manufacturing of the patterned anion exchange membranes, as well as electrochemical devices comprising the disclosed patterned anion exchange membranes.

### RELATED APPLICATIONS

This application claims the benefit of priority to U.S. Provisional Application No. 63/442,617 filed on Feb. 1, 2023. The entire teachings of the above application are incorporated herein by reference.

### BACKGROUND OF THE INVENTION

Alkaline exchange membrane (AEM)-based electrolyzers and fuel cells are cost-effective, industrially important alternatives to proton exchange membranes (PEM) and traditional alkaline exchange devices.

An AEM provides an ionic network for anion transport in a membrane electrode assembly (MEA), facilitating water management within the cell, and acting as a binder for catalyst adhesion and overall mechanical integrity between the layers of the MEA.

Therefore, high-performance AEMs that are resistant to thermal and chemical degradation under the harsh chemical environment and high temperatures of devices such a fuel cells and electrolyzers are needed.

### SUMMARY OF THE INVENTION

In a first example embodiment, the present disclosure relates to a polymer film, comprising a first plurality of volumes and a second plurality of volumes, wherein:
each volume of the first plurality of volumes comprises a cross-linkable precursor ionomer, and each volume of the second plurality of volumes comprises a cross-linked product ionomer, the cross-linkable precursor ionomer and the cross-linked product ionomer each comprising:
a plurality of first repeat units, wherein each first repeat unit is represented by the following structural formula:

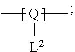

and
a plurality of second repeat units, wherein each first repeat unit is represented by the following structural formula:

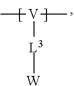

and further wherein:
   the cross-linkable precursor ionomer comprises one or more cross-linkable moieties represented by any one of the following structural formulas:

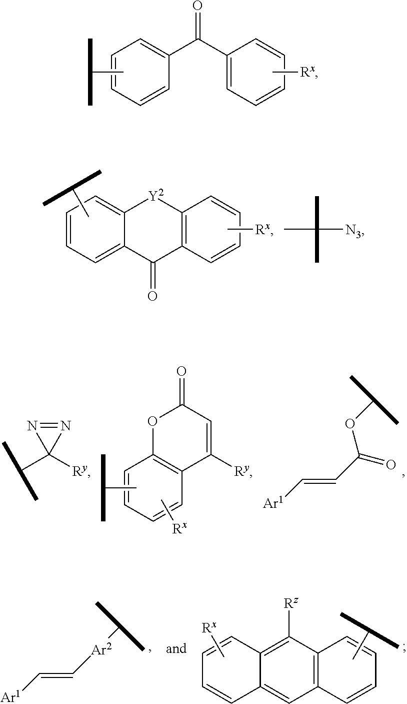

and
the cross-linked product ionomer comprises one or more cross-linking moieties represented by any one of the following structural formulas:

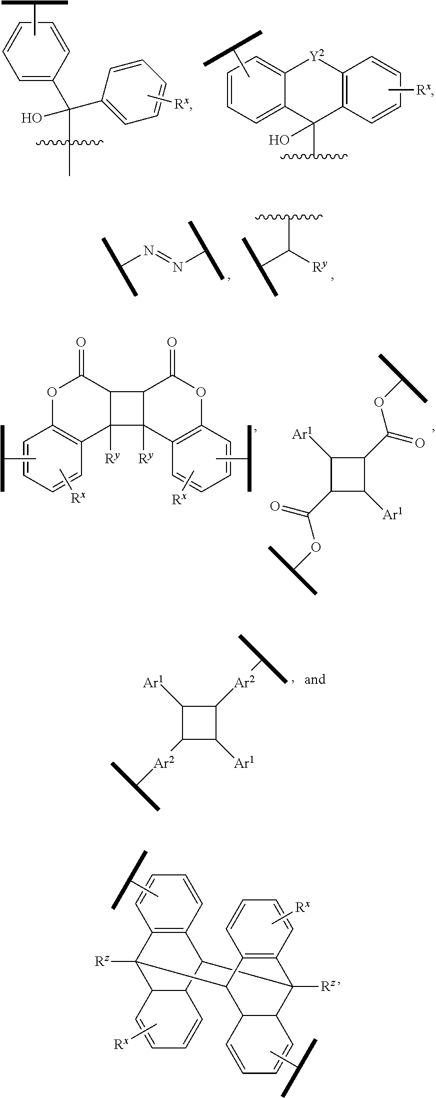

wherein, for each occurrence of the cross-linkable moiety, the symbol [symbol] represents a point of attachment to L², and, for each occurrence of the cross-linking moiety, the symbol [symbol] represents a point of attachment to L² and the symbol [symbol] represents a point of attachment to a first repeat unit or a second repeat unit, and further wherein:

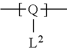

is a moiety represented by one of the following structural formulas:

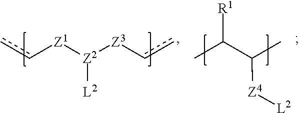

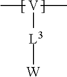

is a moiety represented by any one of the following structural formulas:

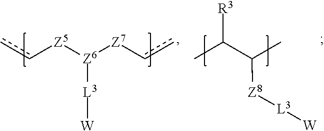

W is a C₁₋₁₂ alkyl or a moiety represented by one of the following structural formulas:

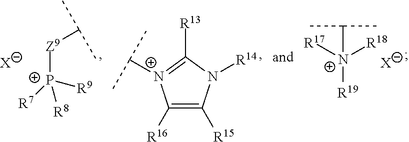

wherein the symbol [symbol] represents a point of attachment to L³, and the symbol [symbol] represents a double bond or a single bond;
Z¹, Z³, Z⁵, and Z⁷ each independently is a C₁₋₃ alkylene or a bond;
Z² is selected from —CHR⁵—, a C₅₋₁₂ cycloalkylene, and a 5 to 16-membered heterocyclylene;
R¹ is selected from H, a C₁₋₁₂ alkyl, and C₆₋₁₂ aryl, and
Z⁴ is a bond or a C₆₋₁₂ arylene, or
Z⁴ is CH, and R¹ and Z⁴ together with the C₂ alkylene to which they are attached form a C₅₋₁₂ cycloalkyl or a 5 to 12-membered heterocyclyl; and
Z⁶ is selected from —CHR⁶—, a C₅₋₁₂ cycloalkylene, and a 5 to 16-membered heterocyclylene;
R³ is selected from H, a C₁₋₁₂ alkyl, and C₆₋₁₂ aryl, and
Z⁸ is a bond or a C₆₋₁₂ arylene, and CH, or
Z⁸ is CH, and R³ and Z⁸ together with the C₂ alkylene to which they are attached form a C₅₋₁₂ cycloalkyl or a 5 to 12-membered heterocyclyl; and
Z⁹ is NR¹⁰ or a bond;
R⁵, R⁶, and R^{y} each independently is H or a C₁₋₁₂ alkyl;
R⁷, R⁸, and R⁹ each independently is selected from NR¹¹R¹², a C₆₋₁₂ aryl, and 5 to 12-membered heterocyclyl;
R¹⁰ is a C₁₋₁₂ alkyl;
R¹¹ and R¹² each independently is C₁₋₁₂ alkyl or a C₃₋₁₂ cycloalkyl, or R¹¹ and R¹² together with the nitrogen atom to which they are attached form a 5 to 12-membered heterocyclyl;
R¹³ is selected from a C₁₋₁₂ alkyl, C₆₋₁₂ aryl, and 5 to 12-membered heterocyclyl;
R¹⁴ is a C₁₋₁₂ alkyl or a C₃₋₁₂ cycloalkyl;
R¹⁵ and R¹⁶ each independently is selected from C₁₋₁₂ alkyl, C₆₋₁₂ aryl, and 5 to 12-membered heterocyclyl; or R¹⁵ and R¹⁶ together with the carbon atoms to which they are attached form a C₆₋₁₂ aryl or a 5 to 12-membered heterocyclyl; and
R¹⁷, R¹⁸, and R¹⁹ each independently is a C₁₋₁₂ alkyl or a C₃₋₁₂ cycloalkyl; or
R¹⁸ and R¹⁹ together with the nitrogen atom to which they are attached form a 5 to 12-membered heterocyclyl and (i) R¹⁷ is a C₁₋₁₂ alkyl or a C₃₋₁₂ cycloalkyl, or (ii) R¹⁷ and at least one atom of L³ together with the nitrogen atom to which L³ and R¹⁷ are attached form a 5- to 12-membered heterocyclyl; or
R¹⁷, R¹⁸, and R¹⁹ together with the nitrogen atom to which they are attached form a bicyclic 5 to 12-membered heterocyclyl;
R^{x} and R^{z} each independently is selected from H, F, Cl, Br, OH, NH₂, NO₂, CN, C₁₋₁₂ alkyl, C₆₋₁₂ aryl, 5 to 12-membered heterocyclyl, and 5 to 12-membered heteroaryl;
Ar¹ is a C₆₋₁₂ aryl or a 5 to 12-membered heterocyclyl;
Ar² is a C₆₋₁₂ arylene or a 5 to 16-membered heterocyclylene;
L² is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₘ, (C₁₋₁₂ alkylene-O)ₘ, C(O)(O—C₁₋₁₂ alkylene)ₘ, OC(O)(C₁₋₁₂ alkylene)ₘ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₘ, (NH)C(O—C₁₋₁₂ alkylene)ₘ, (NH—C₁₋₁₂ alkylene)ₘ, and (C₁₋₁₂ alkylene-NH)ₘ;
L³ is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₙ, (C₁₋₁₂ alkylene-O)ₙ, C(O)(O—C₁₋₁₂ alkylene)ₙ, OC(O)(C₁₋₁₂ alkylene)ₙ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₙ, (NH)C(O—C₁₋₁₂ alkylene)ₙ, (NH—C₁₋₁₂ alkylene)ₙ, (C₁₋₁₂ alkylene-NH)ₙ, and a bond;
m is an integer between 1 and 6;
n is an integer between 1 and 6;
Y² is selected from —C(O)—, —O—, —S—, —NH—, —N(C₁₋₁₂ alkyl)-, and a bond;
X⁻ is selected from F⁻, Cl⁻, Br⁻, OH⁻, NO⁻₂, CN⁻, HCO₃⁻, CO₃²⁻, PF₆⁻, BF₄⁻, and a C₁₋₁₂ carboxylate;
provided that W is C₁₋₁₂ alkyl only when V is a cationic moiety, and wherein:
each C₁₋₁₂ alkyl, C₃₋₁₂ cycloalkyl, C₅₋₁₂ cycloalkyl, C₆₋₁₂ aryl, 5 to 12-membered heteroaryl, 5 to 12-membered heterocyclyl, C₁₋₁₂ alkylene, C₆₋₁₂ arylene, C₅₋₁₂ cycloalkylene, 5 to 16-membered heterocyclylene, and 5 to 12-membered heteroarylene is independently optionally substituted with 1 to 6 substituents independently selected from the group consisting of F, Cl, Br, OH, NH₂, NO₂, oxo, CN, a C₁₋₁₂ alkyl, C₆₋₁₂ aryl, C₁₋₁₂haloalkyl, C₁₋₁₂ alkoxy, C₆₋₁₂ aryl, C₆₋₁₂ aryloxy, 5 to 16-membered heterocyclyl, 5 to 12-membered heteroaryl, NH(C₁₋₁₂ alkyl), N(C₁₋₁₂ alkyl)₂, OC(O)(C₁₋₁₂ alkyl), C(O)O(C₁₋₁₂ alkyl), S(O)₂(C₁₋₁₂ alkyl), S(O)₂(C₆₋₁₂ aryl), NHC(O)(C₁₋₁₂ alkyl), and C(O)NH(C₁₋₁₂ alkyl).

In a second example embodiment the present disclosure relates to an electrode comprising a catalyst/ionomer layer, wherein the catalyst/ionomer layer comprises a polymer film as described herein with respect to the first embodiment and various aspects thereof.

In a third example embodiment the present disclosure relates to a composite material comprising a polymer film as described herein with respect to the first embodiment and various aspects thereof or an electrode as described herein with respect to the second embodiment and various aspects thereof, and a support, wherein the polymer film or the electrode is disposed on the support.

In a fourth example embodiment the present disclosure relates to a membrane electrode assembly (MEA), comprising a polymer film as described herein with respect to the first embodiment and various aspects thereof, an electrode as described herein with respect to the second embodiment and various aspects thereof, or a composite material as described herein with respect to the third embodiment and various aspects thereof.

In a fifth example embodiment the present disclosure relates to a fuel cell comprising an MEA as described herein with respect to the fourth embodiment and various aspects thereof, a source of fuel, and an oxidant

In a sixth example embodiment the present disclosure relates to an electrolyzer comprising an MEA as described herein with respect to the fourth embodiment and various aspects thereof, and an electrolyte source.

In a seventh example embodiment the present disclosure relates to a method of making a polymer film as described herein with respect to the first embodiment and various aspects thereof, comprising:
a) providing a precursor film comprising the cross-linkable precursor ionomer,
b) applying a mask to the film, thereby providing a partially protected film;
c) exposing the partially protected film to ultraviolet radiation for a time sufficient to cross-link the cross-linkable ionomer, thereby producing the polymer film.

### BRIEF DESCRIPTION OF THE DRAWINGS

FIG. 1 is a schematic representation of patterned cross-linking of an AEM.

FIG. 2 is an image of a patterned AEM cross-linked under a 70 mesh stainless steel mask. The AEM was allowed to swell in water and dry overnight, demonstrating a persisting surface pattern.

FIG. 3 is an image of an AEM that has been heated at 50° C. for 45 min while a 70 mesh stainless steel mask was placed on the surface with a 20 g weight, then swelled in water and dried overnight at room temperature.

FIG. 4 is an image of a patterned AEM cross-linked under a 500 mesh stainless steel mask. The AEM was then allowed to swell in water and dry overnight, demonstrating a persisting surface pattern.

FIG. 5 is is a bar graph showing polarization curve data at 1.8 and 2.1 V for an AEM electrolyzer device using a patterned and a non-patterned membrane.

FIG. 6. is a graph demonstrating electrochemical impedance spectroscopy data gathered from the AEM electrolyzer tests shown in FIG. 5.

### DETAILED DESCRIPTION

Developing anion exchange membranes (AEMs) that contain durable polymer backbones and cationic groups is required to commercialize fuel cells, electrolyzers, redox flow batteries, water purifiers and other electrochemical devices. Alkaline systems hold several benefits over acidic counterparts, particularly since the fabrication of devices requires less expensive electrodes and bipolar plates and affords longer lifetimes. Alkaline electrochemical devices are an attractive alternative to proton exchange membrane (PEM) devices because at elevated pH, oxygen reduction is more facile and lower overpotentials are required, and allowing metals other than platinum to be used as electrocatalysts.

An alkaline exchange ionomer (AEI) is a cationic polymer with the ability to conduct hydroxide anions within the MEA of an electrolyzer and a fuel cell device. Suitable AEIs for water electrolyzers and fuel cells are often characterized as having high hydroxide conductivity, modest water absorption properties, and solubility in organic solvents.

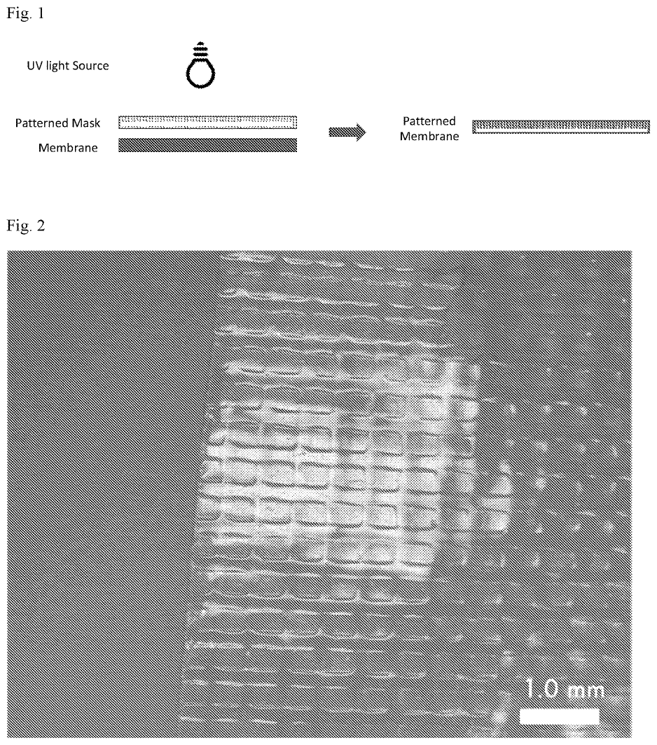

Disclosed herein are patterned AEMs comprising segments of cross-linked and non-crosslinked AEIs. The disclosed AEMs are prepared from AEIs bearing cationic and cross-linkable moieties. The AEMs are prepared by covering a membrane containing a UV-crosslinkable AEI with a mask followed by exposure to UV light. This procedure selectively cross-links the ionomer in the areas not covered by the mask. The obtained partially cross-linked AEM has a pattern of non-crosslinked segments extending from the surface all the way through the thickness of the membrane. These segments correspond to the areas covered by the mask during the UV exposure, while the cross-linked segments correspond to the voids in the mask (see FIG. 1). As a result, the patterned AEM has volumes of low and high ion conductivity due to differences in water content in the cross-linked and non-crosslinked segments. Highly cross-linked areas have reduced water content, thus reducing ion conductivity in this area, while non-cross-linked areas have lower water content, forming ionic channels. High ionic density in the ionic channels creates a concentrated path for ions. For the same overall ion content, a polymer with ionic channels has a higher ionic conductivity compared to a polymer with no ionic channels (as has been shown for ionic/non-ionic block copolymers vs. random copolymers of the same composition).

Poor performance or durability within an electrochemical device, such as an electrolyzer or fuel cell, can be attributed to either chemical or mechanical degradation of the AEI. During operation, MEA components are subjected to pressure and electrochemical forces from the flowing electrolytes, incoming or outgoing gases, heat, and applied voltages. These forces result in a physical change of the AEI layer (swelling or deformation) resulting in a delamination. The delamination results in the loss of electrical and ionic contact and manifests itself as an increase in device resistance and poor overall performance.

The disclosed patterned AEMs combining cross-linked and non-crosslinked volumes have a three-dimensional texture that withstands repeated swelling and dehydration, which improves durability of the AEM by preventing delamination.

The present disclosure describes patterned AEMs formed from an AEI comprising cationic and UV-crosslinkable moieties. Examples of such AEIs are described in the International Patent Application Publication WO 2023/018765, which is incorporated herein by reference in its entirety. The patterned AEM is obtained by exposing a partially masked AEI membrane to UV light. The process does not require the use of external cross-linking agents such as dithiols or dialdehydes to achieve mechanically robust electrodes. This eliminates the need for subjecting the AEM to organic reagents post-production or relying on reactions to take place in slurries after coating. It also allows for selective masking of the precursor membrane (i.e., the AEI membrane comprising UV-cross-linkable moieties which have not yet been cross-linked) in order, for example, to reinforce certain areas of the AEM for mechanical, chemical, or thermal durability.

The disclosed approach to the preparation of the patterned AEM extends the membrane “cure time” indefinitely without the risk of creating an intractable material. The process offers cure on demand using UV light to eliminate the risk of premature curing. Using UV activation to cross-link the ionomers is advantageous because the ionomers can be synthesized and fabricated in any form needed (films, powders, solutions) prior to irreversible cross-linking. UV curing of coatings is common in polymer manufacturing and simplifies the processing for production at larger scale. This is preferred over methods that crosslink in situ or by chemical soaking after fabrication because these methods are difficult to translate in large scale manufacturing. Additionally, it is difficult to control curing of selected segments of the membrane when using thermal or chemical cross-linking initiation, while UV curing offers complete control of the AEM pattern based on the parameters of the mask.

In some embodiments, one or more masks may be applied to (e.g., cover) selected portions of the precursor film comprising non-crosslinked AEM to prevent the selected portions of the AEM material from cross-linking. The one or more masks are preferably configured to substantially prevent exposure of the cross-linkable polymer to UV light that would otherwise cause the cross-linkable polymer to cross-link. For example, a substantially UV-opaque mask applied to a UV-crosslinkable polymer will substantially prevent the cross-linkable polymer from cross-linking during treatment with UV-radiation by protecting the covered portion from the UV-radiation.

In some embodiments, the UV light may be focused onto selected portions of the cross-linkable polymer to prevent the unselected portions of the cross-linkable polymer from cross-linking. In some embodiments, only the portions of the cross-linkable polymer in contact with the focused UV light are capable of being cross-linked.

### Ionomers of the Invention

Presented in the below paragraphs are exemplary components (e.g., backbones, repeat units, cationic moieties, or cross-linkable moieties) of cross-linkable AEIs that can be used in the AEMs of the disclosure. An AEI can comprise any combination of the components disclosed below.

### 1. Ionomer Backbones

A cross-linkable moiety or a cationic moiety can be incorporated in the polymer by connecting it to a repeat unit. For example, the following repeat units or ionomer backbones can be functionalized with cross-linkable or cationic moieties:

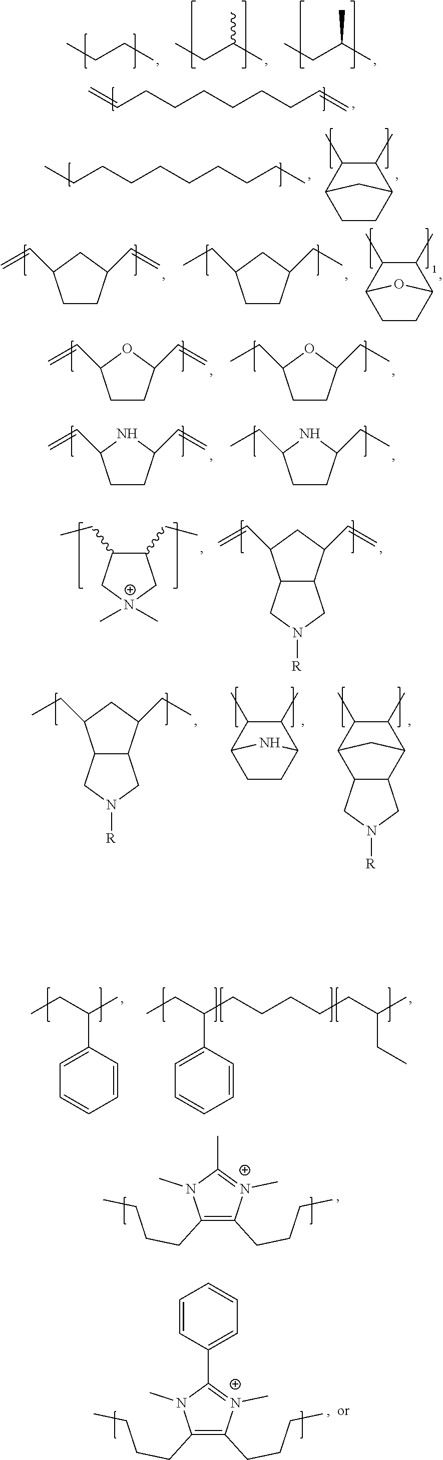

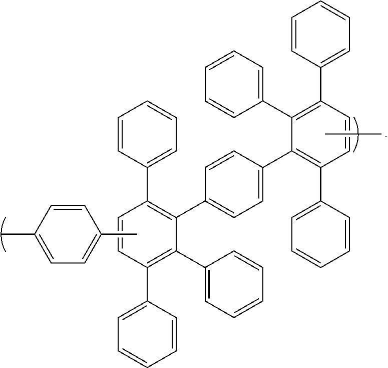

### 2. Cationic Moieties.

The AEIs can comprise various cationic moieties. For example, cationic moieties can be incorporated in an AEI as pendants linked to the backbone of the ionomer. Additionally or alternatively, the backbone of the ionomer can comprise cationic groups. For example, the following cationic moieties can be incorporated in an AEI ( [symbol] indicates the point of attachment of the cationic moiety to the backbone or to a linker connected to the backbone):

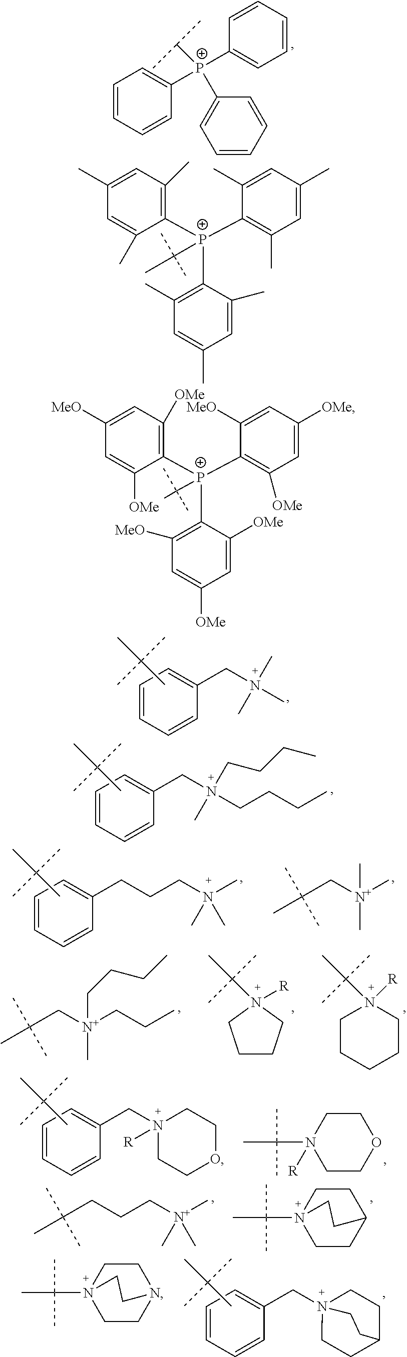

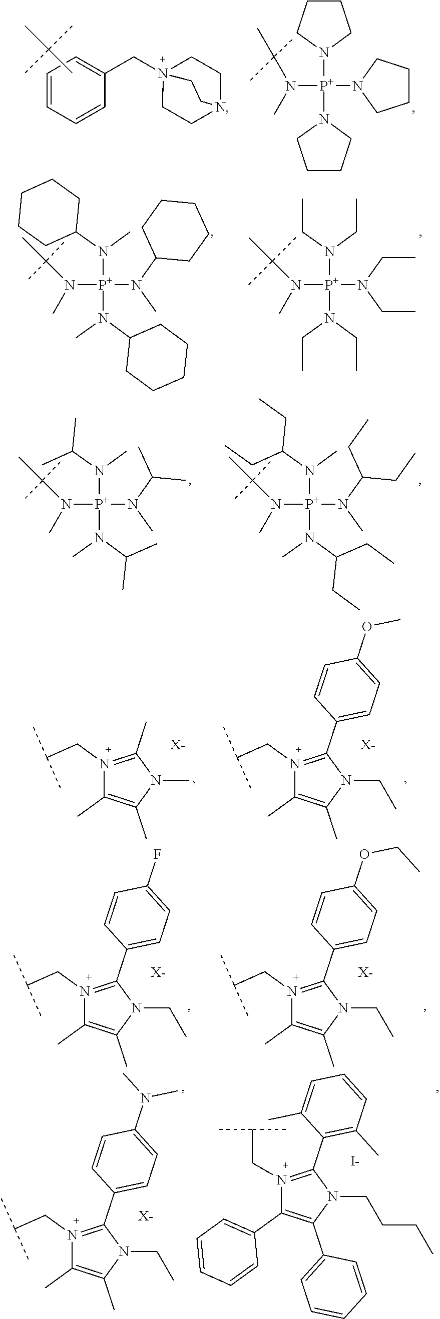

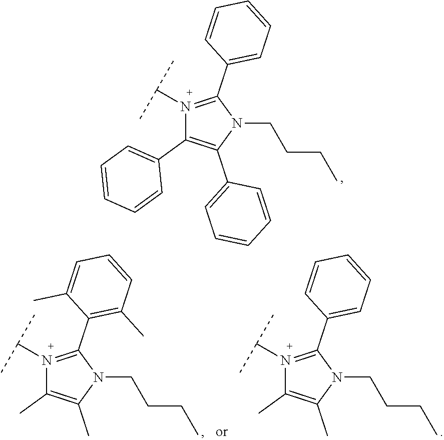

### 3. Cross-Linkable Moieties

The AEIs can comprise, cross-linkable moieties in some of the repeat units of the polymer. The cross-linkable moieties can comprise, for example, type II photoinitiators, e.g., benzophenone, camphorquinone, isopropylthioxanthone, and thioxanthone (see Allushi et al., Polymer Chemistry, 2017, 8, 1972-1977). Type I photoinitiators such as dimethoxyphenylacetophenone, α-hydroxyacetophenone, α-aminoacetophenone, benzoylphosphinoxide, bisbenzoylphosphinoxide, can also be introduced into some of the repeat units of the ionomer.

In some embodiments, the cross-linkable ionomers of this disclosure comprise a type II photoinitiator, such as benzophenone. For example, an ionomer can be prepared by copolymerizing cyclooctene substituted with a benzophenone-containing moiety, cyclooctene substituted with a cationic moiety, and unsubstituted cyclooctene, to yield, for example, the following copolymer:

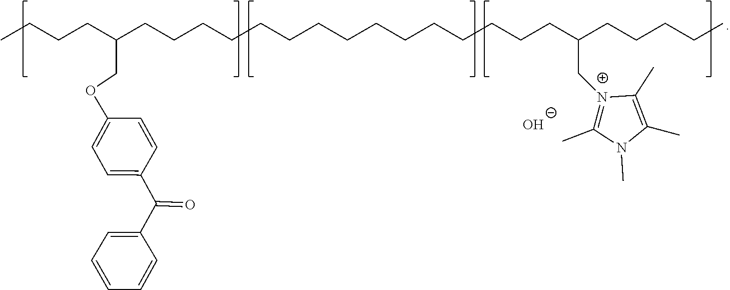

The shown copolymer is a random copolymer.

Upon exposure to UV light, the benzophenone pendants in the ionomer undergo UV-activated C,H-insertion reactions to forms covalent C—C bonds with polymer fragments containing aliphatic C—H bonds. Accordingly, the benzophenone-containing moiety can become covalently linked to a CH-containing group in the polymer backbone or the side chain pendant. For example, after the UV exposure the benzophenone-based crosslinking moiety can be attached to alkylene, alkyl, or cycloalkyl groups in i) the backbone, ii) the cationic moieties; or iii) the linkers attaching the cationic moieties or the benzophenone moieties to the backbone. Such cross-linking can be intramolecular (the covalent bond is formed via C,H-insertion in the same polymer chain) or intermolecular (the covalent bond is formed via C,H-insertion in a different polymer chain). Therefore, upon exposure to UV light, an ionomer comprising benzophenone-containing repeat units forms a cross-linked polymer network. The network can comprise, for example, the following cross-linking moieties:

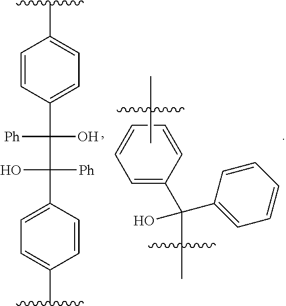

In some embodiments, the AEIs of the disclosure can comprise a diazerine-containing cross-linkable moiety. A diazerene fragment decomposes into a carbene upon exposure to UV light, which enables the cross-linking of essentially any organic polymer through C—H activation:

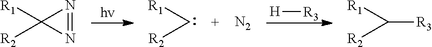

Additionally, the AEIs of the disclosure can comprise crosslinking moieties that undergo UV-initiated [2+2]cycloadditions and [4+4]cycloadditions as shown below:

| Compound | Reaction |
|---|---|
| Anthracene | 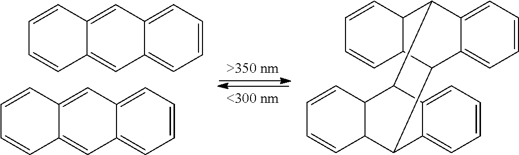 |
| Cinnamic acid | 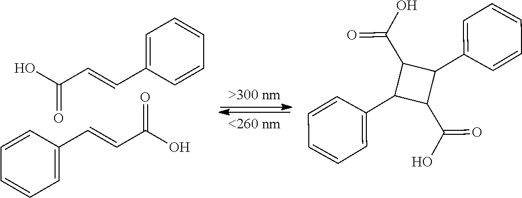 |
| Coumarin | 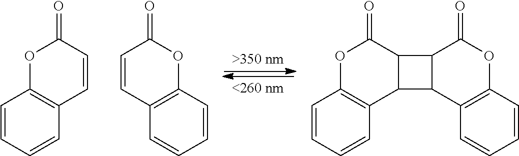 |
| Thymine″ | 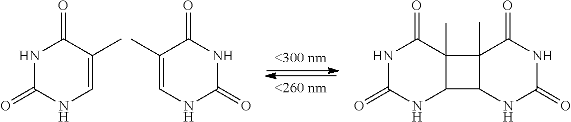 |
| Stilbene | 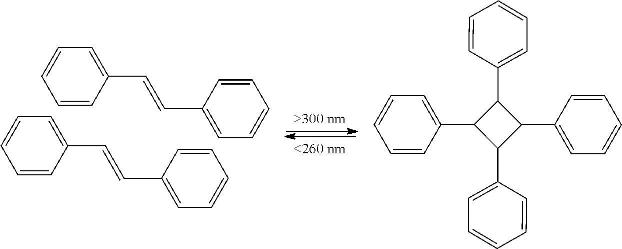 |

In some embodiments, the AEIs of the disclosure can comprise an azide-containing cross-linkable moiety. The azide fragment decomposes into a nitrene upon exposure to UV light, which enables the cross-linking of an organic polymer through C—H activation or through recombination of two nitrenes to form a diazo cross-linker:

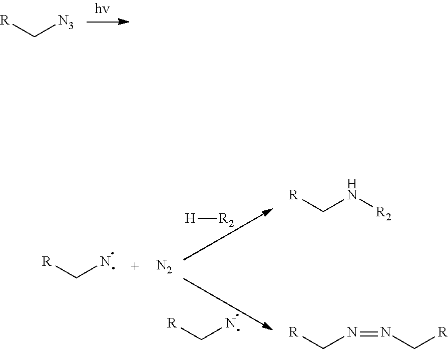

### 4. Repeat Units

In some embodiments, the cross-linkable ionomers of the present disclosure can comprise the following combinations of repeat units:

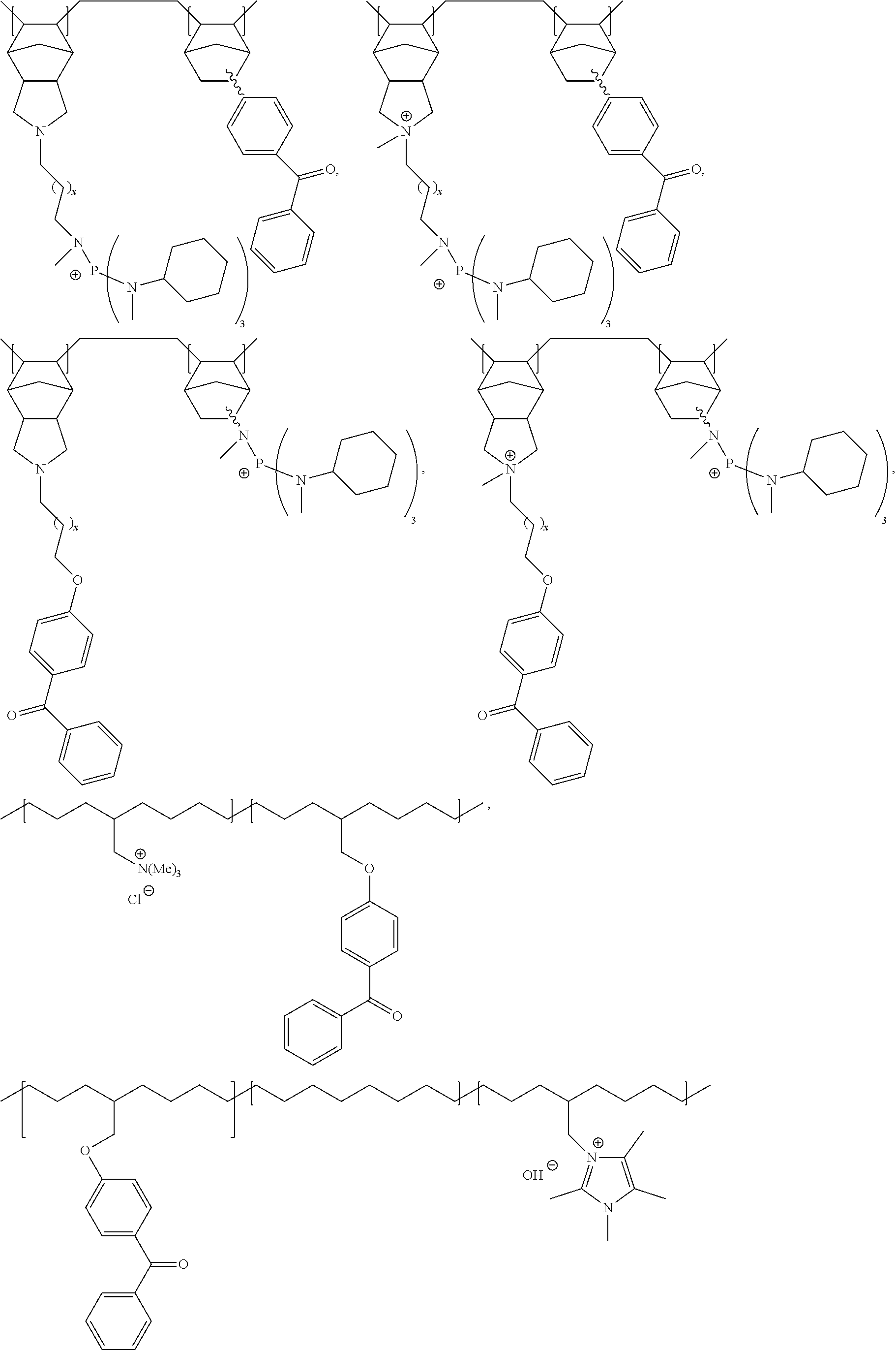

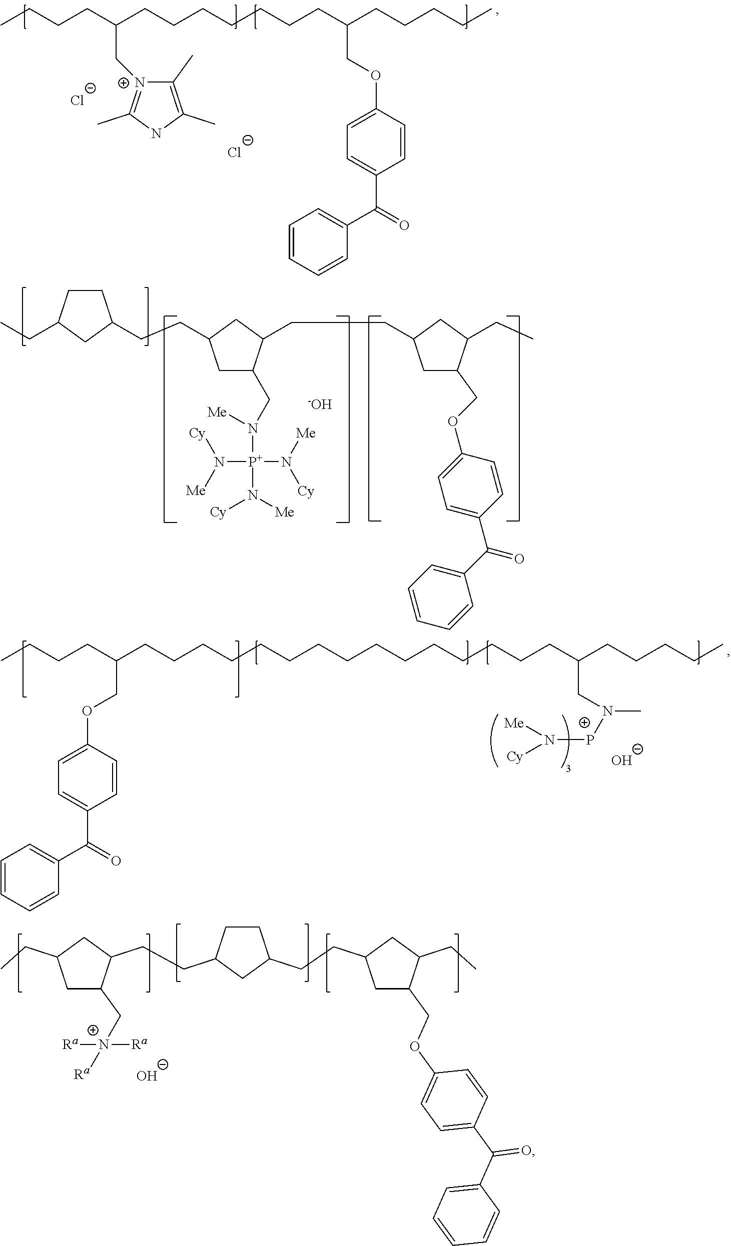

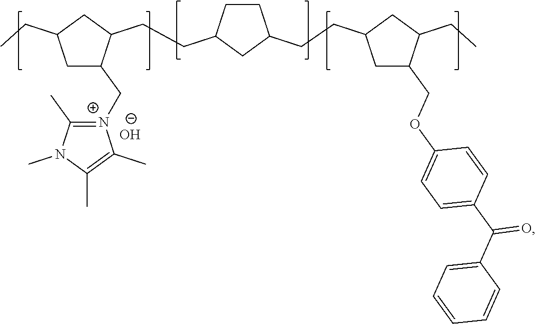

where each R^{a} can independently be a C₁₋₁₂ alkyl or a C₃₋₁₂ cycloalkyl.

### Definitions

Definitions of specific functional groups and chemical terms are described in more detail below. The chemical elements are identified in accordance with the Periodic Table of the Elements, CAS version, Handbook of Chemistry and Physics, 75^{th} Ed., inside cover, and specific functional groups are generally defined as described therein. Additionally, general principles of organic chemistry, as well as specific functional moieties and reactivity, are described in Organic Chemistry, Thomas Sorrell, University Science Books, Sausalito, 1999; Smith and March, March's Advanced Organic Chemistry, 5^{th} Edition, John Wiley & Sons, Inc., New York, 2001; Larock, Comprehensive Organic Transformations, VCH Publishers, Inc., New York, 1989; and Carruthers, Some Modern Methods of Organic Synthesis, 3^{rd} Edition, Cambridge University Press, Cambridge, 1987.

Compounds described herein can comprise one or more asymmetric centers, and thus can exist in various stereoisomeric forms, e.g., enantiomers and/or diastereomers. For example, the compounds described herein can be in the form of an individual enantiomer, diastereomer or geometric isomer, or can be in the form of a mixture of stereoisomers, including racemic mixtures and mixtures enriched in one or more stereoisomer. Isomers can be isolated from mixtures by methods known to those skilled in the art, including chiral high pressure liquid chromatography (HPLC) and the formation and crystallization of chiral salts; or preferred isomers can be prepared by asymmetric syntheses. See, for example, Jacques et al., Enantiomers, Racemates and Resolutions, Wiley Interscience, New York, 1981; Wilen et al., Tetrahedron 33:2725 (1977); Eliel, E. L. Stereochemistry of Carbon Compounds, McGraw-Hill, NY, 1962; and Wilen, S. H., Tables ofResolving Agents and Optical Resolutions p. 268, E. L. Eliel, Ed., Univ. of Notre Dame Press, Notre Dame, IN 1972. The invention additionally encompasses compounds as individual isomers substantially free of other isomers, and alternatively, as mixtures of various isomers.

In a formula, [symbol] or [symbol] is a single or double bond.

When a range of values is listed, it is intended to encompass each value and sub-range within the range. For example, “C₁₋₆ alkyl” is intended to encompass C₁, C₂, C₃, C₄, C₅, C₆, C₁₋₆, C₁₋₅, C₁₋₄, C₁₋₃, C₁₋₂, C₂₋₆, C₂₋₅, C₂₋₄, C₂₋₃, C₃₋₆, C₃₋₅, C₃₋₄, C₄₋₆, C₄₋₅, and C₅₋₆ alkyl.

The term “alkyl” refers to a radical of a straight-chain or branched saturated hydrocarbon group having from 1 to 18 carbon atoms (“C₁₋₁₈ alkyl”). In some embodiments, an alkyl group has 1 to 12 carbon atoms (“C₁₋₁₂ alkyl”). In some embodiments, an alkyl group has 1 to 8 carbon atoms (“C₁₋₈ alkyl”). In some embodiments, an alkyl group has 1 to 6 carbon atoms (“C₁₋₆ alkyl”). In some embodiments, an alkyl group has 1 to 3 carbon atoms (“C₁₋₃ alkyl”). In some embodiments, an alkyl group has 2 to 6 carbon atoms (“C₂₋₆ alkyl”). Examples of C₁₋₆ alkyl groups include methyl (C₁), ethyl (C₂), propyl (C₃) (e.g., n-propyl, isopropyl), butyl (C₄) (e.g., n-butyl, tert-butyl, sec-butyl, iso-butyl), pentyl (C₅) (e.g., n-pentyl, 3-pentanyl, amyl, neopentyl, 3-methyl-2-butanyl, tertiary amyl), and hexyl (C₆) (e.g., n-hexyl). Additional examples of alkyl groups include n-heptyl (C₇), n-octyl (C₈), and the like. Unless otherwise specified, each instance of an alkyl group is independently unsubstituted (an “unsubstituted alkyl”) or substituted (a “substituted alkyl”). In certain embodiments, the alkyl group is an unsubstituted C₁₋₁₂ alkyl (such as unsubstituted C₁₋₆ alkyl, e.g., —CH₃ (Me), unsubstituted ethyl (Et), unsubstituted propyl (Pr, e.g., unsubstituted n-propyl (n-Pr), unsubstituted isopropyl (i-Pr)), unsubstituted butyl (Bu, e.g., unsubstituted n-butyl (n-Bu), unsubstituted tert-butyl (tert-Bu or t-Bu), unsubstituted sec-butyl (sec-Bu), unsubstituted isobutyl (i-Bu)). In certain embodiments, the alkyl group is a substituted C₁₋₁₂ alkyl (such as substituted C₁₋₆ alkyl, e.g., —CF₃, Bn).

The term “haloalkyl” refers to a substituted alkyl group, wherein one or more of the hydrogen atoms are independently replaced by a halogen, e.g., fluoro, bromo, chloro, or iodo. In some embodiments, the haloalkyl moiety has 1 to 12 carbon atoms (“C₁₋₁₂ haloalkyl”). In some embodiments, the haloalkyl moiety has 1 to 6 carbon atoms (“C₁₋₆ haloalkyl”). In some embodiments, the haloalkyl moiety has 1 to 4 carbon atoms (“C₁₋₄ haloalkyl”). In some embodiments, the haloalkyl moiety has 1 to 3 carbon atoms (“C₁₋₃ haloalkyl”). In some embodiments, the haloalkyl moiety has 1 to 2 carbon atoms (“C₁₋₂ haloalkyl”). Examples of haloalkyl groups include —CHF₂, —CH₂F, —CF₃, —CH₂CF₃, —CF₂CF₃, —CF₂CF₂CF₃, —CCl₃, —CFCl₂, —CF₂Cl, and the like.

The term “alkoxy” refers to an alkyl group, as defined herein, appended to the parent molecular moiety through an oxygen atom. In some embodiments, the alkoxy moiety has 1 to 12 carbon atoms (“C₁₋₁₂ alkoxy”). In some embodiments, the alkoxy moiety has 1 to 6 carbon atoms (“C₁₋₆ alkoxy”). In some embodiments, the alkoxy moiety has 1 to 4 carbon atoms (“C₁₋₄ alkoxy”). In some embodiments, the alkoxy moiety has 1 to 3 carbon atoms (“C₁₋₃ alkoxy”). In some embodiments, the alkoxy moiety has 1 to 2 carbon atoms (“C₁₋₂ alkoxy”). Representative examples of alkoxy include, but are not limited to, methoxy, ethoxy, propoxy, 2-propoxy, butoxy and tert-butoxy.

In some embodiments, “cycloalkyl” is a radical of a saturated hydrocarbon monocyclic or polycyclic group having from 3 to 18 ring carbon atoms (“C₃₋₁₈ cycloalkyl”). In some embodiments, a cycloalkyl group has 3 to 12 ring carbon atoms (“C₃₋₁₂ cycloalkyl”). In some embodiments, a cycloalkyl group has 3 to 8 ring carbon atoms (“C₃₋₈ cycloalkyl”). In some embodiments, a cycloalkyl group has 5 to 12 ring carbon atoms (“₅₋₁₂ cycloalkyl”). In some embodiments, a cycloalkyl group has 4 to 6 ring carbon atoms (“C₄₋₆ cycloalkyl”). In some embodiments, a cycloalkyl group has 5 to 6 ring carbon atoms (“C₅₋₆ cycloalkyl”). In some embodiments, a cycloalkyl group has 5 to 7 ring carbon atoms (“C₅₋₇ cycloalkyl”). A polycyclic cycloalkyl group can be, for example, bycyclic, tricyclic, or tetracyclic. A polycyclic cycloalkyl group can contain fused cycloalkyl rings. A polycyclic cycloalkyl group can be a spirocyclic cycloalkyl group or a bridged cycloalkyl group. Examples of C₅₋₆ cycloalkyl groups include cyclopentyl (C₅) and cyclohexyl (C₆). Examples of C₃₋₆ cycloalkyl groups include the aforementioned C₅₋₆ cycloalkyl groups as well as cyclopropyl (C₃) and cyclobutyl (C₄). Examples of C₃₋₈ cycloalkyl groups include the aforementioned C₃₋₆ cycloalkyl groups as well as cycloheptyl (C₇) and cyclooctyl (C₈). Unless otherwise specified, each instance of a cycloalkyl group is independently unsubstituted (an “unsubstituted cycloalkyl”) or substituted (a “substituted cycloalkyl”) with one or more substituents. In certain embodiments, the cycloalkyl group is an unsubstituted C₃₋₁₂ cycloalkyl. In certain embodiments, the cycloalkyl group is a substituted C₃₋₁₂ cycloalkyl. In certain embodiments, the cycloalkyl group is an unsubstituted C₅₋₁₂ cycloalkyl. In certain embodiments, the cycloalkyl group is a substituted C₅₋₁₂ cycloalkyl.

In some embodiments, “cycloalkenyl” is a non-aromatic radical of a hydrocarbon monocyclic or polycyclic group having at least one double bond and from 4 to 18 ring carbon atoms (“C₄₋₁₈ cycloalkenyl”). In some embodiments, a cycloalkenyl group has 4 to 12 ring carbon atoms (“C₄₋₁₂ cycloalkenyl”). In some embodiments, a cycloalkyl group has 4 to 8 ring carbon atoms (“C₄₋₈ cycloalkenyl”). In some embodiments, a cycloalkenyl group has 5 to 12 ring carbon atoms (“₅₋₁₂ cycloalkenyl”). In some embodiments, a cycloalkenyl group has 7 to 8 ring carbon atoms (“C₇₋₈ cycloalkenyl”). A polycyclic cycloalkenyl group can be, for example, bycyclic, tricyclic, or tetracyclic. A polycyclic cycloalkenyl group can contain a cycloalkenyl ring fused to another cycloalkenyl ring, a cycloalkyl ring, or a heterocyclyl ring. A polycyclic cycloalkenyl group can be a spirocyclic cycloalkenyl group or a bridged cycloalkenyl group. Exemplary cycloalkenyl groups include, without limitation, cyclooctenyl, bicyclooctenyl, and norbornenyl.

The term “aryl” refers to a radical of a monocyclic or polycyclic (e.g., bicyclic or tricyclic) 4n+2 aromatic ring system (e.g., having 6, 10, or 14 π electrons shared in a cyclic array) having 6-14 ring carbon atoms and zero heteroatoms provided in the aromatic ring system (“C₆₋₁₄ aryl”). In some embodiments, an aryl group has 6 ring carbon atoms (“C₆ aryl”; e.g., phenyl). In some embodiments, an aryl group has 10 ring carbon atoms (“C₁₀ aryl”; e.g., naphthyl such as 1-naphthyl and 2-naphthyl). In some embodiments, an aryl group has 14 ring carbon atoms (“C₁₄ aryl”; e.g., anthracyl). “Aryl” also includes ring systems wherein the aryl ring, as defined above, is fused with one or more carbocyclyl or heterocyclyl groups wherein the radical or point of attachment is on the aryl ring, and in such instances, the number of carbon atoms continue to designate the number of carbon atoms in the aryl ring system. Unless otherwise specified, each instance of an aryl group is independently unsubstituted (an “unsubstituted aryl”) or substituted (a “substituted aryl”) with one or more substituents. In certain embodiments, the aryl group is an unsubstituted C₆₋₁₂ aryl. In certain embodiments, the aryl group is a substituted C₆₋₁₂ aryl.

The term “aryloxy” refers to an aryl group, as defined herein, appended to the parent molecular moiety through an oxygen atom. In some embodiments, the aryloxy moiety has 6 to 12 carbon atoms (“C₆₋₁₂ aryloxy”). In some embodiments, the aryloxy moiety has 6 to 10 carbon atoms (“C₆₋₁₀ aryloxy”). Representative examples of aryloxy include, but are not limited to, phenoxy and naphthoxy.

The term “heterocyclyl” or “heterocyclic” refers to a radical of a 3- to 16-membered saturated, unsaturated non-aromatic, or aromatic ring system having ring carbon atoms and 1 to 4 ring heteroatoms, wherein each heteroatom is independently selected from nitrogen, oxygen, and sulfur (“5-16 membered heterocyclyl”). In heterocyclyl groups that contain one or more nitrogen atoms, the point of attachment can be a carbon or nitrogen atom, as valency permits. A heterocyclyl group can either be monocyclic (“monocyclic heterocyclyl”) or polycyclic (e.g., a fused, bridged or spiro ring system such as a bicyclic system (“bicyclic heterocyclyl”) or tricyclic system (“tricyclic heterocyclyl”). Heterocyclyl polycyclic ring systems can include one or more heteroatoms in one or both rings. “Heterocyclyl” also includes ring systems wherein the heterocyclyl ring, as defined above, is fused with one or more cycloalkyl groups wherein the point of attachment is either on the cycloalkyl or heterocyclyl ring, or ring systems wherein the heterocyclyl ring, as defined above, is fused with one or more aryl groups, wherein the point of attachment is on the heterocyclyl ring, and in such instances, the number of ring members continue to designate the number of ring members in the combined fused ring system. Unless otherwise specified, each instance of heterocyclyl is independently unsubstituted (an “unsubstituted heterocyclyl”) or substituted (a “substituted heterocyclyl”) with one or more substituents. In certain embodiments, the heterocyclyl group is an unsubstituted 5-12 membered heterocyclyl. In certain embodiments, the heterocyclyl group is a substituted 5-12 membered heterocyclyl.

In some embodiments, a heterocyclyl group is a 5-10 membered non-aromatic ring system having ring carbon atoms and 1-4 ring heteroatoms, wherein each heteroatom is independently selected from nitrogen, oxygen, and sulfur (“5-10 membered heterocyclyl”). In some embodiments, a heterocyclyl group is a 5-8 membered non-aromatic ring system having ring carbon atoms and 1-4 ring heteroatoms, wherein each heteroatom is independently selected from nitrogen, oxygen, and sulfur (“5-8 membered heterocyclyl”). In some embodiments, a heterocyclyl group is a 5-6 membered non-aromatic ring system having ring carbon atoms and 1-4 ring heteroatoms, wherein each heteroatom is independently selected from nitrogen, oxygen, and sulfur (“5-6 membered heterocyclyl”). In some embodiments, the 5-6 membered heterocyclyl has 1-3 ring heteroatoms selected from nitrogen, oxygen, and sulfur. In some embodiments, the 5-6 membered heterocyclyl has 1-2 ring heteroatoms selected from nitrogen, oxygen, and sulfur. In some embodiments, the 5-6 membered heterocyclyl has 1 ring heteroatom selected from nitrogen, oxygen, and sulfur.

As used herein, the term “heterocycloalkenyl” refers to an unsaturated non-aromatic heterocyclyl group as described above, comprising one or more double bonds. In some embodiments, heterocycloalkenyl groups are bicyclic bridge moieties. In some embodiments, heterocycloalkenyl groups are bicyclic fused moieties. Exemplary heterocycloalkenyl groups include, without limitation, 7-oxabicyclo[2.2.1]hept-2-ene, 7-azabicyclo[2.2.1]hept-2-ene, and 7-methyl-7-azabicyclo[2.2.1]hept-2-ene.

Exemplary 3-membered heterocyclyl groups containing 1 heteroatom include, without limitation, aziridinyl, oxiranyl, and thiiranyl. Exemplary 4-membered heterocyclyl groups containing 1 heteroatom include, without limitation, azetidinyl, oxetanyl, and thietanyl. Exemplary 5-membered heterocyclyl groups containing 1 heteroatom include, without limitation, tetrahydrofuranyl, dihydrofuranyl, tetrahydrothiophenyl, dihydrothiophenyl, pyrrolidinyl, dihydropyrrolyl, and pyrrolyl-2,5-dione. Exemplary 5-membered non-aromatic heterocyclyl groups containing 1 heteroatom include, without limitation, tetrahydrofuranyl, dihydrofuranyl, tetrahydrothiophenyl, dihydrothiophenyl, pyrrolidinyl, dihydropyrrolyl, and pyrrolyl-2,5-dione. Exemplary 5-membered heterocyclyl groups containing 2 heteroatoms include, without limitation, dioxolanyl, oxathiolanyl and dithiolanyl. Exemplary 5-membered heterocyclyl groups containing 3 heteroatoms include, without limitation, triazolinyl, oxadiazolinyl, and thiadiazolinyl. Exemplary 6-membered heterocyclyl groups containing 1 heteroatom include, without limitation, piperidinyl, tetrahydropyranyl, dihydropyridinyl, and thianyl. Exemplary 6-membered heterocyclyl groups containing 2 heteroatoms include, without limitation, piperazinyl, morpholinyl, dithianyl, and dioxanyl. Exemplary 6-membered heterocyclyl groups containing 3 heteroatoms include, without limitation, triazinyl. Exemplary 7-membered heterocyclyl groups containing 1 heteroatom include, without limitation, azepanyl, oxepanyl and thiepanyl. Exemplary 8-membered heterocyclyl groups containing 1 heteroatom include, without limitation, azocanyl, oxecanyl and thiocanyl. Exemplary bicyclic heterocyclyl groups include, without limitation, indolinyl, isoindolinyl, dihydrobenzofuranyl, dihydrobenzothienyl, tetrahydrobenzothienyl, tetrahydrobenzofuranyl, tetrahydroindolyl, tetrahydroquinolinyl, tetrahydroisoquinolinyl, decahydroquinolinyl, decahydroisoquinolinyl, octahydrochromenyl, octahydroisochromenyl, decahydronaphthyridinyl, decahydro-1,8-naphthyridinyl, octahydropyrrolo[3,2-b]pyrrole, indolinyl, phthalimidyl, naphthalimidyl, chromanyl, chromenyl, 1H-benzo[e][1,4]diazepinyl, 1,4,5,7-tetrahydropyrano[3,4-b]pyrrolyl, 5,6-dihydro-4H-furo[3,2-b]pyrrolyl, 6,7-dihydro-5H-furo[3,2-b]pyranyl, 5,7-dihydro-4H-thieno[2,3-c]pyranyl, 2,3-dihydro-1H-pyrrolo[2,3-b]pyridinyl, 2,3-dihydrofuro[2,3-b]pyridinyl, 4,5,6,7-tetrahydro-1H-pyrrolo[2,3-b]pyridinyl, 4,5,6,7-tetrahydrofuro[3,2-c]pyridinyl, 4,5,6,7-tetrahydrothieno[3,2-b]pyridinyl, 1,2,3,4-tetrahydro-1,6-naphthyridinyl, and the like.

In some embodiments, the term “heterocyclyl” refers to a radical of a 5-16 membered monocyclic or polycyclic (e.g., bicyclic, tricyclic) 4n+2 aromatic ring system (e.g., having 6, 10, or 14 π electrons shared in a cyclic array), also referred to as “heteroaryl”, having ring carbon atoms and 1-4 ring heteroatoms provided in the aromatic ring system, wherein each heteroatom is independently selected from nitrogen, oxygen, sulfur. In heteroaryl groups that contain one or more nitrogen atoms, the point of attachment can be a carbon or nitrogen atom, as valency permits. Heteroaryl polycyclic ring systems can include one or more heteroatoms in one or both rings. “Heteroaryl” includes ring systems wherein the heteroaryl ring, as defined above, is fused with one or more carbocyclyl or heterocyclyl groups wherein the point of attachment is on the heteroaryl ring, and in such instances, the number of ring members continue to designate the number of ring members in the heteroaryl ring system. “Heteroaryl” also includes ring systems wherein the heteroaryl ring, as defined above, is fused with one or more aryl groups wherein the point of attachment is either on the aryl or heteroaryl ring, and in such instances, the number of ring members designates the number of ring members in the fused polycyclic (aryl/heteroaryl) ring system. Polycyclic heteroaryl groups wherein one ring does not contain a heteroatom (e.g., indolyl, quinolinyl, carbazolyl, and the like) the point of attachment can be on either ring, i.e., either the ring bearing a heteroatom (e.g., 2-indolyl) or the ring that does not contain a heteroatom (e.g., 5-indolyl).

In some embodiments, a heteroaryl group is a 5-12 membered aromatic ring system having ring carbon atoms and 1-4 ring heteroatoms provided in the aromatic ring system, wherein each heteroatom is independently selected from nitrogen, oxygen, and sulfur (“5-12 membered heteroaryl”). In some embodiments, a heteroaryl group is a 5-8 membered aromatic ring system having ring carbon atoms and 1-4 ring heteroatoms provided in the aromatic ring system, wherein each heteroatom is independently selected from nitrogen, oxygen, and sulfur (“5-8 membered heteroaryl”). In some embodiments, a heteroaryl group is a 5-6 membered aromatic ring system having ring carbon atoms and 1-4 ring heteroatoms provided in the aromatic ring system, wherein each heteroatom is independently selected from nitrogen, oxygen, and sulfur (“5-6 membered heteroaryl”). In some embodiments, the 5-6 membered heteroaryl has 1-3 ring heteroatoms selected from nitrogen, oxygen, and sulfur. In some embodiments, the 5-6 membered heteroaryl has 1-2 ring heteroatoms selected from nitrogen, oxygen, and sulfur. In some embodiments, the 5-6 membered heteroaryl has 1 ring heteroatom selected from nitrogen, oxygen, and sulfur. Unless otherwise specified, each instance of a heteroaryl group is independently unsubstituted (an “unsubstituted heteroaryl”) or substituted (a “substituted heteroaryl”) with one or more substituents. In certain embodiments, the heteroaryl group is an unsubstituted 5-14 membered heteroaryl. In certain embodiments, the heteroaryl group is a substituted 5-14 membered heteroaryl.

Exemplary 5-membered heteroaryl groups containing 1 heteroatom include, without limitation, pyrrolyl, furanyl, and thiophenyl. Exemplary 5-membered heteroaryl groups containing 2 heteroatoms include, without limitation, imidazolyl, pyrazolyl, oxazolyl, isoxazolyl, thiazolyl, and isothiazolyl. Exemplary 5-membered heteroaryl groups containing 3 heteroatoms include, without limitation, triazolyl, oxadiazolyl, and thiadiazolyl. Exemplary 5-membered heteroaryl groups containing 4 heteroatoms include, without limitation, tetrazolyl. Exemplary 6-membered heteroaryl groups containing 1 heteroatom include, without limitation, pyridinyl. Exemplary 6-membered heteroaryl groups containing 2 heteroatoms include, without limitation, pyridazinyl, pyrimidinyl, and pyrazinyl. Exemplary 6-membered heteroaryl groups containing 3 or 4 heteroatoms include, without limitation, triazinyl and tetrazinyl, respectively. Exemplary 7-membered heteroaryl groups containing 1 heteroatom include, without limitation, azepinyl, oxepinyl, and thiepinyl. Exemplary 5,6-bicyclic heteroaryl groups include, without limitation, indolyl, isoindolyl, indazolyl, benzotriazolyl, benzothiophenyl, isobenzothiophenyl, benzofuranyl, benzoisofuranyl, benzimidazolyl, benzoxazolyl, benzisoxazolyl, benzoxadiazolyl, benzthiazolyl, benzisothiazolyl, benzthiadiazolyl, indolizinyl, and purinyl. Exemplary 6,6-bicyclic heteroaryl groups include, without limitation, naphthyridinyl, pteridinyl, quinolinyl, isoquinolinyl, cinnolinyl, quinoxalinyl, phthalazinyl, and quinazolinyl. Exemplary tricyclic heteroaryl groups include, without limitation, phenanthridinyl, dibenzofuranyl, carbazolyl, acridinyl, phenothiazinyl, phenoxazinyl, and phenazinyl.

The term “unsaturated” or “partially unsaturated” refers to a moiety that includes at least one double or triple bond.

The term “saturated” refers to a moiety that does not contain a double or triple bond, i.e., the moiety only contains single bonds.

Affixing the suffix “-ene” to a group indicates the group is a divalent moiety, e.g., alkylene is the divalent moiety of alkyl, arylene is the divalent moiety of aryl, heteroarylene is the divalent moiety of heteroaryl, cycloalkylene is a divalent moiety of cycloalkyl, and heterocyclylene is the divalent moiety of hereocyclyl.

The term “C_{x-y}” when used in conjunction with a chemical moiety, such as, acyl, acyloxy, alkyl, alkenyl, alkynyl, or alkoxy is meant to include groups that contain from x to y carbons in the chain. For example, the term “C_{x-y}alkyl” refers to substituted or unsubstituted saturated hydrocarbon groups, including straight-chain alkyl and branched-chain alkyl groups that contain from x to y carbons in the chain, including haloalkyl groups such as trifluoromethyl and 2,2,2-trifluoroethyl, etc. C₀ alkyl indicates a hydrogen where the group is in a terminal position, a bond if internal.

A group is optionally substituted unless expressly provided otherwise. The term “optionally substituted” refers to being substituted or unsubstituted. In certain embodiments, alkyl, cycloalkyl, cycloalkenyl, heterocyclyl, heterocycloalkenyl, aryl, and heteroaryl groups and the corresponding divalent moieties are optionally substituted. “Optionally substituted” refers to a group which may be substituted or unsubstituted (e.g., “substituted” or “unsubstituted” alkyl, “substituted” or “unsubstituted” cycloalkyl, “substituted” or “unsubstituted” cycloalkenyl, “substituted” or “unsubstituted” heterocyclyl, “substituted” or “unsubstituted” heterocycloalkenyl, “substituted” or “unsubstituted” aryl or “substituted” or “unsubstituted” heteroaryl group). In general, the term “substituted” means that at least one hydrogen present on a group is replaced with a permissible substituent, e.g., a substituent which upon substitution results in a stable compound, e.g., a compound which does not spontaneously undergo transformation such as by rearrangement, cyclization, elimination, or other reaction. Unless otherwise indicated, a “substituted” group has a substituent at one or more substitutable positions of the group, and when more than one position in any given structure is substituted, the substituent is either the same or different at each position. The term “substituted” is contemplated to include substitution with all permissible substituents of organic compounds, and includes any of the substituents described herein that results in the formation of a stable compound. The present invention contemplates any and all such combinations in order to arrive at a stable compound. For purposes of this invention, heteroatoms such as nitrogen may have hydrogen substituents and/or any suitable substituent as described herein which satisfy the valencies of the heteroatoms and results in the formation of a stable moiety. The invention is not intended to be limited in any manner by the exemplary substituents described herein.

Exemplary carbon atom substituents include, but are not limited to, halogen, —CN, —NO₂, —N₃, —OH, F, Cl, Br, I, oxo, —SO₂H, —SO₃H, —OR^{aa}, —NH(R^{aa})₂, —N(R^{aa})₂, —N(R^{aa})₃⁺X⁻, —SH, —SR^{aa}, —C(═O)R^{aa}, —CO₂H, —CHO, —CO₂R^{aa}, —OC(═O)R^{aa}, —OCO₂R^{aa}, —C(═O)N(R^{aa})₂, —OC(═O)N(R^{aa})₂, —NR^{aa}C(═O)R^{aa}, —NR^{aa}CO₂R^{aa}, —NR^{aa}C(═O)N(R^{aa})₂, —C(═NR^{aa})R^{aa}, —C(═O)NR^{aa}SO₂R^{aa}, —NR^{aa}SO₂R^{aa}, —SO₂N(R^{aa})₂, —SO₂R^{aa}, —SO₂OR^{aa}, —OSO₂R^{aa}, —S(═O)R^{aa}, —OS(═O)R^{aa}, —Si(R^{aa})₃, —OSi(R^{aa})₃, C₁₋₁₂ alkyl, C₁₋₁₂ haloalkyl, 3-16 membered heterocyclyl, and C₆₋₁₂ aryl, wherein X is a counterion and each instance of R^{aa} is, independently, selected from H, —OH, C₁₋₁₀ alkyl, C₁₋₁₀ haloalkyl, C₃₋₁₂ cycloalkyl, 5-16 membered heterocyclyl, and C₆₋₁₂ aryl, or two R^{aa} groups are joined to form a 3-16 membered heterocyclyl.

Numeric ranges are inclusive of the numbers defining the range. Measured and measureable values are understood to be approximate, taking into account significant digits and the error associated with the measurement. As used in this application, the terms “about” and “approximately” have their art-understood meanings; use of one vs the other does not necessarily imply different scope. Unless otherwise indicated, numerals used in this application, with or without a modifying term such as “about” or “approximately”, should be understood to encompass normal divergence and/or fluctuations as would be appreciated by one of ordinary skill in the relevant art. In certain embodiments, the term “approximately” or “about” refers to a range of values that fall within 10%, 9%, 8%, 7%, 6%, 5%, 4%, 3%, 2%, 1%, or less in either direction (greater than or less than) of a stated reference value unless otherwise stated or otherwise evident from the context (except where such number would exceed 100% of a possible value).

Disclosed herein are catalyst/ionomer compositions prepared from ionomers comprising Tetrakis® cations. The term Tetrakis® refers to a cation of the following structural formula:

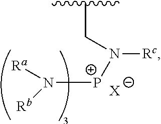

wherein [symbol] is a point of attachment to the polymer or to a linker connected to the polymer, and R^{a}, R^{b}, and R^{c} each independently is an alkyl or a cycloalkyl.

As used herein, the “main chain” of a polymer, or the “backbone” of the polymer, is the series of bonded atoms that together create the continuous chain of the polymer molecule. As used herein, a “side chain” of a polymer is the series of bonded atoms which are pendent from the main chain of a polymer.

As used herein, the term “repeat unit” (also known as a monomer unit) refers to a chemical moiety which appears multiple times in the main chain of the polymer to produce the complete polymer chain (except for the end-groups) by linking the repeat units together successively. A repeat unit is usually shown in square brackets with open valencies designating the points of attachment to the adjacent repeat units in the main chain:

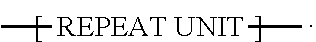

A polymer can contain one or more types of repeat units having different chemical structures. A polymer containing two or more different types of repeat units is known as a copolymer. A copolymer can be a block copolymer, where repeat units of the first type form a continuous main chain, i.e., a first homopolymer subunit, and repeat units of the second type form a continuous main chain, i.e., a second homopolymer subunit, and so forth for the required number of homopolymer subunits. The various homopolymer subunits are connected via covalent bonds to form the block copolymer. In some embodiments, the ionomers of the present disclosure are block copolymers.

A copolymer can be a statistical copolymer, also known as a random copolymer, where repeat units of different types are distributed randomly along the main chain. In random copolymers repeat units of the same type do not have to be attached to each other in the main chain. In some embodiments, the ionomers of the present disclosure are random copolymers.

As used herein, the term “cross-linked polymer” refers to a polymer in which two or more non-adjacent repeat units of the same main chain or two or more repeat units in different main chains are connected via a cross-linking moiety. The term “cross-linked polymer” also refers to two or more different main chains connected via a plurality of cross-linking moieties. For example, a cross-linked polymer, such as a cross-linked ionomer, can comprise a plurality of main chains connected by a plurality of cross-linking moieties to form an interconnected polymer network.

As used herein, the term “cross-linking moiety” refers to a polyvalent, for example, divalent or trivalent, moiety which forms covalent bonds with two or more non-adjacent repeat units of the same polymer main chain or with one or more repeat units of different main chains.

As used herein, the term “radical initiator” refers to a compound that can produce radical species and promote radical chain reactions, such as radical polymerizations. Examples of radical initiators include azo compounds and organic peroxides, such as 2,2′-azobis(2-methylpropionitrile), azobisisobutyronitrile, azobisdimethylvaleronitrile, and benzoyl peroxide.

As used herein, the phrase “catalyst is supported on carbon” refers to a catalyst-containing material in which the catalyst particles are deposited on the surface of activated carbon. Carbon as a support material for catalysts allows the dispersion and stabilization of small metal particles on a surface.

As used herein, the term “Raney nickel” refers a solid catalyst composed of fine grains of a nickel-aluminum alloy. A typical catalyst is around 85-percent nickel by mass, corresponding to about two atoms of nickel for every atom of aluminum.

The phrase “number average molecular weight” refers to total weight of polymer divided by the total number of molecules. The number average molecular weight is the common average of the molecular weights of the individual polymer molecules. It is determined by measuring the molecular weight of n polymer molecules, summing the weights, and dividing by n.

In a first embodiment, the present disclosure relates to a polymer film, comprising a first plurality of volumes and a second plurality of volumes, wherein:
each volume of the first plurality of volumes comprises a cross-linkable precursor ionomer, and each volume of the second plurality of volumes comprises a cross-linked product ionomer, the cross-linkable precursor ionomer and the cross-linked product ionomer each comprising:
a plurality of first repeat units, wherein each first repeat unit is represented by the following structural formula:

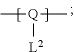

and
a plurality of second repeat units, wherein each first repeat unit is represented by the following structural formula:

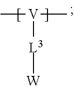

and further wherein:
   the cross-linkable precursor ionomer comprises one or more cross-linkable moieties represented by any one of the following structural formulas:

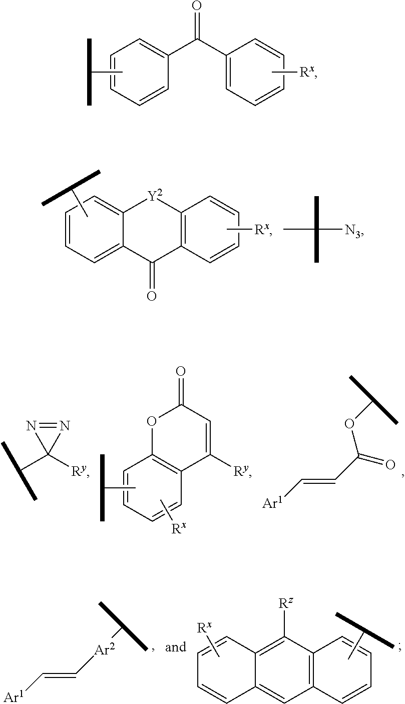

and
the cross-linked product ionomer comprises one or more cross-linking moieties represented by any one of the following structural formulas:

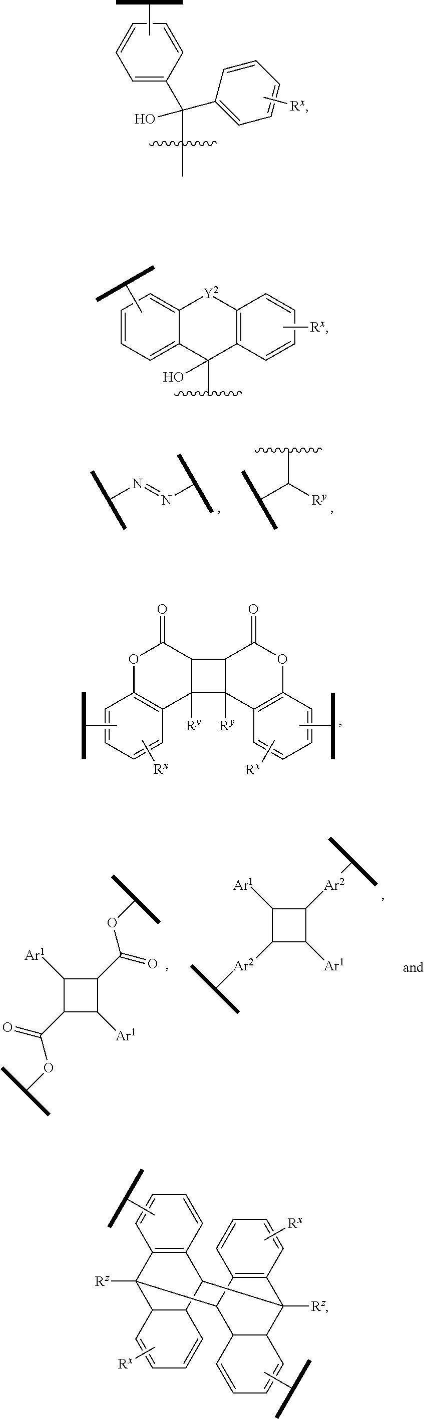

wherein, for each occurrence of the cross-linkable moiety, the symbol [symbol] represents a point of attachment to L², and, for each occurrence of the cross-linking moiety, the symbol [symbol] represents a point of attachment to L² and the symbol [symbol] represents a point of attachment to a first repeat unit or a second repeat unit, and further wherein:

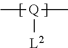

is a moiety represented by one of the following structural formulas:

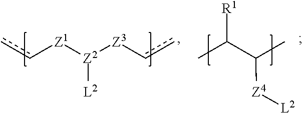

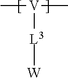

is a moiety represented by any one of the following structural formulas:

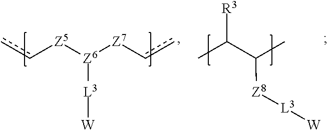

W is a C₁₋₁₂ alkyl or a moiety represented by one of the following structural formulas:

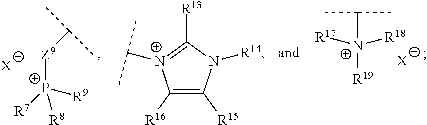

wherein the symbol [symbol] represents a point of attachment to L³, and the symbol
[symbol] represents a double bond or a single bond;
   Z¹, Z³, Z⁵, and Z⁷ each independently is a C₁₋₃ alkylene or a bond;
   Z² is selected from —CHR⁵—, a C₅₋₁₂ cycloalkylene, and a 5 to 16-membered heterocyclylene;
   R¹ is selected from H, a C₁₋₁₂ alkyl, and C₆₋₁₂ aryl, and
   Z⁴ is a bond or a C₆₋₁₂ arylene, or
   Z⁴ is CH, and R¹ and Z⁴ together with the C₂ alkylene to which they are attached form a C₅₋₁₂ cycloalkyl or a 5 to 12-membered heterocyclyl; and
   Z⁶ is selected from —CHR⁶—, a C₅₋₁₂ cycloalkylene, and a 5 to 16-membered heterocyclylene;
   R³ is selected from H, a C₁₋₁₂ alkyl, and C₆₋₁₂ aryl, and
   Z⁸ is a bond or a C₆₋₁₂ arylene, and CH, or
   Z⁸ is CH, and R³ and Z⁸ together with the C₂ alkylene to which they are attached form a C₅₋₁₂ cycloalkyl or a 5 to 12-membered heterocyclyl; and
   Z⁹ is NR¹⁰ or a bond;
   R⁵, R⁶, and R^{y} each independently is H or a C₁₋₁₂ alkyl;
   R⁷, R⁸, and R⁹ each independently is selected from NR¹¹R¹², a C₆₋₁₂ aryl, and 5 to 12-membered heterocyclyl;
   R¹⁰ is a C₁₋₁₂ alkyl;
   R¹¹ and R¹² each independently is C₁₋₁₂ alkyl or a C₃₋₁₂ cycloalkyl, or R¹¹ and R¹² together with the nitrogen atom to which they are attached form a 5 to 12-membered heterocyclyl;
   R¹³ is selected from a C₁₋₁₂ alkyl, C₆₋₁₂ aryl, and 5 to 12-membered heterocyclyl;
   R¹⁴ is a C₁₋₁₂ alkyl or a C₃₋₁₂ cycloalkyl;
   R¹⁵ and R¹⁶ each independently is selected from C₁₋₁₂ alkyl, C₆₋₁₂ aryl, and 5 to 12-membered heterocyclyl; or R¹⁵ and R¹⁶ together with the carbon atoms to which they are attached form a C₆₋₁₂ aryl or a 5 to 12-membered heterocyclyl; and
   R¹⁷, R¹⁸, and R¹⁹ each independently is a C₁₋₁₂ alkyl or a C₃₋₁₂ cycloalkyl; or
   R¹⁸ and R¹⁹ together with the nitrogen atom to which they are attached form a 5 to 12-membered heterocyclyl and (i) R¹⁷ is a C₁₋₁₂ alkyl or a C₃₋₁₂ cycloalkyl, or (ii) R¹⁷ and at least one atom of L³ together with the nitrogen atom to which L³ and R¹⁷ are attached form a 5- to 12-membered heterocyclyl; or
   R¹⁷, R¹⁸, and R¹⁹ together with the nitrogen atom to which they are attached form a bicyclic 5 to 12-membered heterocyclyl;
   R^{x} and R^{z} each independently is selected from H, F, Cl, Br, OH, NH₂, NO₂, CN, C₁₋₁₂ alkyl, C₆₋₁₂ aryl, 5 to 12-membered heterocyclyl, and 5 to 12-membered heteroaryl;
   Ar¹ is a C₆₋₁₂ aryl or a 5 to 12-membered heterocyclyl;
   Ar² is a C₆₋₁₂ arylene or a 5 to 16-membered heterocyclylene;
   L² is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₘ, (C₁₋₁₂ alkylene-O)ₘ, C(O)(O—C₁₋₁₂ alkylene)ₘ, OC(O)(C₁₋₁₂ alkylene)ₘ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₘ, (NH)C(O—C₁₋₁₂ alkylene)ₘ, (NH—C₁₋₁₂ alkylene)ₘ, and (C₁₋₁₂ alkylene-NH)ₘ;
   L³ is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₙ, (C₁₋₁₂ alkylene-O)ₙ, C(O)(O—C₁₋₁₂ alkylene)ₙ, OC(O)(C₁₋₁₂ alkylene)ₙ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₙ, (NH)C(O—C₁₋₁₂ alkylene)ₙ, (NH—C₁₋₁₂ alkylene)ₙ, (C₁₋₁₂ alkylene-NH)ₙ, and a bond;
   m is an integer between 1 and 6;
   n is an integer between 1 and 6;
   Y² is selected from —C(O)—, —O—, —S—, —NH—, —N(C₁₋₁₂ alkyl)-, and a bond;
   X⁻ is selected from F⁻, Cl⁻, Br⁻, OH⁻, NO⁻₂, CN⁻, HCO₃⁻, CO₃²⁻, PF₆⁻, BF₄⁻, and a C₁₋₁₂ carboxylate;
   provided that W is C₁₋₁₂ alkyl only when V is a cationic moiety, and wherein:
   each C₁₋₁₂ alkyl, C₃₋₁₂ cycloalkyl, C₅₋₁₂ cycloalkyl, C₆₋₁₂ aryl, 5 to 12-membered heteroaryl, 5 to 12-membered heterocyclyl, C₁₋₁₂ alkylene, C₆₋₁₂ arylene, C₅₋₁₂ cycloalkylene, 5 to 16-membered heterocyclylene, and 5 to 12-membered heteroarylene is independently optionally substituted with 1 to 6 substituents independently selected from the group consisting of F, Cl, Br, OH, NH₂, NO₂, oxo, CN, a C₁₋₁₂ alkyl, C₆₋₁₂ aryl, C₁₋₁₂haloalkyl, C₁₋₁₂ alkoxy, C₆₋₁₂ aryl, C₆₋₁₂ aryloxy, 5 to 16-membered heterocyclyl, 5 to 12-membered heteroaryl, NH(C₁₋₁₂ alkyl), N(C₁₋₁₂ alkyl)₂, OC(O)(C₁₋₁₂ alkyl), C(O)O(C₁₋₁₂ alkyl), S(O)₂(C₁₋₁₂ alkyl), S(O)₂(C₆₋₁₂ aryl), NHC(O)(C₁₋₁₂ alkyl), and C(O)NH(C₁₋₁₂ alkyl).

In a first aspect of the first embodiment,

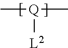

is a moiety represented by the following structural formula:

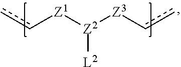

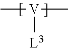

is a moiety represented by the following structural formula:

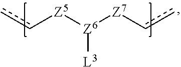

W is a C₁₋₁₂ alkyl or a moiety represented by the following structural formula:

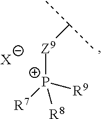

and
each cross-linking moiety is represented by structural formula (I).

In a second aspect of the first embodiment,

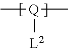

is a moiety represented by the following structural formula:

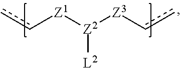

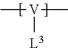

is a moiety represented by the following structural formula:

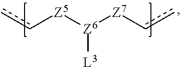

W is a C₁₋₁₂ alkyl or a moiety represented by the following structural formula:

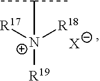

and
each cross-linking moiety is represented by structural formula (I). The remainder of features and example features of the second aspect is as described above with respect to the first aspect of the first embodiment.

In a third aspect of the first embodiment,

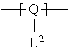

is a moiety represented by the following structural formula:

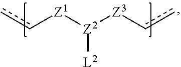

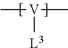

is a moiety represented by the following structural formula:

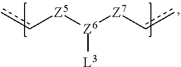

W is a C₁₋₁₂ alkyl or a moiety represented by the following structural formula:

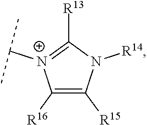

and each cross-linking moiety is represented by structural formula (I). The remainder of features and example features of the third aspect is as described above with respect to the first and second aspects of the first embodiment.

In a fourth aspect of the first embodiment,

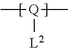

is a moiety represented by the following structural formula:

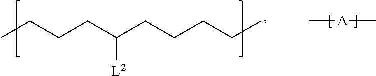

is a moiety represented by the following structural formula:

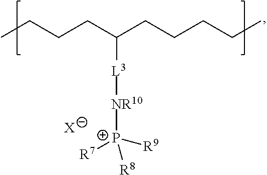

each third repeat unit is a C₈ alkylene, and each cross-linking moiety is represented by structural formula (I). The remainder of features and example features of the fourth aspect is as described above with respect to the first through third aspects of the first embodiment.

In a fifth aspect of the first embodiment,

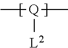

is a moiety represented by the following structural formula:

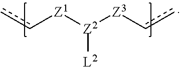

The remainder of features and example features of the fifth aspect is as described above with respect to the first through fourth aspects of the first embodiment.

In a sixth aspect of the first embodiment,

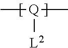

is a moiety represented by the following structural formula:

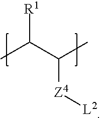

The remainder of features and example features of the sixth aspect is as described above with respect to the first through fifth aspects of the first embodiment.

In a seventh aspect of the first embodiment,

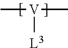

is a moiety represented by the following structural formula:

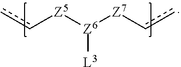

The remainder of features and example features of the seventh aspect is as described above with respect to the first through sixth aspects of the first embodiment.

In an eighth aspect of the first embodiment,

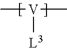

is a moiety represented by the following structural formula:

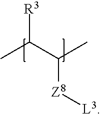

The remainder of features and example features of the eighth aspect is as described above with respect to the first through seventh aspects of the first embodiment.

In a ninth aspect of the first embodiment, the first cross-linked ionomer further comprises a plurality of third repeat units, wherein each third repeat unit is a moiety represented by the following structural formula:

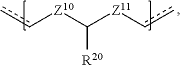

wherein
Z¹⁰ and Z¹¹ each independently is a C₁₋₃ alkylene or a bond;
R²⁰ is H, a C₁₋₁₂ alkyl, or a C₆₋₁₂ aryl.

In some instances, at least one third repeat unit is connected to the cross-linking moiety represented by through the point of attachment on the cross-linking moiety designated as [symbol] .

In a tenth aspect of the first embodiment, the each first repeat unit is a moiety represented by the following structural formula:

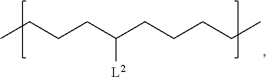

each second repeat unit is a moiety represented by the following structural formula:

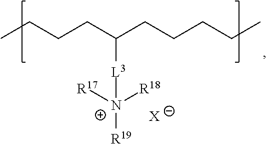

each third repeat unit is a Cs alkylene, and each cross-linking moiety is represented by structural formula (I). The remainder of features and example features of the tenth aspect is as described above with respect to the first through ninth aspects of the first embodiment.

In an eleventh aspect of the first embodiment, each first repeat unit is a moiety represented by the following structural formula:

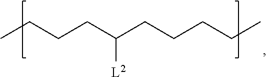

each second repeat unit is a moiety represented by the following structural formula:

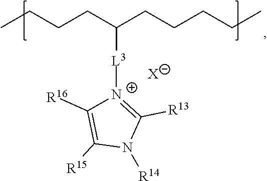

each third repeat unit is a Cs alkylene, and each cross-linking moiety is represented by structural formula (I). For example, R¹³, R¹⁴, R¹⁵, and R¹⁶ are methyl, and the molar ratio of the first repeat units, second repeat units, and third repeat units is 1:14:5. The remainder of features and example features of the eleventh aspect is as described above with respect to the first through tenth aspects of the first embodiment.

In a twelfth aspect of the first embodiment,

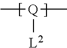

is a moiety represented by any one of the following structural formulas:

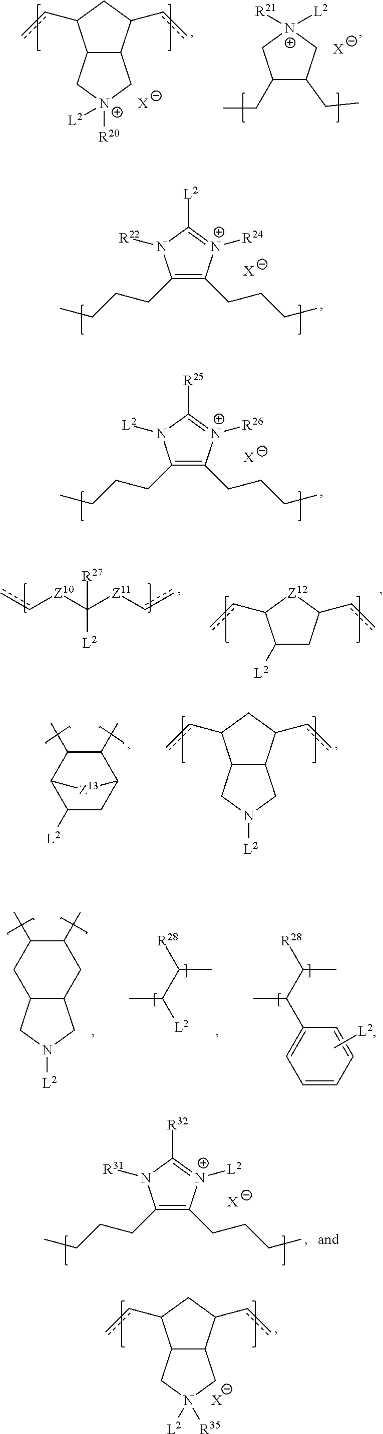

wherein:
R²⁰, R²², R²⁴, R²⁶, and R³¹ each independently is a C₁₋₁₂ alkyl;
R²¹ is a C₁₋₁₂ alkyl, or R²¹ together with the nitrogen atom to which it is attached and at least one atom of L² form a 5- to 12-membered heterocyclyl
R²⁵ and R³² each independently is a C₆₋₁₂ aryl;
R²⁷ is H or a C₁₋₁₂ alkyl;
R²⁸ is H, a C₁₋₁₂ alkyl, or a C₆₋₁₂ aryl;
R³⁵ is a C₁₋₁₂ alkyl, or R³⁵ together with the nitrogen atom to which it is attached and at least one atom of L² form a 5- to 12-membered heterocyclyl;
Z¹⁰ and Z¹¹ each independently is a C₁₋₃ alkylene or a bond; and
Z¹² and Z¹³ each independently is selected from CH₂, O, NH, and N(C₁₋₁₂ alkyl). The remainder of features and example features of the twelfth aspect is as described above with respect to the first through eleventh aspects of the first embodiment.

In a thirteenth aspect of the first embodiment,

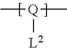

is a moiety represented by any one of the following structural formulas:

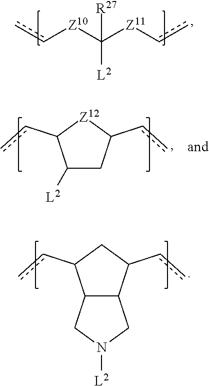

The remainder of features and example features of the thirteenth aspect is as described above with respect to the first through twelfth aspects of the first embodiment.

In a fourteenth aspect of the first embodiment,

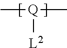

is a moiety represented by the following structural formula:

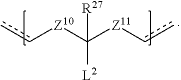

For example,

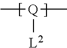

is a moiety represented by the following structural formula:

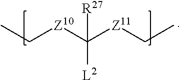

### Alternatively,

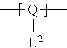

is a moiety represented by the following structural formula:

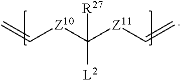

The remainder of features and example features of the fourteenth aspect is as described above with respect to the first through thirteenth aspects of the first embodiment.

In a fifteenth aspect of the first embodiment, Z¹⁰ and Z¹¹ each independently is a C₁₋₃ alkylene. For example, Z¹⁰ is C₂ alkylene and Z¹¹ is C₃ alkylene. The remainder of features and example features of the fifteenth aspect is as described above with respect to the first through fourteenth aspects of the first embodiment.

In a sixteenth aspect of the first embodiment, R²⁷ is H or methyl. The remainder of features and example features of the sixteenth aspect is as described above with respect to the first through fifteenth aspects of the first embodiment.

In a seventeenth aspect of the first embodiment,

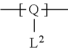

is a moiety represented by the following structural formula:

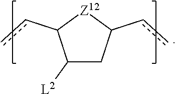

For example

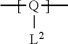

is a moiety represented by the following structural formula:

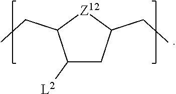

### Alternatively,

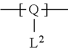

is a moiety represented by the following structural formula:

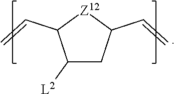

The remainder of features and example features of the seventeenth aspect is as described above with respect to the first through sixteenth aspects of the first embodiment.

In an eighteenth aspect of the first embodiment, Z¹² is CH₂, O, NH or N(C₁₋₁₂ alkyl). For example, Z¹² is CH₂ or O. Alternatively, Z¹² is NH or N(C₁₋₁₂ alkyl). The remainder of features and example features of the eighteenth aspect is as described above with respect to the first through seventeenth aspects of the first embodiment.

In a nineteenth aspect of the first embodiment,

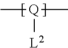

is a moiety represented by any one of the following structural formulas:

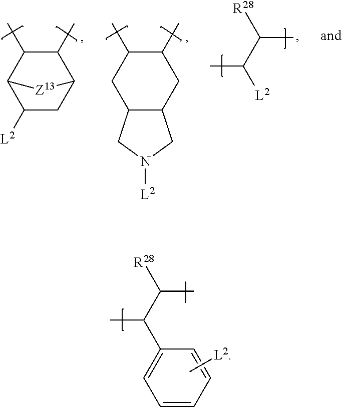

The remainder of features and example features of the nineteenth aspect is as described above with respect to the first through eighteenth aspects of the first embodiment.

In a twentieth aspect of the first embodiment,

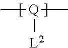

is a moiety represented by the following structural formula:

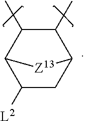

The remainder of features and example features of the twentieth aspect is as described above with respect to the first through nineteenth aspects of the first embodiment.

In a twenty-first aspect of the first embodiment, Z¹³ is CH₂, O, NH, or N(C₁₋₁₂ alkyl). For example, Z¹³ is CH₂ or O. Alternatively, Z¹³ is NH or N(C₁₋₁₂ alkyl). The remainder of features and example features of the twenty-first aspect is as described above with respect to the first through twentieth aspects of the first embodiment.

In a twenty-second aspect of the first embodiment,

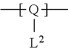

is a moiety represented by the following structural formula:

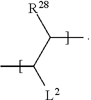

The remainder of features and example features of the twenty-second aspect is as described above with respect to the first through twenty-first aspects of the first embodiment.

In a twenty-third aspect of the first embodiment, R²⁸ is H or methyl. For example, R²⁸ is H. Alternatively, R²⁸ is methyl. The remainder of features and example features of the twenty-third aspect is as described above with respect to the first through twenty-second aspects of the first embodiment.

In a twenty-fourth aspect of the first embodiment,

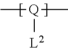

is a moiety represented by the following structural formula:

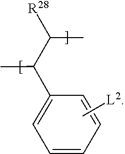

The remainder of features and example features of the twenty-fourth aspect is as described above with respect to the first through twenty-third aspects of the first embodiment.

In a twenty-fifth aspect of the first embodiment,

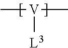

is a moiety represented by any one of the following structural formulas:

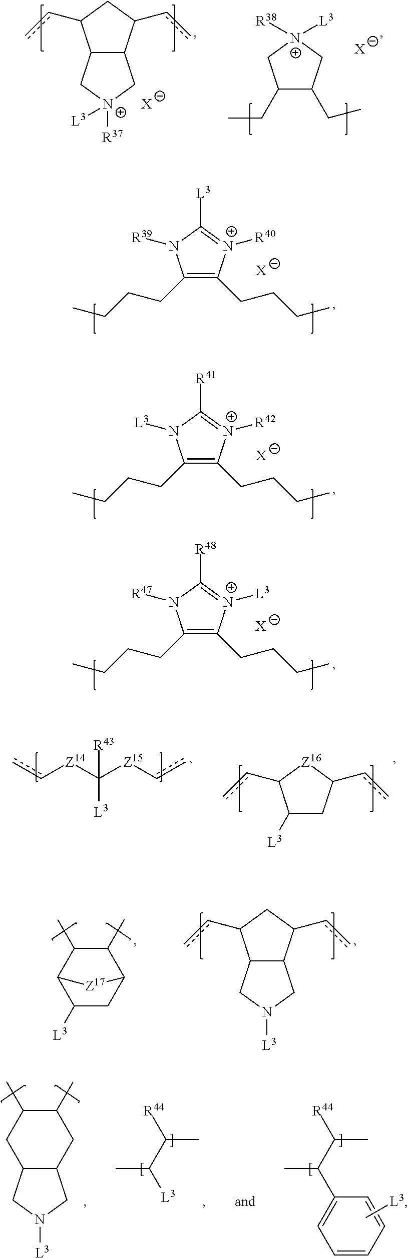

wherein:
R³⁹, R⁴⁰, R⁴², R⁴⁵, R⁴⁷, and R⁴⁹ each independently is a C₁₋₁₂ alkyl;
R⁴¹ and R⁴⁸ each independently is a C₆₋₁₂ aryl;
R⁴³ is H or a C₁₋₁₂ alkyl;
R⁴⁴ is H, a C₁₋₁₂ alkyl, or a C₆₋₁₂ aryl;
R³⁷ is a C₁₋₁₂ alkyl, or R³⁷ together with the nitrogen atom to which it is attached and at least one atom of L³ form a 5- to 12-membered heterocyclyl;
R³⁸ is a C₁₋₁₂ alkyl, or R³⁸ together with the nitrogen atom to which it is attached and at least one atom of L³ form a 5- to 12-membered heterocyclyl;
Z¹⁴ and Z¹⁵ each independently is a C₁₋₃ alkylene or a bond; and
Z¹⁶ and Z¹⁷ each independently is selected from CH₂, O, NH, and N(C₁₋₁₂ alkyl). The remainder of features and example features of the twenty-fifth aspect is as described above with respect to the first through twenty-fourth aspects of the first embodiment.

In a twenty-sixth aspect of the first embodiment,

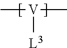

is a moiety represented by any one of the following structural formulas:

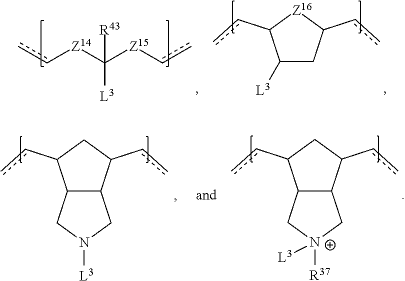

The remainder of features and example features of the twenty-sixth aspect is as described above with respect to the first through twenty-fifth aspects of the first embodiment.

In a twenty-seventh aspect of the first embodiment,

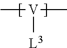

is a moiety represented by the following structural formula:

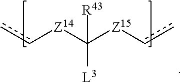

For example,

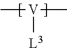

is a moiety represented by the following structural formula:

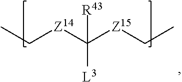

### Alternatively,

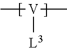

is a moiety represented by the following structural formula:

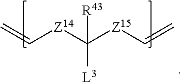

The remainder of features and example features of the twenty-seventh aspect is as described above with respect to the first through twenty-sixth aspects of the first embodiment.

In a twenty-eighth aspect of the first embodiment, Z¹⁴ and Z¹⁵ each independently is a C₁₋₃ alkylene. For example, Z¹⁴ is C₂ alkylene and Z¹⁵ is C₃ alkylene. The remainder of features and example features of the twenty-eighth aspect is as described above with respect to the first through twenty-seventh aspects of the first embodiment.

In a twenty-ninth aspect of the first embodiment, R⁴³ is H or methyl. For example, R⁴³ is H. Alternatively, R⁴³ is methyl. The remainder of features and example features of the twenty-ninth aspect is as described above with respect to the first through twenty-eighth aspects of the first embodiment.

In a thirtieth aspect of the first embodiment,

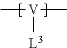

is a moiety represented by the following structural formula:

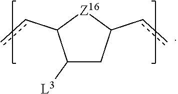

For example,

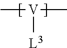

is a moiety represented by the following structural formula:

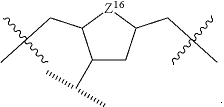

### Alternatively,

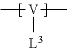

is a moiety represented by the following structural formula:

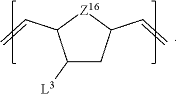

The remainder of features and example features of the thirtieth aspect is as described above with respect to the first through twenty-ninth aspects of the first embodiment.

In a thirty-first aspect of the first embodiment, Z¹⁶ is CH₂, O, NH or N(C₁₋₁₂ alkyl). For example, Z¹⁶ is CH₂ or O. Alternatively, Z¹⁶ is NH or N(C₁₋₁₂ alkyl). The remainder of features and example features of the thirty-first aspect is as described above with respect to the first through thirtieth aspects of the first embodiment.

In a thirty-second aspect of the first embodiment,

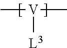

is a moiety represented by any one of the following structural formulas:

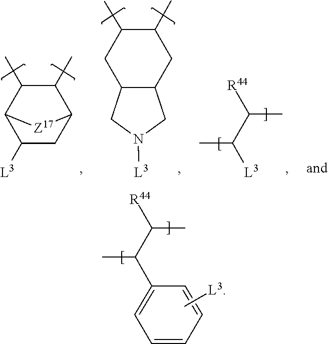

The remainder of features and example features of the thirty-second aspect is as described above with respect to the first through thirty-first aspects of the first embodiment.

In a thirty-third aspect of the first embodiment,

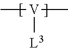

is a moiety represented by the following structural formula:

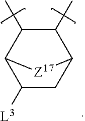

The remainder of features and example features of the thirty-third aspect is as described above with respect to the first through thirty-second aspects of the first embodiment.

In a thirty-fourth aspect of the first embodiment, Z¹³ is CH₂, O, NH or N(C₁₋₁₂ alkyl). For example, Z¹³ is CH₂ or O. Alternatively, Z¹³ is NH or N(C₁₋₁₂ alkyl). The remainder of features and example features of the thirty-fourth aspect is as described above with respect to the first through thirty-third aspects of the first embodiment.

In a thirty-fifth aspect of the first embodiment,

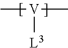

is a moiety represented by the following structural formula:

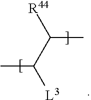

The remainder of features and example features of the thirty-fifth aspect is as described above with respect to the first through thirty-fourth aspects of the first embodiment.

In a thirty-sixth aspect of the first embodiment, R⁴⁴ is H or methyl. For example, R⁴⁴ is H. Alternatively, R⁴⁴ is methyl. The remainder of features and example features of the thirty-sixth aspect is as described above with respect to the first through thirty-fifth aspects of the first embodiment.

In a thirty-seventh aspect of the first embodiment,

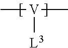

is a moiety represented by the following structural formula:

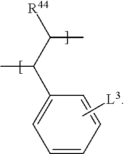

The remainder of features and example features of the thirty-seventh aspect is as described above with respect to the first through thirty-sixth aspects of the first embodiment.

In a thirty-eighth aspect of the first embodiment, W is

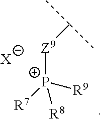

The remainder of features and example features of the thirty-eighth aspect is as described above with respect to the first through thirty-seventh aspects of the first embodiment.

In a thirty-ninth aspect of the first embodiment, Z⁹ is NR¹⁰; and R⁷, R⁸, and R⁹ each independently is NR¹¹R¹². The remainder of features and example features of the thirty-ninth aspect is as described above with respect to the first through thirty-eighth aspects of the first embodiment.

In a fortieth aspect of the first embodiment, Z⁹ is a bond and R⁷, R⁸, and R⁹ each independently is a C₆₋₁₂ aryl. For example, R⁷, R⁸, and R⁹ each is phenyl. The remainder of features and example features of the fortieth aspect is as described above with respect to the first through thirty-ninth aspects of the first embodiment.

In a forty-first aspect of the first embodiment, R¹¹ and R¹² each independently is C₁₋₁₂ alkyl or a C₃₋₁₂ cycloalkyl. For example, R¹¹ is a C₁₋₃ alkyl, and R¹² is a C₅₋₇ cycloalkyl or a C₁₋₃ alkyl. For example, R¹¹ and R¹² are each methyl; or R¹¹ is methyl and R¹² is isopropyl; or R¹¹ is cyclohexyl and R¹² is methyl. The remainder of features and example features of the forty-first aspect is as described above with respect to the first through fortieth aspects of the first embodiment.

In a forty-second aspect of the first embodiment, W is

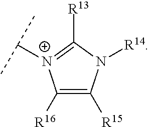

The remainder of features and example features of the forty-second aspect is as described above with respect to the first through forty-first aspects of the first embodiment.

In a forty-third aspect of the first embodiment, R¹³ is an unsubstituted C₆₋₁₂ aryl. For example, R¹³ is an unsubstituted phenyl. Alternatively, R¹³ is a C₆₋₁₂ aryl substituted with 1 to 3 substituents independently selected from a C₁₋₁₂ alkyl, C₁₋₁₂ alkoxy, and N(C₁₋₁₂ alkyl)₂. For example, R¹³ is a C₆₋₁₂ aryl substituted with 1 to 3 substituents independently selected from methyl, ethyl, propyl, isopropyl, methoxy, ethoxy, propoxy, isopropoxy, dimethylamino, or diethylamino, such as phenyl substituted with 1 to 3 substituents independently selected from methyl, ethyl, propyl, isopropyl, methoxy, ethoxy, propoxy, isopropoxy, dimethylamino, or diethylamino. The remainder of features and example features of the forty-third aspect is as described above with respect to the first through forty-second aspects of the first embodiment.

In a forty-fourth aspect of the first embodiment, R¹⁴ is a C₁₋₁₂ alkyl. For example, R¹⁴ is methyl, ethyl, propyl, isopropyl, butyl, sec-butyl, isobutyl, or tert-butyl. Alternatively, R¹⁴ is a C₃₋₈ cycloalkyl, such as cyclopropyl, cyclobutyl, cyclopentyl, or cyclohexyl. The remainder of features and example features of the forty-fourth aspect is as described above with respect to the first through forty-third aspects of the first embodiment.

In a forty-fifth aspect of the first embodiment, R¹⁵ and R¹⁶ each independently is a C₁₋₁₂ alkyl. For example, R¹⁵ and R¹⁶ each independently is methyl, ethyl, propyl, isopropyl, butyl, sec-butyl, isobutyl, or tert-butyl. For example, R¹⁵ and R¹⁶ each is methyl. The remainder of features and example features of the forty-fifth aspect is as described above with respect to the first through forty-fourth aspects of the first embodiment.

In a forty-sixth aspect of the first embodiment, R¹⁵ and R¹⁶ each independently is a C₆₋₁₂ aryl. For example, R¹⁵ and R¹⁶ are each phenyl. The remainder of features and example features of the forty-sixth aspect is as described above with respect to the first through forty-fifth aspects of the first embodiment.

In a forty-seventh aspect of the first embodiment, R¹⁵ and R¹⁶ together with the carbon atoms to which they are attached form a C₆₋₁₂ aryl. For example, R¹⁵ and R¹⁶ together with the carbon atoms to which they are attached form a C₆ aryl. The remainder of features and example features of the forty-seventh aspect is as described above with respect to the first through forty-sixth aspects of the first embodiment.

In a forty-eighth aspect of the first embodiment, W is

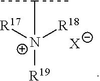

The remainder of features and example features of the forty-eighth aspect is as described above with respect to the first through forty-seventh aspects of the first embodiment.

In a forty-ninth aspect of the first embodiment, R¹⁷, R¹⁸, and R¹⁹ each independently is selected from a C₁₋₁₂ alkyl. For example, R¹⁷, R¹⁸, and R¹⁹ each is methyl. The remainder of features and example features of the forty-ninth aspect is as described above with respect to the first through forty-eighth aspects of the first embodiment.

In a fiftieth aspect of the first embodiment, R¹⁷ is a C₁₋₁₂ alkyl and R¹⁸, and R¹⁹ together with the nitrogen atom to which they are attached form a 5 to 12-membered heterocyclyl. The remainder of features and example features of the fiftieth aspect is as described above with respect to the first through forty-ninth aspects of the first embodiment.

In a fifty-first aspect of the first embodiment, R¹⁷, R¹⁸, and R¹⁹ together with the nitrogen atom to which they are attached form a bicyclic 5 to 12-membered heterocyclyl. The remainder of features and example features of the fifty-first aspect is as described above with respect to the first through fiftieth aspects of the first embodiment.

In a fifty-second aspect of the first embodiment, L² is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₘ, (C₁₋₁₂ alkylene-O)ₘ, C(O)(O—C₁₋₁₂ alkylene)ₘ, OC(O)(C₁₋₁₂ alkylene)ₘ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₘ, (NH)C(O—C₁₋₁₂ alkylene)ₘ, (NH—C₁₋₁₂ alkylene)ₘ, and (C₁₋₁₂ alkylene-NH)ₘ. Each of the moieties representing L² can be attached to Q by either end of the moiety. For example, if L² is OC(O)(C₁₋₁₂ alkylene)ₘ, it can be attached to Q through the ester or through the alkylene. In some instances, L² is a C₁₋₁₂ alkylene. For example, L² is C₁ alkylene, C₂ alkylene, C₃ alkylene, C₄ alkylene, C₅ alkylene, C₆ alkylene, C₇ alkylene, C₈ alkylene, C₉ alkylene, C₁₀ alkylene, C₁₁ alkylene, or C₁₂ alkylene. The remainder of features and example features of the fifty-second aspect is as described above with respect to the first through fifty-first aspects of the first embodiment.

In a fifty-third aspect of the first embodiment, L² is (O—C₁₋₁₂ alkylene)ₘ or (C₁₋₁₂ alkylene-O)ₘ. For example, L² is —CH₂O— or —OCH₂—. The remainder of features and example features of the fifty-third aspect is as described above with respect to the first through fifty-second aspects of the first embodiment.

In a fifty-fourth aspect of the first embodiment, m is 1, 2, 3, 4, 5, or 6. For example, m is 1. The remainder of features and example features of the fifty-fourth aspect is as described above with respect to the first through fifty-third aspects of the first embodiment.

In a fifty-fifth aspect of the first embodiment, L³ is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₙ, (C₁₋₁₂ alkylene-O)ₙ, C(O)(O—C₁₋₁₂ alkylene)ₙ, OC(O)(C₁₋₁₂ alkylene)ₙ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₙ, (NH)C(O—C₁₋₁₂ alkylene)ₙ, (NH—C₁₋₁₂ alkylene)ₙ, (C₁₋₁₂ alkylene-NH), and a bond. Each of the moieties representing L³ can be attached to Q by either end of the moiety. For example, if L³ is OC(O)(C₁₋₁₂ alkylene)ₙ, it can be attached to Q through the ester or through the alkylene. In some instances, L³ is a C₁₋₁₂ alkylene. For example, L³ is C₁ alkylene, C₂ alkylene, C₃ alkylene, C₄ alkylene, C₅ alkylene, C₆ alkylene, C₇ alkylene, C₈ alkylene, C₉ alkylene, C₁₀ alkylene, C₁₁ alkylene, or C₁₂ alkylene. For example, L³ is methylene. The remainder of features and example features of the fifty-fifth aspect is as described above with respect to the first through fifty-fourth aspects of the first embodiment.

In a fifty-sixth aspect of the first embodiment, L³ is (O—C₁₋₁₂ alkylene)ₙ or (C₁₋₁₂ alkylene-O)ₙ. For example, L³ is —CH₂O— or —OCH₂—. The remainder of features and example features of the fifty-sixth aspect is as described above with respect to the first through fifty-fifth aspects of the first embodiment.

In a fifty-seventh aspect of the first embodiment, n is 1, 2, 3, 4, 5, or 6. For example, n is 1. The remainder of features and example features of the fifty-seventh aspect is as described above with respect to the first through fifty-sixth aspects of the first embodiment.

In a fifty-eighth aspect of the first embodiment,

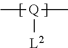

is a moiety represented by the following structural formula:

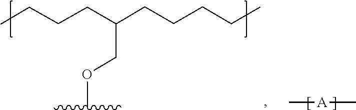

is a moiety represented by the following structural formula:

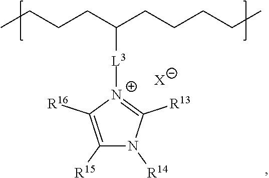

each third repeat unit is a Cs alkylene, and each cross-linking moiety is represented by structural formula (I). The remainder of features and example features of the fifty-eighth aspect is as described above with respect to the first through fifty-seventh aspects of the first embodiment.

In a fifty-ninth aspect of the first embodiment,

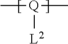

is a moiety represented by the following structural formula:

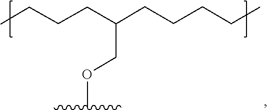

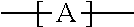

is a moiety represented by the following structural formula:

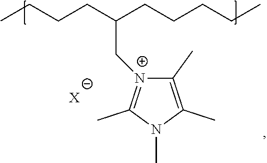

each third repeat unit is a C₈ alkylene, each cross-linking moiety is represented by structural formula (I), and the molar ratio of the first repeat units, second repeat units, and third repeat units is 1:14:5.

In a sixtieth aspect of the first embodiment, the cross-linkable precursor ionomer comprises from about 0.5 mol-% to about 15 mol-% of the first repeat units. For example, the first ionomer comprises from about 0.5 mol-% to about 15 mol-%, from about 1 mol-% to about 14 mol-%, from about 2 mol-% to about 12 mol-%, from about 3 mol-% to about 10 mol-%, from about 0.5 mol-% to about 10 mol-%, from about 0.5 mol-% to about 7 mol-%, from about 0.5 mol-% to about 10 mol-%, from about 0.5 mol-% to about 10 mol-%, from about 1 mol-% to about 10 mol-%, from about 1 mol-% to about 7 mol-%, from about 1 mol-% to about 5 mol-%, or from about 2 mol-% to about 7 mol-% of the first repeat units. For example, the first ionomer comprises about 0.5 mol-%, about 1 mol-%, about 2 mol-%, about 3 mol-%, about 4 mol-%, about 5 mol-%, about 6 mol-%, about 7 mol-%, about 8 mol-%, about 9 mol-%, about 10 mol-%, about 11 mol-%, about 12 mol-% about 13 mol-%, about 14 mol-%, or about 15 mol-% of the first repeat units. For example, the first ionomer comprises about 5 mol-% of the first repeat units. The remainder of features and example features of the sixtieth aspect is as described above with respect to the first through fifty-ninth aspects of the first embodiment.

In a sixty-first aspect of the first embodiment, the cross-linkable precursor ionomer comprises from about 20 mol-% to about 98 mol-% of the second repeat units. For example, the first ionomer comprises from about 20 mol-% to about 95 mol-%, from about 20 mol-% to about 90 mol-%, from about 20 mol-% to about 80 mol-%, from about 20 mol-% to about 70 mol-%, from about 20 mol-% to about 60 mol-%, from about 20 mol-% to about 50 mol-%, from about 30 mol-% to about 80 mol-%, from about 30 mol-% to about 70 mol-%, from about 40 mol-% to about 90 mol-%, from about 50 mol-% to about 90 mol-%, from about 50 mol-% to about 80 mol-%, or from about 60 mol-% to about 90 mol-% of the second repeat units. For example, the first ionomer comprises about 20 mol-%, about 25 mol-%, about 30 mol-%, about 35 mol-%, about 40 mol-%, about 45 mol-%, about 50 mol-%, about 55 mol-%, about 60 mol-%, about 65 mol-%, about 70 mol-%, about 75 mol-%, about 80 mol-% about 85 mol-%, about 90 mol-%, or about 95 mol-% of the second repeat units. For example, the first ionomer comprises about 28 mol-% of the second repeat units. The remainder of features and example features of the sixty-first aspect is as described above with respect to the first through sixtieth aspects of the first embodiment.

In a sixty-second aspect of the first embodiment, the cross-linkable precursor ionomer comprises from about 0 mol-% to about 70 mol-% of the third repeat units. For example, the first ionomer comprises from about 0 mol-% to about 60 mol-%, from about 0 mol-% to about 50 mol-%, from about 0 mol-% to about 40 mol-%, from about 0 mol-% to about 30 mol-%, from about 0 mol-% to about 20 mol-%, from about 0 mol-% to about 10 mol-%, from about 50 mol-% to about 70 mol-%, from about 5 mol-% to about 50 mol-%, from about 5 mol-% to about 40 mol-%, from about 10 mol-% to about 80 mol-%, from about 10 mol-% to about 50 mol-%, or from about 10 mol-% to about 40 mol-% of the third repeat units. For example, the first ionomer comprises about 0 mol-%, about 5 mol-%, about 10 mol-%, about 15 mol-%, about 20 mol-%, about 25 mol-%, about 30 mol-%, about 35 mol-%, about 40 mol-%, about 45 mol-%, about 50 mol-%, about 55 mol-%, about 60 mol-%, about 65 mol-%, or about 90 mol-% of the third repeat units. For example, the first ionomer comprises about 67 mol-% of the third repeat units.

The remainder of features and example features of the sixty-second aspect is as described above with respect to the first through sixty-first aspects of the first embodiment.

In a sixty-third aspect of the first embodiment, the moiety

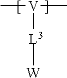

is represented by the following structural formula:

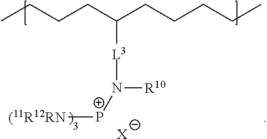

For example, the moiety

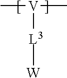

is represented by the following structural formula:

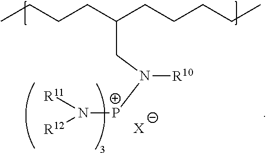

The remainder of features and example features of the sixty-third aspect is as described above with respect to the first through sixty-second aspects of the first embodiment.

In a sixty-fourth aspect of the first embodiment, the moiety

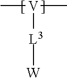

is represented by the following structural formula:

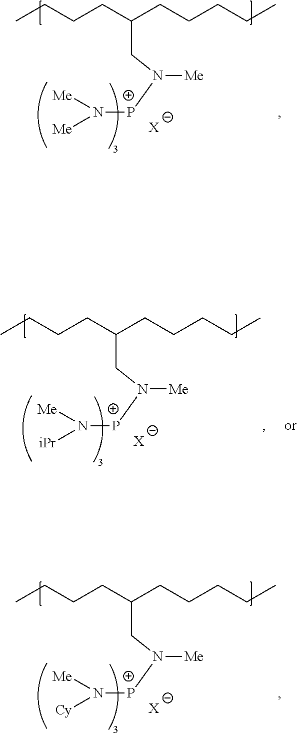

wherein Me is methyl, iPr is isopropyl and Cy is cyclohexyl. The remainder of features and example features of the sixty-fourth aspect is as described above with respect to the first through sixty-third aspects of the first embodiment.

In a sixty-fifth aspect of the first embodiment, the cross-linking moiety is represented by one of the following structural formulas:

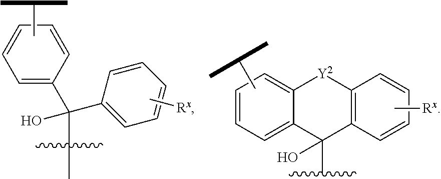

For example, the cross-linking moiety is represented by the following structural formula:

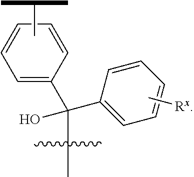

For example, the cross-linking moiety is represented by the following structural formula:

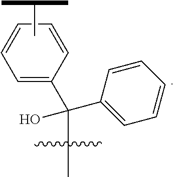

The remainder of features and example features of the sixty-fifth aspect is as described above with respect to the first through sixty-fourth aspects of the first embodiment.

In a sixty-sixth aspect of the first embodiment, the number average molecular weight (MWn) of the cross-linkable precursor ionomer is from about 30,000 g/mol to about 500,000 g/mol. For example, the MWn of the cross-linkable precursor ionomer is from about 50,000 g/mol to about 360,000 g/mol, such as about 120,000 g/mol. The remainder of features and example features of the sixty-sixth aspect is as described above with respect to the first through sixty-fifth aspects of the first embodiment.

In a sixty-seventh aspect of the first embodiment, the cross-linkable precursor ionomer comprises from about 10 mol-% to about 80 mol-% of the second repeat units. For example, the cross-linkable precursor ionomer comprises from about 20 mol-% to about 60 mol-% of the second repeat units, such as about 28 mol-%, about 46 mol-%, or about 70 mol-%. The remainder of features and example features of the sixty-seventh aspect is as described above with respect to the first through sixty-sixth aspects of the first embodiment.

In a sixty-eighth aspect of the first embodiment, R^{x} is H. Alternatively, R^{x} is selected from F, Cl, Br, OH, NH₂, NO₂, CN, and C₁₋₁₂ alkyl. For example, R^{x} is selected from F, Cl, CN, and C₁₋₆ alkyl. For example, R^{x} is selected from F, Cl, and C₁₋₃ alkyl. The remainder of features and example features of the sixty-eighth aspect is as described above with respect to the first through sixty-seventh aspects of the first embodiment. The remainder of features and example features of the sixty-eighth aspect is as described above with respect to the first through sixty-seventh aspects of the first embodiment.

In a sixty-ninth aspect of the first embodiment, the cross-linkable moiety is represented by one of the following structural formulas:

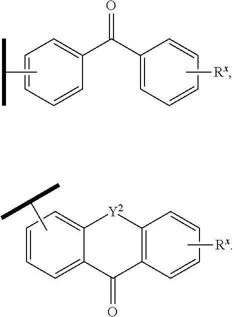

For example, the cross-linkable moiety is represented by the following structural formula:

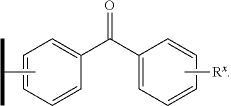

For example, the cross-linkable moiety is represented by structural formula (I):

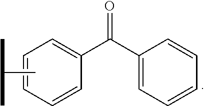

The remainder of features and example features of the sixty-eighth aspect is as described above with respect to the first through sixty-fourth aspects of the first embodiment.

In a seventieth aspect of the first embodiment, the polymer film comprises from about 20 wt. % to about 80 wt. % of the cross-linked product ionomer. For example, the polymer film comprises from about 20 mol-% to about 70 mol-%, from about 20 mol-% to about 60 mol-%, from about 20 mol-% to about 50 mol-%, from about 30 mol-% to about 80 mol-%, from about 30 mol-% to about 70 mol-%, from about 40 mol-% to about 80 mol-%, from about 40 mol-% to about 70 mol-%, from about 40 mol-% to about 60 mol-%, from about 40 mol-% to about 50 mol-%, from about 50 mol-% to about 80 mol-%, from about 50 mol-% to about 80 mol-%, or from about 50 mol-% to about 60 mol-% of the cross-linked product ionomer. For example, the first ionomer comprises about 20 mol-%, about 25 mol-%, about 30 mol-%, about 35 mol-%, about 40 mol-%, about 45 mol-%, about 50 mol-%, about 55 mol-%, about 60 mol-%, about 65 mol-%, about 70 mol-%, about 75 mol-%, or about 80 mol-% of the cross-linked product ionomer. For example, the polymer film comprises about 28 mol-% of the cross-linked product ionomer. The remainder of features and example features of the seventieth aspect is as described above with respect to the first through sixty-ninth aspects of the first embodiment.

In a second embodiment the present disclosure relates to an electrode comprising a catalyst/ionomer layer, wherein the catalyst/ionomer layer comprises a polymer film as described herein with respect to the first embodiment and various aspects thereof, and a catalyst.

In the first aspect of the second embodiment, the catalyst is dispersed within the polymer film. For example, the particles of the catalyst are evenly distributed throughout the polymer film.

In the second aspect of the second embodiment, the catalyst is disposed on the polymer film.

In the third aspect of the second embodiment, the catalyst comprises:
i) a metal selected from Ni, Fe, Ru, Ir, Co, Mn, Pt, Pd, Mo, and, La, or a combination thereof; and/or (ii) an oxide of a metal selected from Ni, Fe, Ru, Ir, Co, Mn, Pt, Pd, Mo, and La, or a combination thereof. For example, the catalyst comprises a metal selected from Ni, Fe, Ru, Ir, Co, Mn, Pt, Pd, Mo, and, La, or a combination thereof. For example, the catalyst comprises an oxide of a metal selected from Ni, Fe, Ru, Ir, Co, Mn, Pt, Pd, Mo, and La, or a combination thereof. In some embodiments of the third aspect, the catalyst is supported on carbon. In some embodiments of the third aspect, the catalyst is selected from Pt, Pt supported on carbon (Pt/C), Pt and Ru supported on carbon (PtRu/C), Pd, Pd supported on carbon (Pd/C), Ir, IrO₂, IrRuO, RuO₂, Raney nickel (Al/Ni), Ni_{0.5}Co_{0.5}Fe₂O₄, NiCoO₂, NiFe, NiFe₂O₄, NiO, NiMo, Ni and Mo supported on carbon (NiMo/C), FeCoNi, Fe₂O₃, LaCoO₃, LiNiO₂, LiCoO₂, Co₃O₄, CoFe₂O₄, CoO, MnO, Mn₂O₃, MnO₂, and Mn₃O₄, or a combination thereof. For example, the catalyst is selected from Pt, Pt/C, Ir, IrO₂, IrRuO, RuO₂, Ni_{0.5}Co_{0.5}Fe₂O₄, and NiCoO₂, or a combination thereof. For example, the catalyst is Ni_{0.5}Co_{0.5}Fe₂O₄ or NiFe₂O₄. In some embodiments of the third aspect, the catalyst is selected Raney nickel (Al/Ni), Ni_{0.5}Co_{0.5}Fe₂O₄, NiCoO₂, NiFe, NiFe₂O₄, NiO, NiMo, Ni and Mo supported on carbon (NiMo/C), FeCoNi, Fe₂O₃, LaCoO₃, LiNiO₂, LiCoO₂, Co₃O₄, CoFe₂O₄, CoO, MnO, Mn₂O₃, MnO₂, and Mn₃O₄. The remainder of features and example features of the third aspect is as described above with respect to the first and second aspects of the second embodiment.

In a fourth aspect of the second embodiment, the catalyst/ionomer layer comprises about 50-97 wt. % catalyst and about 3-50 wt. % polymer film. For example, the catalyst/ionomer layer comprises about 50-95 wt. % catalyst and about 5-50 wt. % polymer film, about 60-95 wt. % catalyst and about 5-40 wt. % polymer film, about 70-95 wt. % catalyst and about 5-30 wt. % polymer film, about 60-90 wt. % catalyst and about 10-40 wt. % polymer film, about 65-90 wt. % catalyst and about 10-35 wt. % polymer film, about 70-90 wt. % catalyst and about 10-30 wt. % polymer film, about 75-90 wt. % catalyst and about 10-25 wt. % ionomer, about 65-95 wt. % catalyst and about 5-35 wt. % ionomer, about 70-95 wt. % catalyst and about 5-30 wt. % polymer film, about 75-95 wt. % catalyst and about 5-25 wt. % polymer film, about 65-85 wt. % catalyst and about 15-35 wt. % polymer film, about 65-80 wt. % catalyst and about 20-35 wt. % polymer film. For example, the catalyst/ionomer layer comprises about 80-90 wt. % catalyst and about 10-20 wt. % polymer film. The remainder of features and example features of the fourth aspect is as described above with respect to the first through third aspects of the second embodiment.

In a second embodiment the present disclosure relates to a composite material, comprising a polymer film as described herein with respect to the first embodiment and various aspects thereof, or an electrode as described herein with respect to the second embodiment and various aspects thereof, and a support, wherein the polymer film or the electrode is disposed on the support.

In a first aspect of the third embodiment, the support comprises a polyolefin, a polyphenylene, a polyester, a polyamide, or a polysulfone.

In a second aspect of the third embodiment, the support comprises a perfluorinated polyolefin. For example, the support comprises polytetrafluoroethylene (PTFE). The remainder of features and example features of the second aspect is as described above with respect to the first aspect of the third embodiment.

In a third aspect of the third embodiment, the support comprises polyethylene, polypropylene, polytetrafluoroethylene, polyvinyl chloride, or polyvynyldifluoroethylene. For example, the support comprises polyethylene. Alternatively or additionally, the support comprises polypropylene. Alternatively or additionally, the support comprises PTFE. The remainder of features and example features of the third aspect is as described above with respect to the first and second aspects of the third embodiment.

As used herein, the term “polyolefin” refers to a polymer comprising a plurality of repeat units represented by the following structural formula:

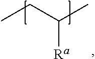

where R^{a} is H, Cl, or C₁₋₁₂ alkyl. If R^{a} is H, the polyolefin is polyethylene. If R^{a} is methyl, the polyolefin is polypropylene. If R^{a} is Cl, the polyolefin is polyvinyl chloride.

As used herein, the term “polyester” refers to a polymer formed through a condensation reaction between a dicarboxylic acid and a diol, which comprises a plurality of ester groups in its backbone. For example, a polyester can comprise a repeat unit represented by the following structural formula:

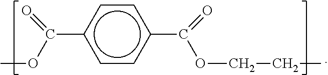

As used herein, the term “polyphenylene” refers to a polymer comprising a plurality of repeat units represented by the following structural formula:

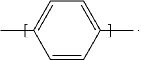

As used herein, the term “polyamide” refers to a polymer formed through a condensation reaction between a dicarboxylic acid and a diamine, which comprises a plurality of amide groups in its backbone. For example, a polyamide can comprise a repeat unit represented by one of the following structural formulas:

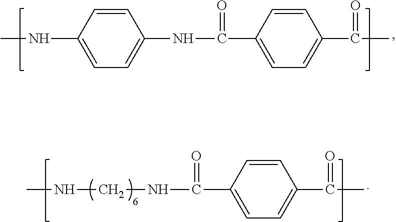

As used herein, the term “polysulfone” refers to a polymer comprising a plurality of “aryl-S(O)₂-aryl” subunits in the backbone of the polymer. For example, a polysulfone can comprise a repeat unit represented by one of the following structural formulas:

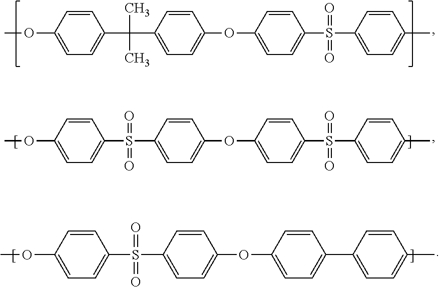

As used herein, the term “polyvynyldifluoroethylene” refers to a polymer comprising a plurality of repeat units represented by the following structural formula:

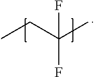

As used herein, the term “polytetrafluoroethylene” refers to a polymer comprising a plurality of repeat units represented by the following structural formula:

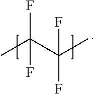

In a fourth aspect of the third embodiment, the support comprises a support ionomer. For example, the support ionomer is a cross-linked ionomer comprising:
a plurality of fourth repeat units, wherein each fourth repeat unit is a moiety represented by structural formula

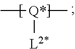

a plurality of fifth repeat units, wherein each fifth repeat unit is a moiety represented by structural formula

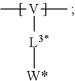

and
a plurality of cross-linking moieties, wherein each crosslinking moiety is represented by one of the following structural formulas:

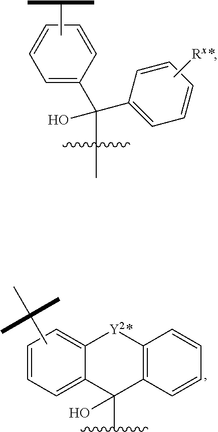

wherein, for each occurrence of the cross-linking moiety, the symbol [symbol] represents a point of attachment to L²* and the symbol [symbol] represents a point of attachment to a fourth repeat unit or a fifth repeat unit; and further wherein:

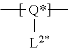

is a moiety represented by one of the following structural formulas:

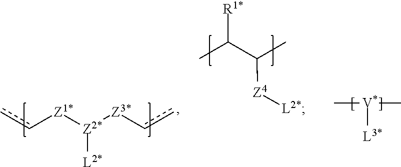

is a moiety represented by one of the following structural formulas:

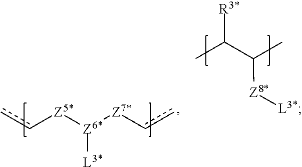

W* is C₁₋₁₂ alkyl or a moiety represented by one of the structural formulas selected from:

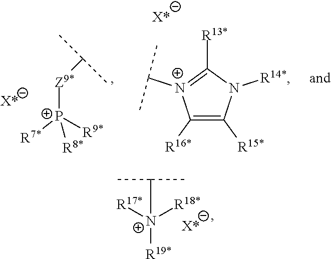

wherein the symbol [symbol] represents a point of attachment to L³*, and the symbol [symbol] represents a double bond or a single bond;
Z¹*, Z³*, Z⁵*, and Z⁷* each independently is a C₁₋₃ alkylene or a bond;
Z²* is selected from —CHR⁵*—, a C₅₋₁₂ cycloalkylene, and a 5 to 16-membered heterocyclylene;
R¹* is selected from H, a C₁₋₁₂ alkyl, and C₆₋₁₂ aryl, and
Z⁴* is a bond or a C₆₋₁₂ arylene, or
Z⁴* is CH, and R¹* and Z⁴* together with the C₂ alkylene to which they are attached form a C₅₋₁₂ cycloalkyl or a 5 to 12-membered heterocyclyl; and
Z⁶* is selected from —CHR⁶—, a C₅₋₁₂ cycloalkylene, and a 5 to 16-membered heterocyclylene;
R³* is selected from H, a C₁₋₁₂ alkyl, and C₆₋₁₂ aryl, and
Z⁸* is a bond or a C₆₋₁₂ arylene, and CH, or
Z⁸* is CH, and R³* and Z⁸* together with the C₂ alkylene to which they are attached form a C₅₋₁₂ cycloalkyl or a 5 to 12-membered heterocyclyl; and
Z⁹* is NR¹⁰* or a bond;
R⁵* and R⁶* each independently is H or a C₁₋₁₂ alkyl;
R⁷*, R⁸*, and R⁹* each independently is selected from NR¹¹*R¹²*, a C₆₋₁₂ aryl, and 5 to 12-membered heterocyclyl;
R¹⁰* is a C₁₋₁₂ alkyl;
R¹¹* and R¹²* each independently is C₁₋₁₂ alkyl or a C₃₋₁₂ cycloalkyl, or R¹¹* and R¹²* together with the nitrogen atom to which they are attached form a 5 to 12-membered heterocyclyl;
R¹³* is selected from a C₁₋₁₂ alkyl, C₆₋₁₂ aryl, and 5 to 12-membered heterocyclyl;
R¹⁴* is a C₁₋₁₂ alkyl or C₃₋₁₂ cycloalkyl;
R¹⁵* and R¹⁶* each independently is selected from C₁₋₁₂ alkyl, C₆₋₁₂ aryl, and 5 to 12-membered heterocyclyl; or R¹⁵* and R¹⁶* together with the carbon atoms to which they are attached form a C₆₋₁₂ aryl or a 5 to 12-membered heterocyclyl; and
R¹⁷*, R¹⁸*, and R¹⁹* each independently is a C₁₋₁₂ alkyl or a C₃₋₁₂ cycloalkyl; or
R¹⁸* and R¹⁹* together with the nitrogen atom to which they are attached form a 5 to 12-membered heterocyclyl and (i) R¹⁷* is a C₁₋₁₂ alkyl or a C₃₋₁₂ cycloalkyl, or (ii) R¹⁷* and at least one atom of L³*, if present, together with the nitrogen atom to which L³* and R¹⁷* are attached form a 5- to 12-membered heterocyclyl; or
R¹⁷*, R¹⁸*, and R¹⁹* together with the nitrogen atom to which they are attached form a bicyclic 5 to 12-membered heterocyclyl;
R^{x}* is selected from H, F, Cl, Br, OH, NH₂, NO₂, CN, C₁₋₁₂ alkyl, C₆₋₁₂ aryl, 5 to 12-membered heterocyclyl, and 5 to 12-membered heteroaryl;
L²* is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₘ*, (C₁₋₁₂ alkylene-O)ₘ*, C(O)(O—C₁₋₁₂ alkylene)ₘ*, OC(O)(C₁₋₁₂ alkylene)ₘ*, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₘ*, (NH)C(O—C₁₋₁₂ alkylene)ₘ*, (NH—C₁₋₁₂ alkylene)ₘ*, and (C₁₋₁₂ alkylene-NH)ₘ*;
L³* is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₙ*, (C₁₋₁₂ alkylene-O)ₙ*, C(O)(O—C₁₋₁₂ alkylene)ₙ*, OC(O)(C₁₋₁₂ alkylene)ₙ*, C₁₋₁₂ alkylene-NH-C₁₋₁₂ alkylene, C₁₋₁₂ alkylene-N(C₁₋₁₂ alkyl)-C₁₋₁₂ alkylene, C(O)(NH—C₁₋₁₂ alkylene)ₙ*, (NH)C(O—C₁₋₁₂ alkylene)ₙ*, (NH—C₁₋₁₂ alkylene)ₙ*, (C₁₋₁₂ alkylene-NH)ₙ*, and a bond;
m* is an integer between 1 and 6;
n* is an integer between 1 and 6;
Y²* is selected from —C(═O)—, O, S, NH, N(C₁₋₁₂ alkyl), and a bond;
X*⁻ is selected from F⁻, Cl⁻, Br⁻, OH⁻, NO⁻₂, CN⁻, HCO₃⁻, CO₃²⁻, PF₆⁻, BF₄⁻, and a C₁₋₁₂ carboxylate;
provided that W* is C₁₋₁₂ alkyl only when V* is a cationic moiety, and wherein:
each C₁₋₁₂ alkylene, C₆₋₁₂ arylene, C₅₋₁₂ cycloalkylene, 5 to 16-membered heterocyclylene, C₁₋₁₂alkyl, C₃₋₁₂cycloalkyl, C₅₋₁₂cycloalkyl, C₆₋₁₂ aryl, and 5 to 12-membered heterocyclyl is independently optionally substituted with 1 to 6 substituents independently selected from the group consisting of F, Cl, Br, OH, NH₂, NO₂, oxo, CN, a C₁₋₁₂ alkyl, C₆₋₁₂ aryl, C₁₋₁₂haloalkyl, C₁₋₁₂ alkoxy, C₆₋₁₂ aryl, C₆₋₁₂ aryloxy, 5 to 12-membered heterocyclyl, 5 to 12-membered heteroaryl, NH(C₁₋₁₂ alkyl), N(C₁₋₁₂ alkyl)₂, OC(O)(C₁₋₁₂ alkyl), C(O)O(C₁₋₁₂ alkyl), S(O)₂(C₁₋₁₂ alkyl), S(O)₂(C₆₋₁₂ aryl), NHC(O)(C₁₋₁₂ alkyl), and C(O)NH(C₁₋₁₂ alkyl). The remainder of features and example features of the fourth aspect is as described above with respect to the first through third aspects of the third embodiment.

In a fifth aspect of the third embodiment,

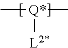

is a moiety represented by the following structural formula:

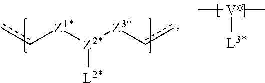

is a moiety represented by the following structural formula:

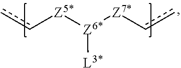

W* is a C₁₋₁₂ alkyl or a moiety represented the following structural formula:

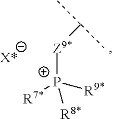

and each cross-linking moiety is represented by the following structural formula:

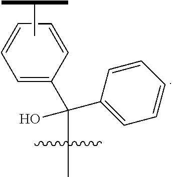

The remainder of features and example features of the fifth aspect is as described above with respect to the first through fourth aspects of the third embodiment.

In a sixth aspect of the third embodiment,

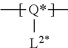

is a moiety represented by the following structural formula:

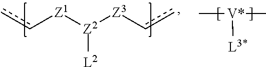

is a moiety represented by the following structural formula:

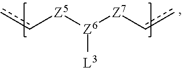

W* is a C₁₋₁₂ alkyl or a moiety represented the following structural formula:

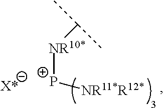

and each cross-linking moiety is represented by the following structural formula:

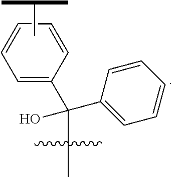

The remainder of features and example features of the sixth aspect is as described above with respect to the first through fifth aspects of the third embodiment.
described above with respect to the first through eighth aspects of the third embodiment.

In a seventh aspect of the third embodiment,

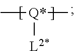

is moiety represented by the following structural formula:

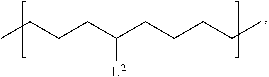

and each fifth repeat unit is a moiety represented by structural formula by the following structural formula:

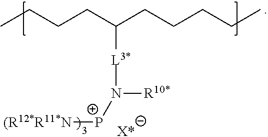

The remainder of features and example features of the seventh aspect is as described above with respect to the first through sixth aspects of the third embodiment.

In an eighth aspect of the third embodiment,

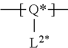

is a moiety represented by the following structural formula:

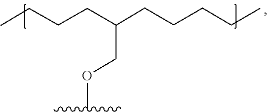

and each fifth repeat unit is a moiety represented by one of the following structural formulas:

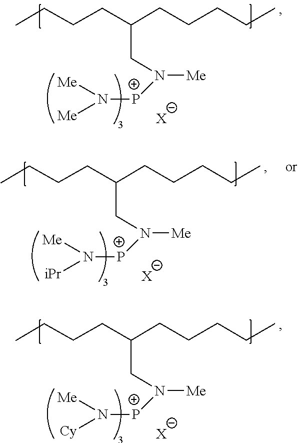

wherein Me is methyl, iPr is isopropyl, and Cy is cyclohexyl. The remainder of features and example features of the eighth aspect is as described above with respect to the first through seventh aspects of the third embodiment.

In a ninth aspect of the third embodiment, the support ionomer further comprises a plurality of sixth repeat units represented by the following structural formula:

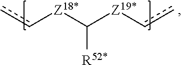

wherein: Z¹⁸* and Z¹⁹* each independently is a C₁₋₃ alkylene or a bond; R⁵²* is H, a C₁₋₁₂ alkyl, or a C₆₋₁₂ aryl. In some instances, at least one sixth repeat unit is connected to a cross-linking moiety through the point of attachment on the cross-linking moiety designated as [symbol] . The remainder of features and example features of the ninth aspect is as described above with respect to the first through eighth aspects of the third embodiment.

In a tenth aspect of the third embodiment, the support ionomer comprises a repeat unit represented by any one of the following structural formulas:

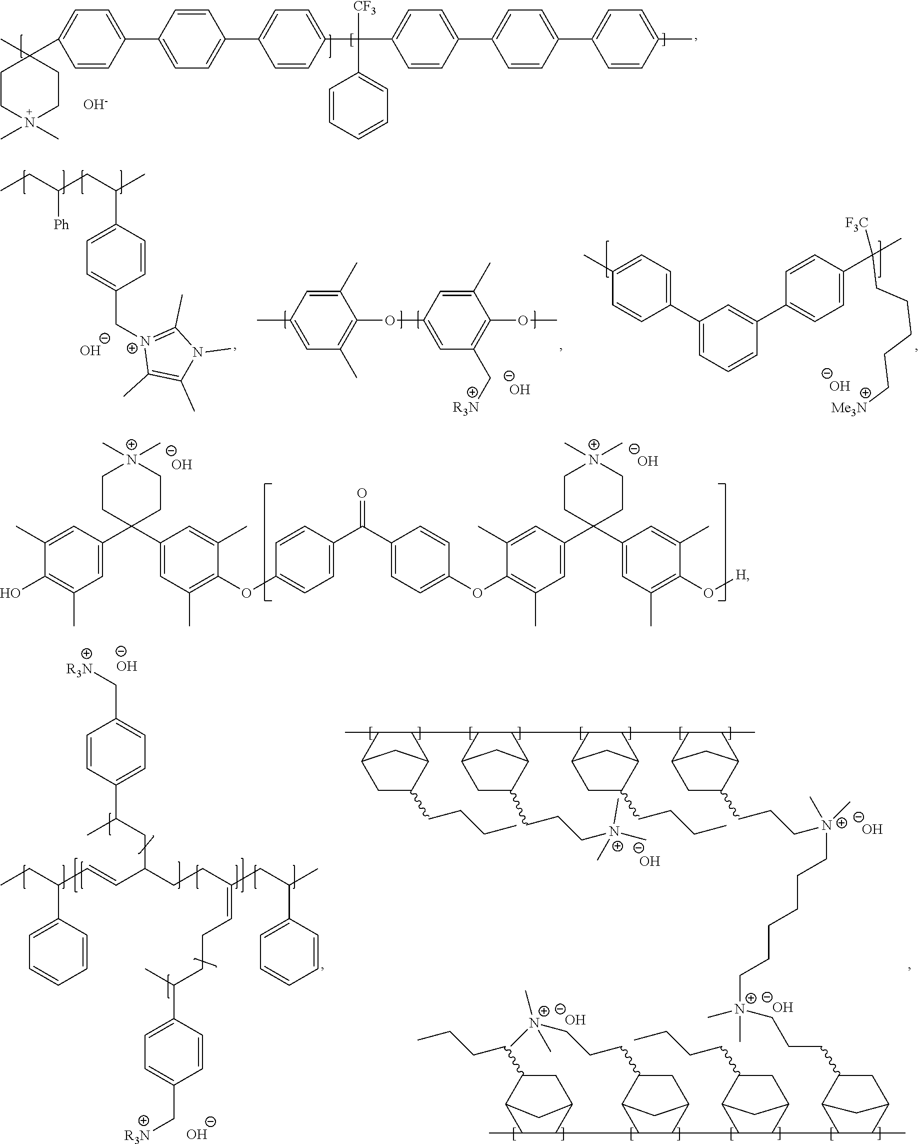

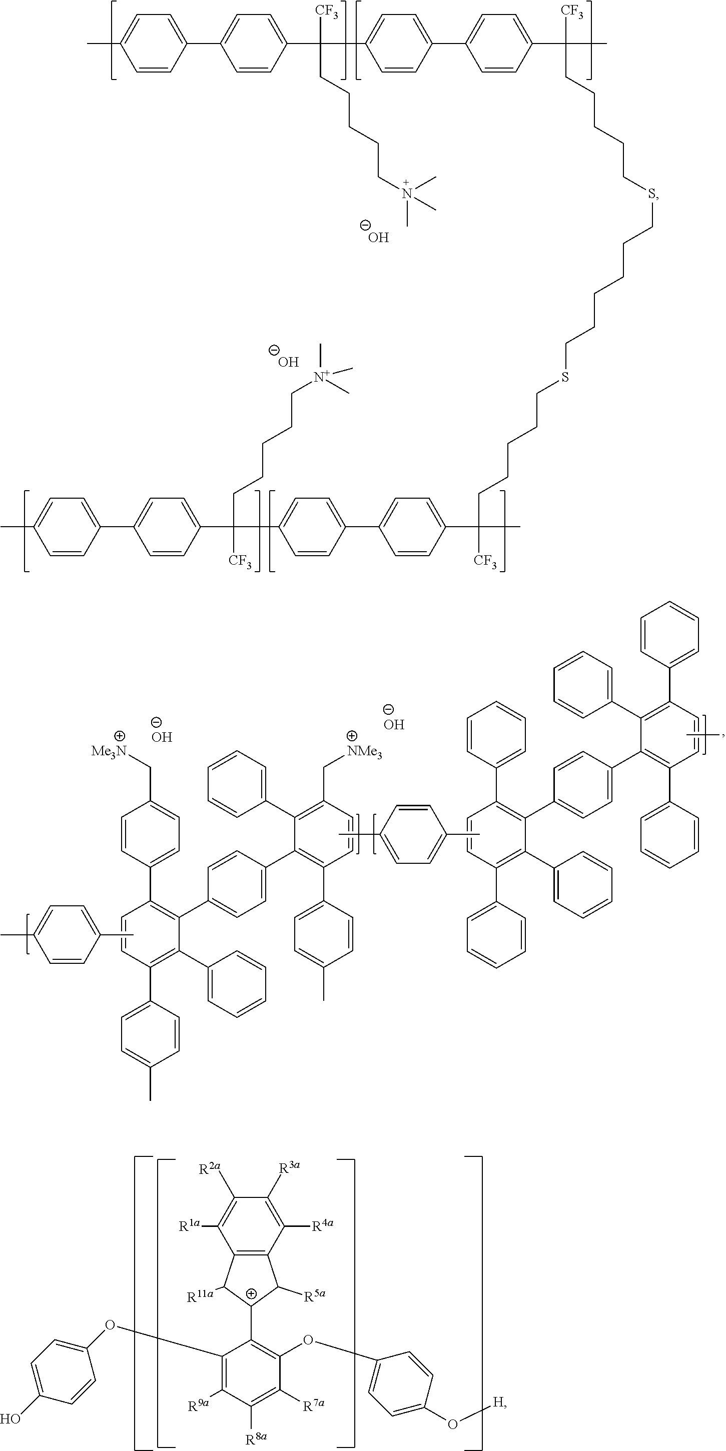

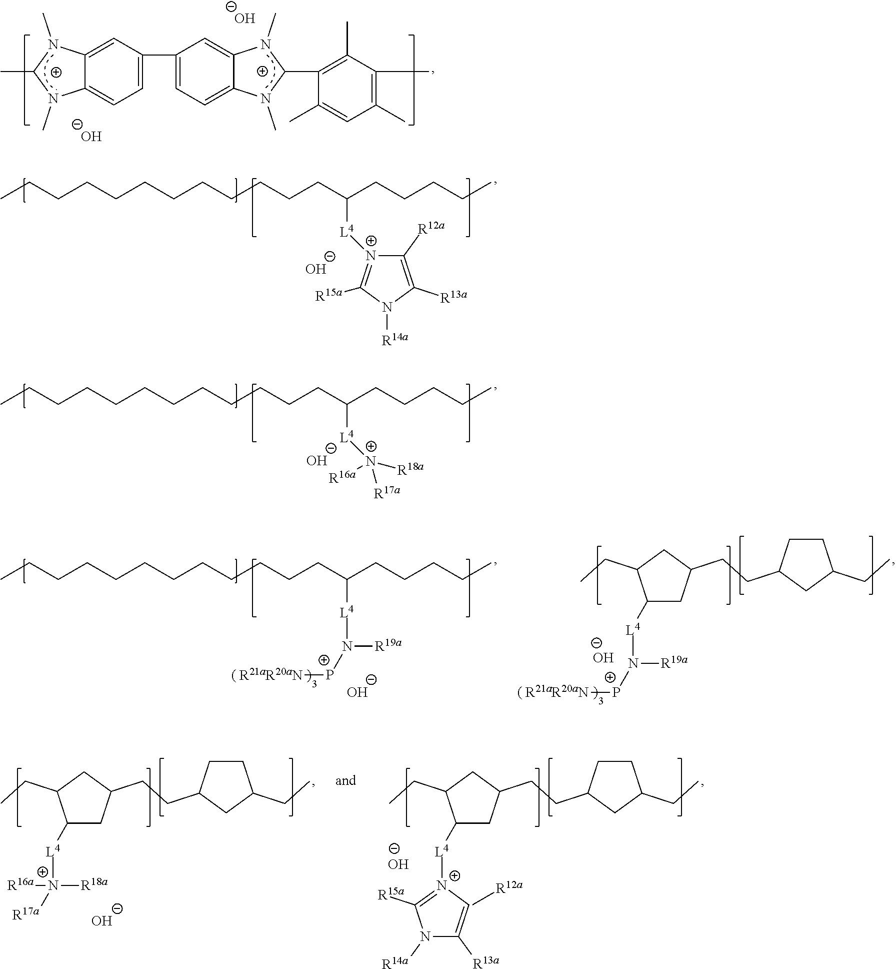

wherein:
   R, R^{1a}, R^{2a}, R^{3a}, R^{4a}, R^{5a}, R^{7a}, R^{8a}, R^{9a}, R^{11a}, R^{12a}, R^{13a}, R^{14a}, R^{15a}, R^{16a}, R^{17a}, R^{18a}, R^{19a}, R^{20a}, and R^{21a} is each independently selected from H, a C₁₋₃ alkyl, C₆₋₁₂ aryl, and C₅₋₁₂ cycloalkyl,
   L⁴ is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₚ, (C₁₋₁₂ alkylene-O)ₚ, C(O)(O—C₁₋₁₂ alkylene)ₚ, OC(O)(C₁₋₁₂ alkylene)ₚ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₚ, (NH)C(O—C₁₋₁₂ alkylene)ₚ, (NH—C₁₋₁₂ alkylene)ₚ, (C₁₋₁₂ alkylene-NH)ₚ, and a bond;
   p is an integer between 1 and 6; and each moiety within square brackets represents a repeat unit of the support ionomer. The remainder of features and example features of the tenth aspect is as described above with respect to the first through ninth aspects of the third embodiment.

In a fourth embodiment the present disclosure relates to a membrane electrode assembly (MEA), comprising a polymer film as described herein with respect to the first embodiment and various aspects thereof, or an electrode as described herein with respect to the second embodiment and various aspects thereof, composite material as described herein with respect to the third embodiment and various aspects thereof.

In a fifth embodiment the present disclosure relates to a fuel cell comprising an MEA described herein with respect to the fourth embodiment and various aspects thereof, a source of fuel, and an oxidant.

In a first aspect of the fifth embodiment, the fuel is humidified.

In a second aspect of the fifth embodiment, the fuel is selected from hydrogen, methanol, ethanol, and ammonia. The remainder of features and example features of the second aspect is as described above with respect to the first aspect of the fifth embodiment.

In a third aspect of the fifth embodiment, the oxidant is oxygen. The remainder of features and example features of the third aspect is as described above with respect to the first and second aspects of the fifth embodiment.

In a sixth embodiment the present disclosure relates to an electrolyzer comprising an MEA as described herein with respect to the fourth embodiment and various aspects thereof and an electrolyte source.

In a first aspect of the sixth embodiment, the electrolyte source comprises water, a metal hydroxide, ethanol, methanol, ammonia, carbon dioxide, or a combination thereof.

In a seventh embodiment, the present disclosure relates to a method of making a polymer film as described herein with respect to the first embodiment and various aspects thereof, the method comprising:
a) providing a precursor film comprising the cross-linkable precursor ionomer,
b) applying a mask to the film, thereby providing a partially protected film;
c) exposing the partially protected film to ultraviolet radiation for a time sufficient to cross-link the cross-linkable ionomer, thereby producing the polymer film.

In a first aspect of the seventh embodiment, the cross-linkable moiety is represented by the following structural formula:

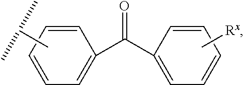

and W is a moiety represented by the following structural formula:

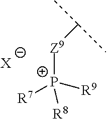

In a second aspect of the seventh embodiment, the cross-linkable moiety represented by the following structural formula:

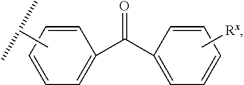

and W is a moiety represented by the following structural formula:

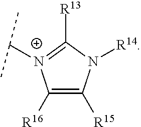

The remainder of features and example features of the second aspect is as described above with respect to the first aspect of the seventh embodiment.

In a third aspect of the seventh embodiment, the cross-linkable moiety is represented by the following structural formula:

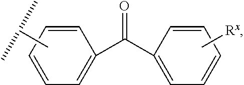

and W is a moiety represented by the following structural formula:

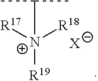

The remainder of features and example features of the third aspect is as described above with respect to the first through second aspects of the seventh embodiment.

In a fourth aspect of the seventh embodiment, the cross-linkable moiety is represented by the following structural formula:

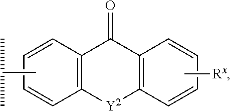

and W is a moiety represented by one of the following structural formulas:

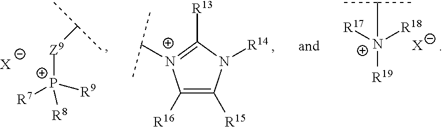

The remainder of features and example features of the fourth aspect is as described above with respect to the first through third aspects of the seventh embodiment.

In a fifth aspect of the seventh embodiment, Q, V, W, L², L³, the cross-linkable moiety, and the cross-linking moiety are as described in any of the second through sixty-ninth aspects of the first embodiment. The remainder of features and example features of the fifth aspect is as described above with respect to the first through fourth aspects of the seventh embodiment.

In a sixth aspect of the seventh embodiment, the precursor film does not comprise an external radical initiator. As used herein, the term “external radical initiator” refers to a radical initiator that is not covalently attached to the ionomer. The remainder of features and example features of the tenth aspect is as described above with respect to the first through fifth aspects of the seventh embodiment.

### EXEMPLIFICATION

The examples below describe methods of synthesis of the ionomers and catalyst/ionomer layers of the present disclosure. The examples also provide methods of manufacturing and characterization of the MEAs of the disclosure.

### Abbreviations

COE cyclooctene
TEA triethylamine
THF tetrahydrofuran
ACN acetonitrile
Grubbs' Gen II catalyst (1,3-Bis(2,4,6-trimethylphenyl)-2-imidazolidinylidene)dichloro(phenylmethylene)(tricyclohexylp hosphine)ruthenium
Crabtree's catalyst (1,5-Cyclooctadiene)(pyridine)(tricyclohexylphosphine)-Ir(I) PF₆

### Example 1. Synthesis of COE-Benzophenone Monomer

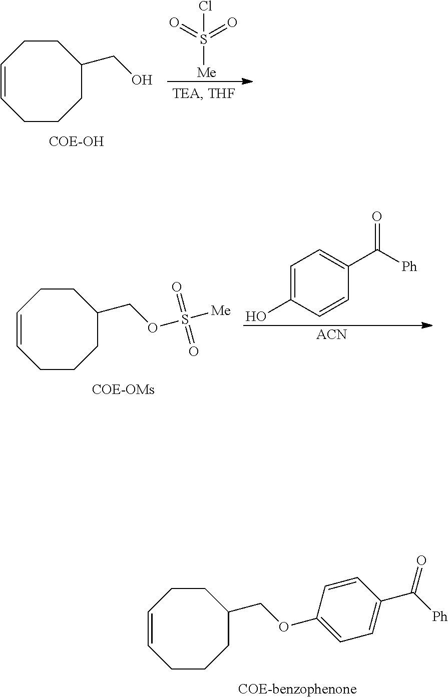

COE-OH (10 g, 71 mmol) was combined with triethylamine (8.1 g, 80 mmol) and tetrahydrofuran (anhydrous, 100 mL) in a 250 mL round bottom flask. The solution was cooled to 0° C. in an ice bath and methane sulfonyl chloride was added dropwise under the flow of nitrogen. The reaction was warmed to room temperature and allowed to stir for 24 h. The resulting heterogeneous mixture was filtered to remove solids and the organic layer was concentrated, in vacuo, to remove tetrahydrofuran. The crude oil was dissolved in diethyl ether and washed with KOH (1M), water, and brine. The organic layer was dried over magnesium sulfate and concentrated, in vacuo, to produce COE-OMs as a light yellow oil (13.3 g). COE-OMs (5 g, 23 mmol) was combined in a 250 mL round bottom flask with potassium carbonate (7 g, 50 mmol), acetonitrile (50 mL) and 4-hydroxybenzophenone (4.8 g, 24 mmol). The round bottom flask was fitted with a reflux condenser and the reaction was heated to reflux for 24 h. The reaction was cooled, filtered, and concentrated, in vacuo, to remove acetonitrile. The resulting crude oil was dissolved in ethyl acetate and washed with 1M KOH, water, and brine. The organic layer was dried over magnesium sulfate, filtered, and concentrated, in vacuo, to produce COE-Benzophenone as an off-white, waxy solid (4.1 g).

### Example 2. Synthesis of Cyclohexyl-Methyl Tetrakis® Monomer (3)

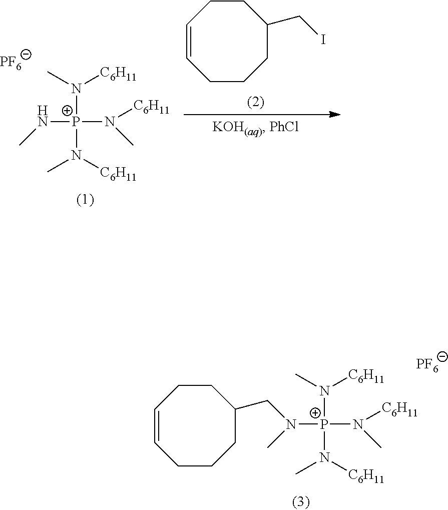

Tris(cyclohexyl(methyl)amino)(methylamino)phosphonium hexafluorophosphate (1) was synthesized as detailed in Treichel, M. et al. Macromolecules, 2020, 53, 8509.

Compound (1) (5.0 g, 9 mmol) was combined with chlorobenzene (16 mL) in a 250 mL round bottom flask. A potassium hydroxide solution (50 wt %, 10.0 g, 178 mmol) was charged followed by COE-iodide (2) (3.5 g, 14 mmol). The reaction was heated to 60° C. for 24 h. The reaction was cooled and layers separated. The aqueous layer was extracted with dichloromethane and all organic layers were washed with 1M HCl, saturated potassium hexafluorophosphate, and water. The organic layer was dried over magnesium chloride, concentrated, in vacuo, to produce a crude oil. The oil was dissolved in a minimal amount of dichloromethane and precipitated into diethyl ether to produce Tetrakis® monomer (3) as an off-white solid (3.5 g).

### Example 3. Synthesis of COE-Imidazolium Monomer (5)

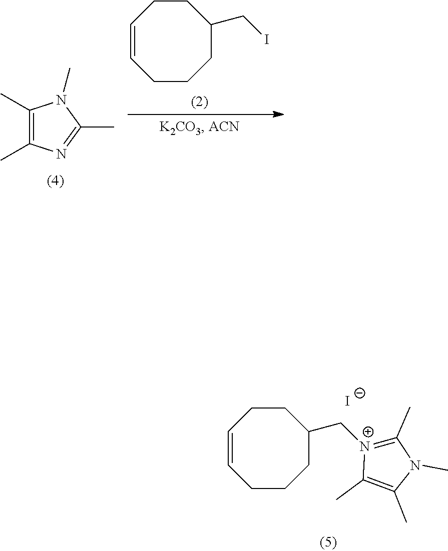

Tetramethyl imidazole (4) (3.0 g, 24 mmol) was combined with acetonitrile (16 mL) and potassium carbonate (3.3 g, 24 mmol) in a 50 mL round bottom flask. COE-iodide (2) (9 g, 36 mmol) was charged to the flask and the reaction was heated at 80° C. for 19 h. The reaction was cooled, filtered, and concentrated, in vacuo, to an oil. The collected oil was dissolved in dichloromethane, extracted with water, and dried over magnesium sulfate. The dichloromethane layer was filtered and precipitated into diethyl ether to produce COE-Imidazolium monomer (5) as a tan solid (5.7 g).

### Example 4. Synthesis of Tetrakis®-BXL Ionomer Containing Cross-Linkable Benzophenone Moieties

Tetrakis®-BXL ionomer refers to an ionomer comprising first repeat units containing benzophenone moieties, and second repeat units containing Tetrakis® cations. Tetrakis® Monomer (3) (0.63 g, 1.1 mmol), COE-Benzophenone (0.07 g, 0.20 mmol), and cyclooctene (0.30 g, 2.7 mmol) were dissolved in dichloromethane while under inert atmosphere. Grubbs' Gen II catalyst (7 mg, 0.01 mmol) was added to the solution and the reaction was stirred for 18 h. The resulting polymer was dissolved in a 2:1 (v:v) dichloromethane:methanol mixture and added to a pressure vessel. Crabtree's catalyst (10 mg, 0.01 mmol) was added, and the reaction was pressurized to 800 psi of hydrogen and heated to 55° C. for 17 h. The reaction was cooled to room temperature and the solvent removed to produce 0.96 g of a Tetrakis-BXL ionomer (28 mol % cationic units, 5 mol % cross-linkable units).

### Example 5. Synthesis of Imidazolium-BXL Ionomer Containing Cross-Linkable Benzophenone Moieties

Imidazolium-BXL ionomer refers to an ionomer comprising first repeat units containing benzophenone moieties, and second repeat units containing imidazolium cations. COE-Imidazolium Monomer (5) (0.86 g, 2.3 mmol), COE-Benzophenone (0.05 g, 0.16 mmol), and cyclooctene (0.09 g, 0.82 mmol) were dissolved in dichloromethane while under inert atmosphere. Grubbs' Gen II catalyst (4 mg, 0.005 mmol) was added to the solution and the reaction was stirred for 18 h. The resulting polymer was dissolved in a 2:1 (v:v) dichloromethane:methanol mixture and added to a pressure vessel. Crabtree's catalyst (5 mg, 0.007 mmol) was added, and the reaction was pressurized to 800 psi of hydrogen and heated to 55° C. for 17 h. The reaction was cooled to room temperature and the solvent removed to produce 0.82 g of Imidazolium-BXL ionomer (70 mol % cationic units, 5 mol % cross-linkable units).

### Example 6. Tetrakis®-BXL Polymer Membrane Synthesis

A stock solution of 4:1 (w/w) was prepared by combining DI water (40 g) and 1-propanol (10 g). An aliquot of the water:1-propanol solution (10.8 g) was combined with 1.0 g of Tetrakis® polymer formed in Example 4. The mixture was stirred and heated at 80° C. until dissolved to form an 8.5 wt. % polymer solution (11.8 g).

The entire polymer solution (11.8 g) was poured onto the surface of a tempered glass plate at 25° C. A drawdown bar (RDS, No. 250G) was used to spread the polymer solution on the tempered glass to form a uniform polymer film. The film was allowed to dry at 25° C. for 30 min, then transferred to an oven at 120° C. for 1 h. The film was allowed to cool to room temperature, then lifted off the glass by submerging in deionized water (DI) water. The released film was allowed to air dry to produce a Tetrakis®-BXL membrane film with UV-crosslinkable groups (ca. 11×11 cm, 50 μm thick).

### Example 7. Formation of a UV-Patterned Tetrakis®-BXL Membrane (70 Mesh Mask)

A ca. 3×3 cm portion of the 50 μm Tetrakis®-BXL membrane film formed in Example 6, was covered with a 70 mesh stainless-steel (SS) mask (0.0065″ wire, 29.8% open area). The masked membrane was placed under a UV-lamp (365 nm wavelength, 100 W) for 45 min, then allowed to cool to room temperature. The 70 mesh mask was removed from the Tetrakis®-BXL membrane film and it was placed into DI water for 5 min. The Tetrakis®-BXL membrane film was removed from the DI water and allowed to air dry overnight to produce a film with a distinct patterning resembling the 70 mesh mask (FIG. 2).

### Example 8. Formation of a UV-Patterned Tetrakis®-BXL Membrane (500 Mesh Mask)

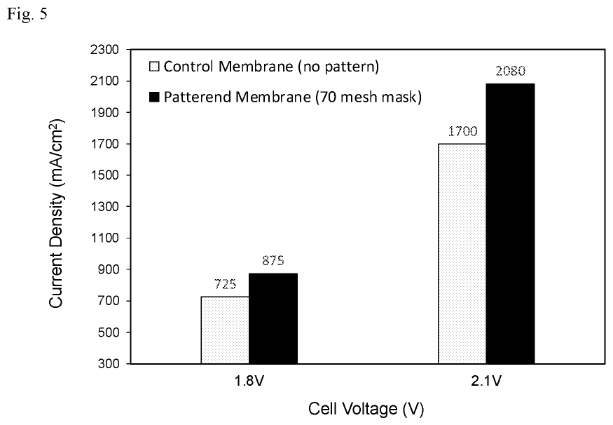

The procedure was performed as in Example 7, except a finer 500 mesh SS mask (0.0010″ wire, 25% open area) was used to create a patterned Tetrakis®-BXL membrane. As with Example 5, this patterning was consistent with the 500 mesh pattern and persisted after swelling the membrane in DI water and allowing to dry overnight (FIG. 4).

### Example 9. Heat Only Treatment of Tetrakis®-BXL Membrane

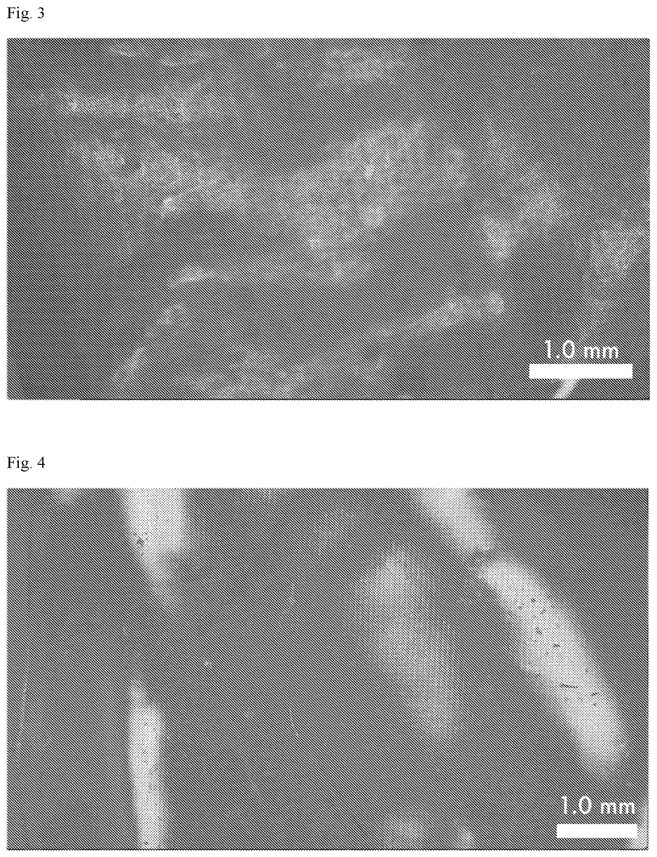

A 1×1 cm square of Tetrakis®-BXL membrane film, formed in Example 6, was placed on a Teflon coated hot plate. A 70 mesh SS mask (0.0065″ wire, 29.8% open area), was placed on top of the Tetrakis®-BXL membrane film. A 20 g cylindrical weight was placed on top of the SS mask to provide greater contact between the mask and Tetrakis®-BXL membrane surface. The masked membrane was heated at 50° C. for 45 min, then allowed to cool to room temperature. The heat treated Tetrakis®-BXL membrane film was submerged in DI water for 5 min, then allowing to dry overnight. Unlike the UV-patterned Tetrakis®-BXL membranes formed in Examples 7 and 8, the heat-only treatment failed to provide a persistent pattern after DI water exposure and drying. The surface of the heat-treated (no UV) Tetrakis®-BXL membrane was consistent with that of an as cast film, showing no pattern corresponding to the 70 mesh mask (FIG. 3).

### Example 10. Measurement of Polarization Curve Electrochemical Impedance Spectroscopy

Two 7.5×7.5 cm squares of a 60 μm Tetrakis®-BXL membrane film were cut from the same stock material. The control membrane film (no pattern) was formed by crosslinking under a lamp (365 nm wavelength, 100 W) for 45 min. The patterned membrane (70 mesh mask) was formed placing a 70 mesh stainless-steel (SS) mask (0.0065″ wire, 29.8% open area, 2.5×2.5 cm) in the center of the film and crosslinking under a UV-lamp (365 nm wavelength, 100 W) for 45 min.

The two membrane films (patterned and non-patterned) were each tested under identical conditions in an electrolyzer device consisting of bipolar plates (BPP) with serpentine flow fields, gas diffusion electrodes, and teflon gaskets (6.25 cm² active area, DM-type alkaline water electrolyzer cell, 30% cathode compression, 10% anode compression). In each test, the device was first equilibrated at room temperature for 60 mins by flowing electrolyte (12 mL/min) and subsequently pre-conditioned by applying 1.8 V across the device for 15 mins. The device was heated from room temperature to 40° C., using external heating pads with temperature monitored both internally and externally. The films were tested with current-controlled polarization curves at 40° C. Before the polarization curves, electrochemical impedance spectroscopy (EIS) analysis was performed at 1.7 V and 40° C. The frequency range for EIS was set from 100,000 to 0.1 Hz with a 10 mV amplitude.

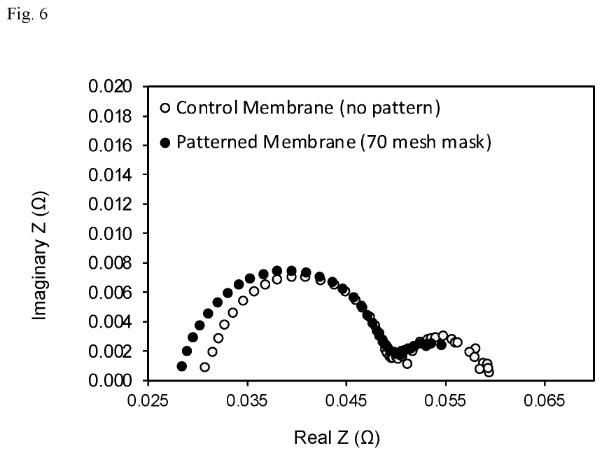

The obtained data are shown in FIGS. 5 and 6. The data show that under the same operating conditions, an increased current density was observed for the device using the patterned membrane at both 1.8 and 2.1 V compared to the non-patterned membrane. The electrolyzer test with a patterned membrane resulted in a lower high frequency resistance (HFR), reflected in the improved device performance, over the non-patterned membrane.

While this invention has been particularly shown and described with references to example embodiments thereof, it will be understood by those skilled in the art that various changes in form and details may be made therein without departing from the scope of the invention encompassed by the appended claims.

The teachings of all patents, published applications and references cited herein are incorporated by reference in their entirety.

What is claimed is:

1. A polymer film, comprising a first plurality of volumes and a second plurality of volumes, wherein:
each volume of the first plurality of volumes comprises a cross-linkable precursor ionomer, and each volume of the second plurality of volumes comprises a cross-linked product ionomer, the cross-linkable precursor ionomer and the cross-linked product ionomer each comprising:
a plurality of first repeat units, wherein each first repeat unit is represented by the following structural formula: 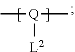
and
a plurality of second repeat units, wherein each first repeat unit is represented by the following structural formula: 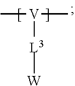
and further wherein:
the cross-linkable precursor ionomer comprises one or more cross-linkable moieties represented by any one of the following structural formulas: 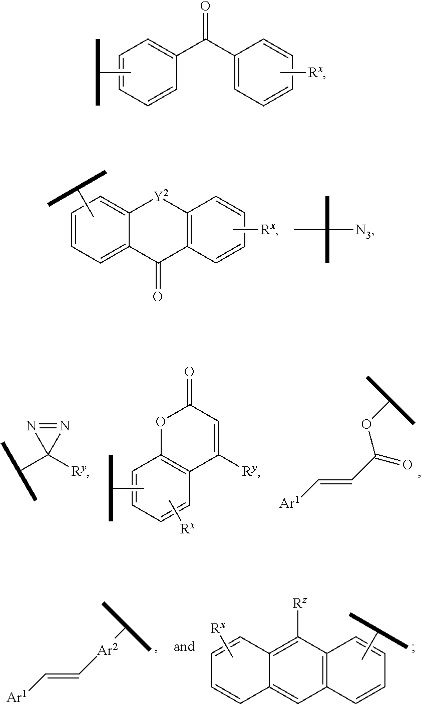
and
the cross-linked product ionomer comprises one or more cross-linking moieties represented by any one of the following structural formulas: 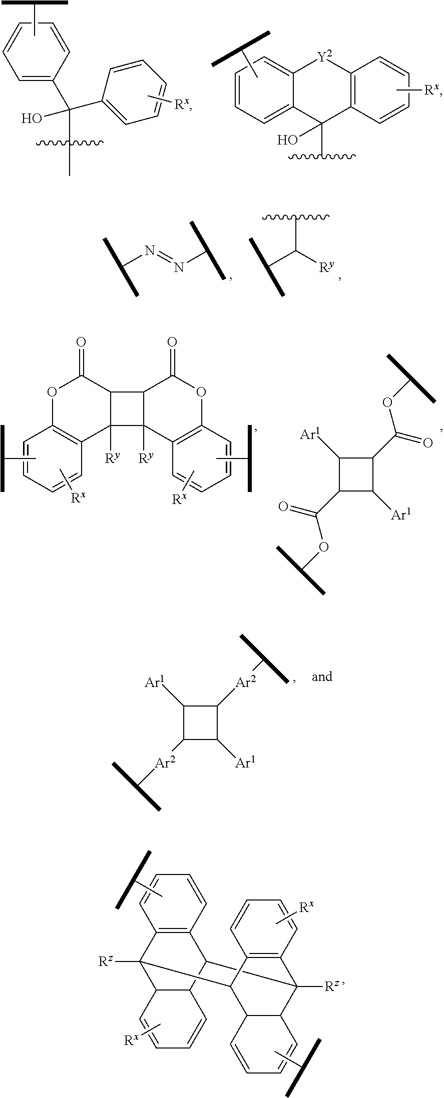
wherein, for each occurrence of the cross-linkable moiety, the symbol [symbol] represents a point of attachment to L², and, for each occurrence of the cross-linking moiety, the symbol [symbol] represents a point of attachment to L² and the symbol [symbol] represents a point of attachment to a first repeat unit or a second repeat unit, and further wherein: 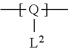
is a moiety represented by one of the following structural formulas: 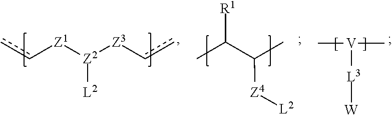
is a moiety represented by any one of the following structural formulas: 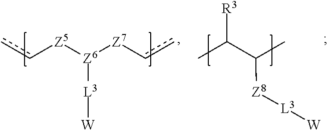
W is a C₁₋₁₂ alkyl or a moiety represented by one of the following structural formulas: 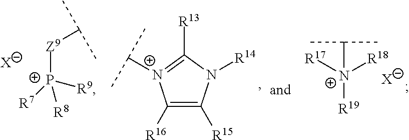
wherein the symbol [symbol] represents a point of attachment to L³, and the symbol [symbol] represents a double bond or a single bond;
Z¹, Z³, Z⁵, and Z⁷ each independently is a C₁₋₃ alkylene or a bond;
Z² is selected from —CHR⁵—, a C₅₋₁₂ cycloalkylene, and a 5 to 16-membered heterocyclylene;
R¹ is selected from H, a C₁₋₁₂ alkyl, and C₆₋₁₂ aryl, and
Z⁴ is a bond or a C₆₋₁₂ arylene, or
Z⁴ is CH, and R¹ and Z⁴ together with the C₂ alkylene to which they are attached form a C₅₋₁₂ cycloalkyl or a 5 to 12-membered heterocyclyl; and
Z⁶ is selected from —CHR⁶—, a C₅₋₁₂ cycloalkylene, and a 5 to 16-membered heterocyclylene;
R³ is selected from H, a C₁₋₁₂ alkyl, and C₆₋₁₂ aryl, and
Z⁸ is a bond or a C₆₋₁₂ arylene, and CH, or
Z⁸ is CH, and R³ and Z⁸ together with the C₂ alkylene to which they are attached form a C₅₋₁₂ cycloalkyl or a 5 to 12-membered heterocyclyl; and
Z⁹ is NR¹⁰ or a bond;
R⁵, R⁶, and R^{y} each independently is H or a C₁₋₁₂ alkyl;
R⁷, R⁸, and R⁹ each independently is selected from NR¹¹R¹², a C₆₋₁₂ aryl, and 5 to 12-membered heterocyclyl;
R¹⁰ is a C₁₋₁₂ alkyl;
R¹¹ and R¹² each independently is C₁₋₁₂ alkyl or a C₃₋₁₂ cycloalkyl, or R¹¹ and R¹² together with the nitrogen atom to which they are attached form a 5 to 12-membered heterocyclyl;
R¹³ is selected from a C₁₋₁₂ alkyl, C₆₋₁₂ aryl, and 5 to 12-membered heterocyclyl;
R¹⁴ is a C₁₋₁₂ alkyl or a C₃₋₁₂ cycloalkyl;
R¹⁵ and R¹⁶ each independently is selected from C₁₋₁₂ alkyl, C₆₋₁₂ aryl, and 5 to 12-membered heterocyclyl; or R¹⁵ and R¹⁶ together with the carbon atoms to which they are attached form a C₆₋₁₂ aryl or a 5 to 12-membered heterocyclyl; and
R¹⁷, R¹⁸, and R¹⁹ each independently is a C₁₋₁₂ alkyl or a C₃₋₁₂ cycloalkyl; or
R¹⁸ and R¹⁹ together with the nitrogen atom to which they are attached form a 5 to 12-membered heterocyclyl and (i) R¹⁷ is a C₁₋₁₂ alkyl or a C₃₋₁₂ cycloalkyl, or (ii) R¹⁷ and at least one atom of L³ together with the nitrogen atom to which L³ and R¹⁷ are attached form a 5- to 12-membered heterocyclyl; or
R¹⁷, R¹⁸, and R¹⁹ together with the nitrogen atom to which they are attached form a bicyclic 5 to 12-membered heterocyclyl;
R^{x} and R^{z} each independently is selected from H, F, Cl, Br, OH, NH₂, NO₂, CN, C₁₋₁₂ alkyl, C₆₋₁₂ aryl, 5 to 12-membered heterocyclyl, and 5 to 12-membered heteroaryl;
Ar¹ is a C₆₋₁₂ aryl or a 5 to 12-membered heterocyclyl;
Ar² is a C₆₋₁₂ arylene or a 5 to 16-membered heterocyclylene;
L² is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₘ, (C₁₋₁₂ alkylene-O)ₘ, C(O)(O—C₁₋₁₂ alkylene)ₘ, OC(O)(C₁₋₁₂ alkylene)ₘ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₘ, (NH)C(O—C₁₋₁₂ alkylene)ₘ, (NH—C₁₋₁₂ alkylene)ₘ, and (C₁₋₁₂ alkylene-NH)ₘ;
L³ is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₙ, (C₁₋₁₂ alkylene-O)ₙ, C(O)(O—C₁₋₁₂ alkylene)ₙ, OC(O)(C₁₋₁₂ alkylene)ₙ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₙ, (NH)C(O—C₁₋₁₂ alkylene)ₙ, (NH—C₁₋₁₂ alkylene)ₙ, (C₁₋₁₂ alkylene-NH)ₙ, and a bond;
m is an integer between 1 and 6;
n is an integer between 1 and 6;
Y² is selected from —C(O)—, —O—, —S—, —NH—, —N(C₁₋₁₂ alkyl)-, and a bond;
X⁻ is selected from F⁻, Cl⁻, Br⁻, OH⁻, NO⁻₂, CN⁻, HCO₃⁻, CO₃²⁻, PF₆⁻, BF₄⁻, and a C₁₋₁₂ carboxylate;
provided that W is C₁₋₁₂ alkyl only when V is a cationic moiety,
and wherein:
each C₁₋₁₂ alkyl, C₃₋₁₂ cycloalkyl, C₅₋₁₂ cycloalkyl, C₆₋₁₂ aryl, 5 to 12-membered heteroaryl, 5 to 12-membered heterocyclyl, C₁₋₁₂ alkylene, C₆₋₁₂ arylene, C₅₋₁₂ cycloalkylene, 5 to 16-membered heterocyclylene, and 5 to 12-membered heteroarylene is independently optionally substituted with 1 to 6 substituents independently selected from the group consisting of F, Cl, Br, OH, NH₂, NO₂, oxo, CN, a C₁₋₁₂ alkyl, C₆₋₁₂ aryl, C₁₋₁₂haloalkyl, C₁₋₁₂ alkoxy, C₆₋₁₂ aryl, C₆₋₁₂ aryloxy, 5 to 16-membered heterocyclyl, 5 to 12-membered heteroaryl, NH(C₁₋₁₂ alkyl), N(C₁₋₁₂ alkyl)₂, OC(O)(C₁₋₁₂ alkyl), C(O)O(C₁₋₁₂ alkyl), S(O)₂(C₁₋₁₂ alkyl), S(O)₂(C₆₋₁₂ aryl), NHC(O)(C₁₋₁₂ alkyl), and C(O)NH(C₁₋₁₂ alkyl).

2. The polymer film of claim 1, wherein the cross-linkable precursor ionomer and the cross-linked product ionomer each further comprises a plurality of third repeat units, wherein each third repeat unit is a moiety represented by the following structural formula: 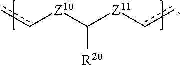
wherein
Z¹⁰ and Z¹¹ each independently is a C₁₋₃ alkylene or a bond;
R²⁰ is H, a C₁₋₁₂ alkyl, or a C₆₋₁₂ aryl.

3. The polymer film of claim 1 or 2, wherein the cross-linking moiety is represented by one of the following structural formulas:

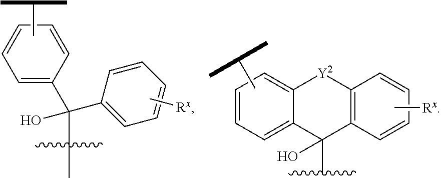

4. The polymer film of claim 3, wherein the cross-linking moiety is represented by structural formula (I):

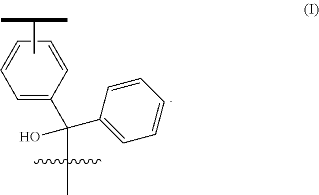

5. The polymer film of any one of claims 1-4, wherein the cross-linkable moiety is represented by one of the following structural formulas:

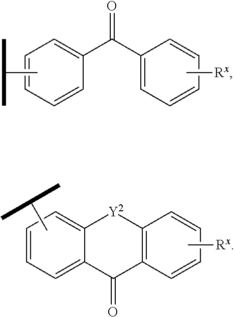

6. The polymer film of claim 5, wherein the cross-linkable moiety is represented by the following structural formula:

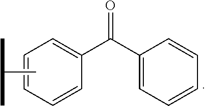

7. The polymer film of any one of claims 1-6, wherein the moiety 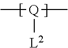
is represented by the following structural formula:

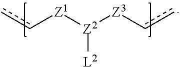

8. The polymer film of any one of claims 1-7, wherein the moiety 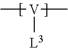
is represented by the following structural formula:

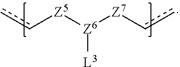

9. The polymer film of any one of claims 1-8, wherein W is a moiety represented by the following structural formula:

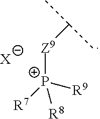

10. The polymer film of any one of claims 1-8, wherein W is a moiety represented by the following structural formula:

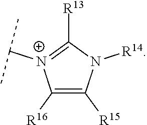

11. The polymer film of any one of claims 1-8, wherein W is a moiety represented by the following structural formula:

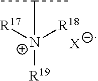

12. The polymer film of any one of claims 1-9, wherein the moiety 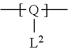
is represented by the following structural formula: 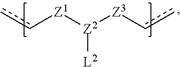
the moiety 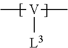
is represented by the following structural formula: 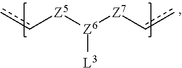
W is a C₁₋₁₂ alkyl or a moiety represented by the following structural formula: 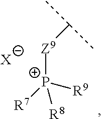
and
each cross-linking moiety is represented by structural formula (I).

13. The polymer film of any one of claims 1-8, wherein the moiety 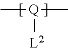
is represented by the following structural formula: 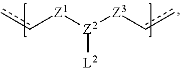
the moiety 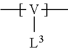
is represented by the following structural formula: 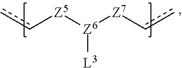
W is a C₁₋₁₂ alkyl or a moiety represented by the following structural formula: 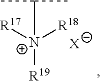
and
each cross-linking moiety is represented by structural formula (I).

14. The polymer film of any one of claims 1-8, wherein the moiety 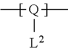
is represented by the following structural formula: 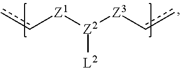
the moiety 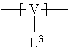
is represented by the following structural formula: 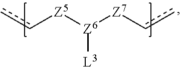
W is a C₁₋₁₂ alkyl or a moiety represented by the following structural formula: 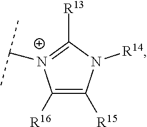
and
each cross-linking moiety is represented by structural formula (I).

15. The polymer film of any one of claims 1-14, wherein the moiety 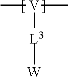
is represented by the following structural formula:

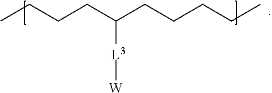

16. The polymer film of any one of claims 1-15, wherein the moiety 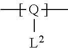
is represented by the following structural formula:

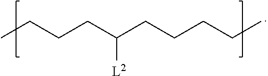

17. The polymer film of any one of claims 2-8, wherein:
the moiety 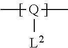
is represented by the following structural formula: 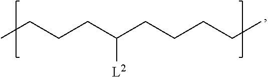
the moiety 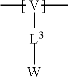
is represented by the following structural formula: 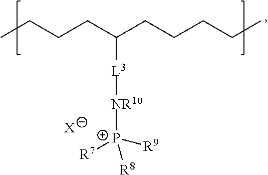
each third repeat unit is a Cs alkylene, and
each cross-linking moiety is represented by structural formula (I).

18. The polymer film of any one of claims 2-8, wherein:
the moiety 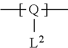
is represented by the following structural formula: 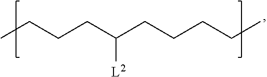
the moiety 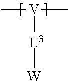
is represented by the following structural formula: 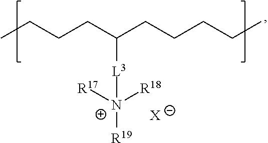
each third repeat unit is a C₈ alkylene, and
each cross-linking moiety is represented by structural formula (I).

19. The polymer film of any one of claims 2-8, wherein:
the moiety 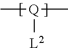
is represented by the following structural formula: 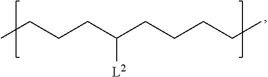
the moiety 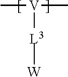
is represented by the following structural formula: 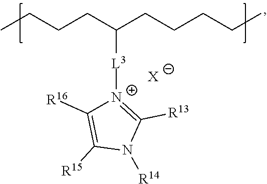
each third repeat unit is a Cs alkylene, and
each cross-linking moiety is represented by structural formula (I).

20. The polymer film of claim 19, wherein R¹³, R¹⁴, R¹⁵, and R¹⁶ are each a methyl.

21. The polymer film of any one of claims 1-20, wherein each first repeat unit is represented by the following structural formula:

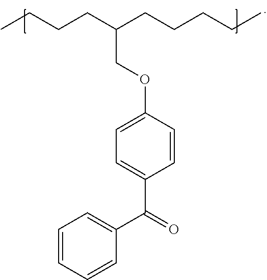

22. The polymer film of any one of claims 1-8, wherein the moiety 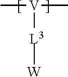
is represented by the following structural formula:

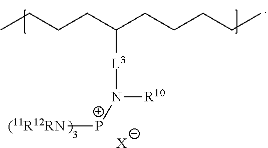

23. The polymer film of claim 22, wherein the moiety 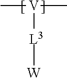
is represented by any one of the following structural formulas: 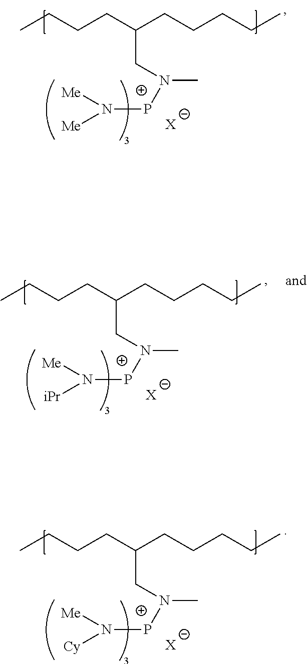
wherein Me is methyl, iPr is isopropyl and Cy is cyclohexyl.

24. The polymer film of claim 1, wherein
each first repeat unit is represented by the following structural formula: 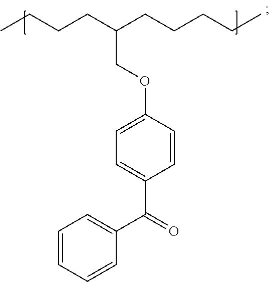
and
the moiety 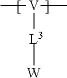
is represented by any one of the following structural formulas:

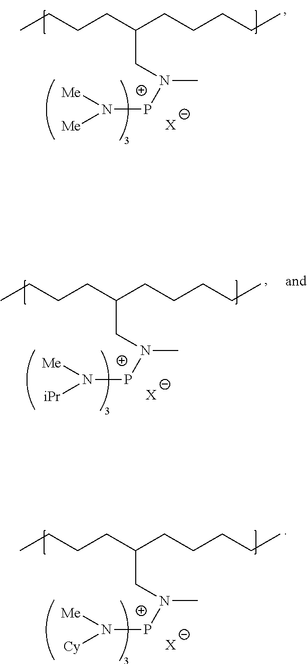

25. The polymer film of any one of claims 1-8, wherein
each first repeat unit is represented by the following structural formula: 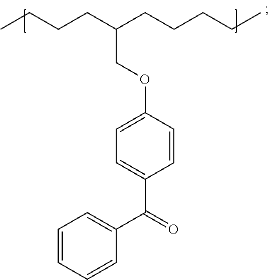
and
the moiety 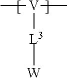
is represented by the following structural formula:

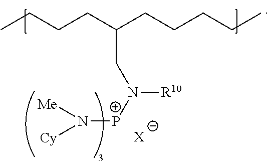

26. The polymer film of any one of claims 1-25, wherein the cross-linkable precursor ionomer comprises from about 0.5 mol-% to about 15 mol-% of the first repeat units.

27. The polymer film of claim 26, wherein the cross-linkable precursor ionomer comprises about 5 mol-% of the first repeat units.

28. The polymer film of any one of claims 1-27, wherein the cross-linkable precursor ionomer comprises from about 20 mol-% to about 98 mol-% of the second repeat units.

29. The polymer film of claim 28, wherein the cross-linkable precursor ionomer comprises about 28 mol-% of the second repeat units.

30. The polymer film of any one of claims 2-29, wherein the cross-linkable precursor ionomer comprises from about 20 mol-% to about 50 mol-% or from about 50 mol-% to about 90 mol-% of the third repeat units.

31. The polymer film of any one of claims 1-30, wherein the cross-linkable precursor ionomer comprises from about 0 mol-% to about 70 mol-% of the third repeat units.

32. The polymer film of claim 31, wherein the cross-linkable precursor ionomer comprises about 67 mol-% of the third repeat units.

33. The polymer film of any one of claims 1-32, wherein the number average molecular weight of the cross-linkable precursor ionomer is from about 30,000 g/mol to about 500,000 g/mol.

34. The polymer film of claim 33, wherein the number average molecular weight of the cross-linkable precursor ionomer is from about 50,000 g/mol to about 360,000 g/mol.

35. The polymer film of any one of claims 1-34, wherein the polymer film comprises from about 20 wt. % to about 80 wt. % of the cross-linked product ionomer.

36. An electrode comprising a catalyst/ionomer layer, wherein the catalyst/ionomer layer comprises a polymer film of any one of claims 1-35 and a catalyst.

37. The electrode of claim 36, wherein the catalyst is dispersed within the polymer film.

38. The electrode of claim 36, wherein the catalyst is disposed on the polymer film.

39. The electrode of any one of claims 36-38, wherein the catalyst comprises:
(i) a metal selected from Ni, Fe, Ru, Ir, Co, Mn, Pt, Pd, Mo, and, La, or a combination thereof; and/or
(ii) an oxide of a metal selected from Ni, Fe, Ru, Ir, Co, Mn, Pt, Pd, Mo, and La, or a combination thereof.

40. The electrode of any one of claims 36-39, wherein the catalyst comprises Pt, Pt supported on carbon (Pt/C), Pt and Ru supported on carbon (PtRu/C), Pd, Pd supported on carbon (Pd/C), Ir, IrO₂, IrRuO, RuO₂, Raney nickel (Al/Ni), Ni_{0.5}Co_{0.5}Fe₂O₄, NiCoO₂, NiFe, NiFe₂O₄, NiO, NiMo, Ni and Mo supported on carbon (NiMo/C), FeCoNi, Fe₂O₃, LaCoO₃, LiNiO₂, LiCoO₂, Co₃O₄, CoFe₂O₄, CoO, MnO, Mn₂O₃, MnO₂, or Mn₃O₄, or a combination thereof.

41. The electrode of claim 40, wherein the catalyst comprises Ni_{0.5}Co_{0.5}Fe₂O₄ or NiFe₂O₄.

42. The electrode of any one of claims 36-41, wherein the catalyst/ionomer layer comprises about 50-97 wt. % of the catalyst and about 3-50 wt. % of the polymer film.

43. The electrode of claim 42, wherein the catalyst/ionomer layer comprises about 80-90 wt. % catalyst and about 10-20 wt. % of the polymer film.

44. A composite material comprising a polymer film of any one of claims 1-35 or an electrode of any one of claims 36-43, and a support, wherein the polymer film or the electrode is disposed on the support.

45. The composite material of claim 44, wherein the support comprises a polyolefin, a polyphenylene, a polyester, a polyamide, or a polysulfone.

46. The composite material of claim 44, wherein the support comprises a perfluorinated polyolefin.

47. The composite material of claim 44, wherein the support comprises polyethylene, polypropylene, polytetrafluoroethylene, polyvinyl chloride, or polyvynyldifluoroethylene.

48. The composite material of claim 44, wherein the support comprises a support ionomer.

49. The composite material of claim 48, wherein the support ionomer is a cross-linked ionomer comprising:
a plurality of fourth repeat units, wherein each fourth repeat unit is a moiety represented by structural formula 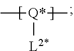
a plurality of fifth repeat units, wherein each fifth repeat unit is a moiety represented by structural formula 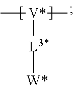
and
a plurality of cross-linking moieties, wherein each crosslinking moiety is represented by one of the following structural formulas: 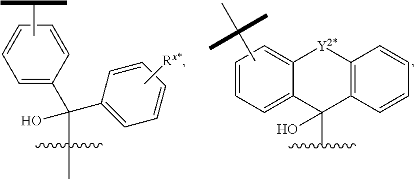
wherein for each occurrence of the cross-linking moiety, the symbol [symbol] represents a point of attachment to L²* and the symbol [symbol] represents a point of attachment to a fourth repeat unit or a fifth repeat unit;
and further wherein: 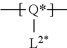
is a moiety represented by one of the following structural formulas: 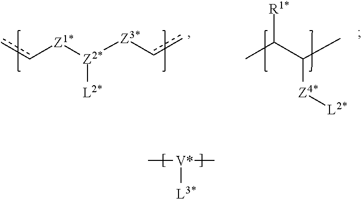
is a moiety represented by one of the following structural formulas: 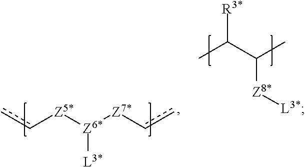
W* is C₁₋₁₂ alkyl or a moiety represented by one of the structural formulas selected from: 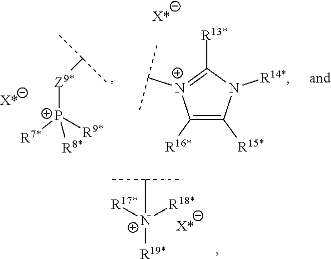
wherein the symbol [symbol] represents a point of attachment to L³*, and the symbol [symbol] represents a double bond or a single bond;
Z¹*, Z³* Z⁵*, and Z⁷* each independently is a C₁₋₃ alkylene or a bond;
Z²* is selected from —CHR⁵*—, a C₅₋₁₂ cycloalkylene, and a 5 to 16-membered heterocyclylene;
R¹* is selected from H, a C₁₋₁₂ alkyl, and C₆₋₁₂ aryl, and
Z⁴* is a bond or a C₆₋₁₂ arylene, or
Z⁴* is CH, and R¹* and Z⁴* together with the C₂ alkylene to which they are attached form a C₅₋₁₂ cycloalkyl or a 5 to 12-membered heterocyclyl; and
Z⁶* is selected from —CHR⁶—, a C₅₋₁₂ cycloalkylene, and a 5 to 16-membered heterocyclylene;
R³* is selected from H, a C₁₋₁₂ alkyl, and C₆₋₁₂ aryl, and
Z⁸* is a bond or a C₆₋₁₂ arylene, and CH, or
Z⁸* is CH, and R³* and Z⁸* together with the C₂ alkylene to which they are attached form a C₅₋₁₂ cycloalkyl or a 5 to 12-membered heterocyclyl; and
Z⁹* is NR¹⁰* or a bond;
R⁵* and R⁶* each independently is H or a C₁₋₁₂ alkyl;
R⁷*, R⁸*, and R⁹* each independently is selected from NR¹¹*R¹²*, a C₆₋₁₂ aryl, and 5 to 12-membered heterocyclyl;
R^{10*} is a C₁₋₁₂ alkyl;
R¹¹* and R¹²* each independently is C₁₋₁₂ alkyl or a C₃₋₁₂ cycloalkyl, or R^{11*} and R^{12*} together with the nitrogen atom to which they are attached form a 5 to 12-membered heterocyclyl;
R¹³* is selected from a C₁₋₁₂ alkyl, C₆₋₁₂ aryl, and 5 to 12-membered heterocyclyl;
R¹⁴* is a C₁₋₁₂ alkyl or C₃₋₁₂ cycloalkyl;
R^{15*} and R^{16*} each independently is selected from C₁₋₁₂ alkyl, C₆₋₁₂ aryl, and 5 to 12-membered heterocyclyl; or R¹⁵* and R¹⁶* together with the carbon atoms to which they are attached form a C₆₋₁₂ aryl or a 5 to 12-membered heterocyclyl; and
R¹⁷*, R¹⁸*, and R¹⁹* each independently is a C₁₋₁₂ alkyl or a C₃₋₁₂ cycloalkyl; or
R¹⁸* and R¹⁹* together with the nitrogen atom to which they are attached form a 5 to 12-membered heterocyclyl and (i) R¹⁷* is a C₁₋₁₂ alkyl or a C₃₋₁₂ cycloalkyl, or (ii) R¹⁷* and at least one atom of L³*, if present, together with the nitrogen atom to which L³* and R¹⁷* are attached form a 5- to 12-membered heterocyclyl; or
R¹⁷*, R¹⁸*, and R¹⁹* together with the nitrogen atom to which they are attached form a bicyclic 5 to 12-membered heterocyclyl;
R^{x}* is selected from H, F, Cl, Br, OH, NH₂, NO₂, CN, C₁₋₁₂ alkyl, C₆₋₁₂ aryl, 5 to 12-membered heterocyclyl, and 5 to 12-membered heteroaryl;
L²* is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₘ*, (C₁₋₁₂ alkylene-O)ₘ*, C(O)(O—C₁₋₁₂ alkylene)ₘ*, OC(O)(C₁₋₁₂ alkylene)ₘ*, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₘ*, (NH)C(O—C₁₋₁₂ alkylene)ₘ*, (NH—C₁₋₁₂ alkylene)ₘ*, and (C₁₋₁₂ alkylene-NH)ₘ*;
L³* is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₙ*, (C₁₋₁₂ alkylene-O)ₙ*, C(O)(O—C₁₋₁₂ alkylene)ₙ*, OC(O)(C₁₋₁₂ alkylene)ₙ*, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₙ*, (NH)C(O—C₁₋₁₂ alkylene)ₙ*, (NH—C₁₋₁₂ alkylene)ₙ*, (C₁₋₁₂ alkylene-NH)ₙ*, and a bond;
m* is an integer between 1 and 6;
n* is an integer between 1 and 6;
Y²* is selected from —C(═O)—, O, S, NH, N(C₁₋₁₂ alkyl), and a bond;
X*⁻ is selected from F⁻, Cl⁻, Br⁻, OH⁻, NO⁻₂, CN⁻, HCO₃⁻, CO₃²⁻, PF₆⁻, BF₄⁻, and a C₁₋₁₂ carboxylate;
provided that W* is C₁₋₁₂ alkyl only when V* is a cationic moiety, and wherein:
each C₁₋₁₂ alkylene, C₆₋₁₂ arylene, C₅₋₁₂ cycloalkylene, 5 to 16-membered heterocyclylene, C₁₋₁₂ alkyl, C₃₋₁₂ cycloalkyl, C₅₋₁₂ cycloalkyl, C₆₋₁₂ aryl, and 5 to 12-membered heterocyclyl is independently optionally substituted with 1 to 6 substituents independently selected from the group consisting of F, Cl, Br, OH, NH₂, NO₂, oxo, CN, a C₁₋₁₂ alkyl, C₆₋₁₂ aryl, C₁₋₁₂haloalkyl, C₁₋₁₂ alkoxy, C₆₋₁₂ aryl, C₆₋₁₂ aryloxy, 5 to 12-membered heterocyclyl, 5 to 12-membered heteroaryl, NH(C₁₋₁₂ alkyl), N(C₁₋₁₂ alkyl)₂, OC(O)(C₁₋₁₂ alkyl), C(O)O(C₁₋₁₂ alkyl), S(O)₂(C₁₋₁₂ alkyl), S(O)₂(C₆₋₁₂ aryl), NHC(O)(C₁₋₁₂ alkyl), and C(O)NH(C₁₋₁₂ alkyl).

50. The composite material of claim 48, wherein the support ionomer comprises a repeat unit represented by any one of the following structural formulas: 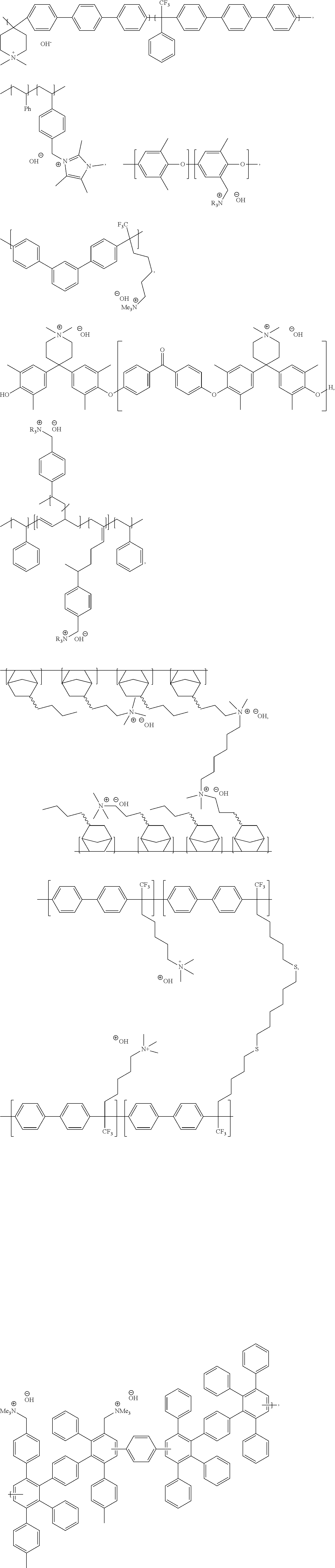 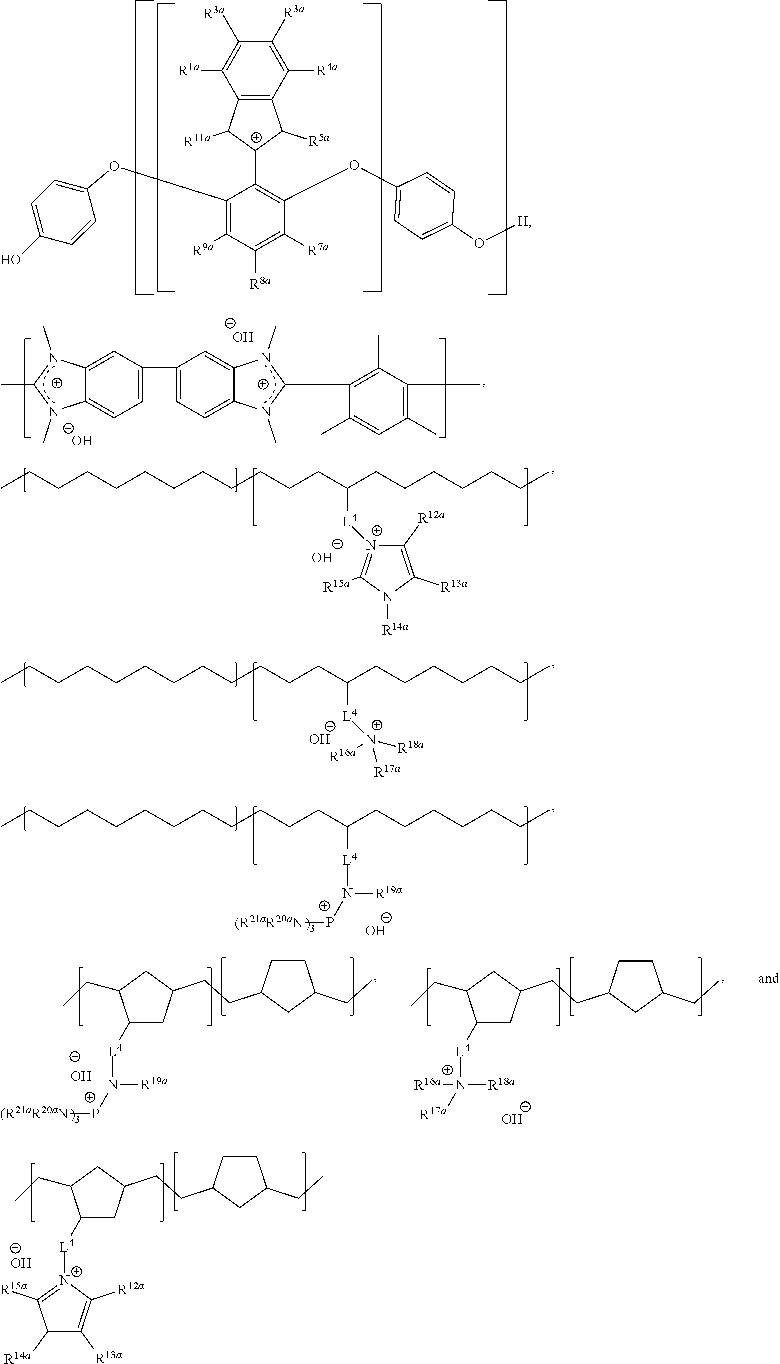
wherein:
R, R^{1a}, R^{2a}, R^{3a}, R^{4a}, R^{5a}, R^{7a}, R^{8a}, R^{9a}, R^{11a}, R^{12a}, R^{13a}, R^{14a}, R^{15a}, R^{16a}, R^{17a}, R^{18a}, R^{19a}, R^{20a}, and R^{21a} is each independently selected from H, a C₁₋₃ alkyl, C₆₋₁₂ aryl, and C₅₋₁₂ cycloalkyl,
L⁴ is selected from a C₁₋₁₂ alkylene, C₆₋₁₂ arylene, C₆₋₁₂ arylene-C₁₋₁₂ alkylene, C₁₋₁₂ alkylene-C₆₋₁₂ arylene, C₁₋₁₂ alkylene-O—C₁₋₁₂ alkylene, (O—C₁₋₁₂ alkylene)ₚ, (C₁₋₁₂ alkylene-O)ₚ, C(O)(O—C₁₋₁₂ alkylene)ₚ, OC(O)(C₁₋₁₂ alkylene)ₚ, C₁₋₁₂ alkylene-NH—C₁₋₁₂ alkylene, C₁₋₁₂ alkylene-N(C₁₋₁₂ alkyl)-C₁₋₁₂ alkylene, C(O)(NH—C₁₋₁₂ alkylene)ₚ, (NH)C(O—C₁₋₁₂ alkylene)ₚ, (NH—C₁₋₁₂ alkylene)ₚ, (C₁₋₁₂ alkylene-NH)ₚ, and a bond;
p is an integer between 1 and 6; and
each moiety within square brackets represents a repeat unit of the support ionomer.

51. A membrane electrode assembly (MEA), comprising a polymer film of any one of claims 1-35, an electrode of any one of claims 36-43, or a composite material of any one of claims 44-50.

52. A fuel cell comprising an MEA of claim 51, a source of fuel, and an oxidant.

53. The fuel cell of claim 52, wherein the fuel is humidified.

54. The fuel cell of claim 53 or 53, wherein the fuel is selected from hydrogen, methanol, ethanol, and ammonia.

55. The fuel cell of any one of claims 52-54, wherein the oxidant is oxygen.

56. An electrolyzer comprising an MEA of claim 51 and an electrolyte source.

57. The electrolyzer of claim 56, wherein the electrolyte source comprises water, a metal hydroxide, ethanol, methanol, ammonia, carbon dioxide, or a combination thereof.

58. A method of making a polymer film of any one of claims 1-35, comprising:
a) providing a precursor film comprising the cross-linkable precursor ionomer,
b) applying a mask to the film, thereby providing a partially protected film;
c) exposing the partially protected film to ultraviolet radiation for a time sufficient to cross-link the cross-linkable ionomer, thereby producing the polymer film.

59. The method of claim 58, wherein the precursor film does not comprise an external radical initiator.
